(19) United States
(12) Patent Application Publication
(10) Pub. No.: US 2026/0183872 A1
(43) Pub. Date: Jul. 2, 2026

(54) DICING DEVICE, SEMICONDUCTOR CHIP MANUFACTURING METHOD, AND SEMICONDUCTOR CHIP

(71) Applicant: YAMAHA HATSUDOKI KABUSHIKI KAISHA, Iwata-shi, Shizuoka (JP)

(72) Inventor: Yoshikuni SUZUKI, Iwata-shi, Shizuoka (JP)

(73) Assignee: YAMAHA HATSUDOKI KABUSHIKI KAISHA, Iwata-shi, Shizuoka (JP)

(21) Appl. No.: 18/859,110

(22) PCT Filed: Feb. 3, 2023
(86) PCT No.: PCT/JP2023/003641

§ 371 Date: Oct. 22, 2024

(30) Foreign Application Priority Data
Apr. 27, 2022 (WO) PCT/JP2022/019189

(51) Int. Cl. B23K 26/53; B23K 26/03; H10P 54/20; H10P 72/00

(52) U.S. Cl. CPC B23K 26/53; B23K 26/032; H10P 54/20; H10P 72/0428; H10P 72/0604; H10P 72/0616

(57) ABSTRACT

A dicing device includes a laser irradiator configured to emit a laser in a direction extending along each of a plurality of streets of a wafer to form a modified layer in the wafer, a first imager configured to image the wafer in which the modified layer has been formed, and a shared mounting member to which both the laser irradiator and the first imager are mounted.

### CROSS-REFERENCE TO RELATED APPLICATION

This application is a National Stage of International Patent Application No. PCT/JP2022/019189, filed Apr. 27, 2022, the entire content of which is incorporated herein by reference.

### BACKGROUND

### Technical Field

The present disclosure relates to a dicing device, a semiconductor chip manufacturing method, and a semiconductor chip, and more particularly, it relates to a dicing device including a laser irradiator to form a modified layer in a wafer, a semiconductor chip manufacturing method, and a semiconductor chip.

### Background Art

Conventionally, a dicing device including a laser irradiator to form a modified layer in a wafer is known. Such a dicing device is disclosed in Japanese Patent No. 6281328, for example.

Japanese Patent No. 6281328 discloses a laser dicing device including a laser head to form a modified region in a wafer. The laser dicing device includes a laser movement mechanism, a microscope, and a microscope movement mechanism.

The laser head disclosed in Japanese Patent No. 6281328 is attached to the laser movement mechanism arranged above the wafer. The microscope images the state of cracks due to the modified region appearing on the back surface of the wafer. The microscope is attached to the microscope movement mechanism arranged below the wafer.

### SUMMARY

In the laser dicing device disclosed in Japanese Patent No. 6281328, the laser head is attached to the laser movement mechanism, and the microscope is attached to the microscope movement mechanism that is provided separately from the laser movement mechanism. Thus, the number of components used in the mounting structure for the laser head and the microscope in the laser dicing device increases, and the mounting structure for the laser head and the microscope in the laser dicing device becomes complex.

Therefore, the present disclosure provides a dicing device, a semiconductor chip manufacturing method, and a semiconductor chip each capable of reducing or preventing an increase in the number of components in the mounting structure for a laser irradiator and an imager of the dicing device and the complexity of the mounting structure.

A dicing device according to a first aspect of the present disclosure includes a laser irradiator configured to emit a laser in a processing direction extending along each of a plurality of streets of a wafer to form a modified layer in the wafer, a first imager configured to image the wafer in which the modified layer has been formed, and a shared mounting member to which both the laser irradiator and the first imager are mounted.

As described above, the dicing device according to the first aspect of the present disclosure includes the shared mounting member to which both the laser irradiator and the first imager are mounted. Accordingly, the laser irradiator and the first imager are mounted to the shared mounting member such that an increase in the number of components and the complexity of the mounting structure for the laser irradiator and the first imager in the dicing device can be reduced or prevented.

In the dicing device according to the first aspect, the mounting member is preferably fixed in position in a horizontal direction and an upward-downward direction of the dicing device, and the laser irradiator and the first imager are preferably fixed in position in the horizontal direction and mounted to the mounting member. Accordingly, as compared with a case in which a movement mechanism is provided to move each of the laser irradiator and the first imager in the horizontal direction, an increase in the number of components in the movement mechanism for the laser irradiator and the movement mechanism for the first imager and the complexity of the movement mechanism for the laser irradiator and the movement mechanism for the first imager can be reduced or prevented.

In such a case, the dicing device preferably further includes a table unit configured to move the wafer in the processing direction while holding the wafer, and the first imager is preferably fixed in position in the horizontal direction and is preferably configured to image the wafer in which the modified layer has been formed by the laser emitted to the wafer from the laser irradiator while the wafer is moved in the processing direction by the table unit. Accordingly, the wafer is moved by the table unit such that the crack formed in the wafer can be imaged, and thus the need for a movement mechanism to move the imager in the horizontal direction can be eliminated.

The dicing device including the table unit preferably further includes a controller configured or programmed to, when imaging a crack caused by the modified layer using the first imager after the modified layer is formed in the wafer, perform a control to continue to expose the first imager to light at an illumination intensity and for an exposure time, the illumination intensity and the exposure time both being set to correspond to a value obtained by multiplying together a predetermined illumination intensity and a predetermined exposure time, both of which enable the crack to be recognized, while moving the wafer held by the table unit in the processing direction with respect to the first imager fixed in position by the mounting member. Accordingly, an image in which the crack is recognizable can be reliably acquired even when the first imager is continuously exposed to light and captures the image.

In such a case, the controller is preferably configured or programmed to control the first imager to image the crack based on an imaging execution section for the first imager set to further satisfy an imaging condition that the first imager is exposed to light with respect to a portion of a predetermined street of the plurality of streets in which the modified layer is formed by the laser, and the first imager is not exposed to light with respect to a portion of the predetermined street in which the modified layer is not formed by the laser, the predetermined exposure time, and the predetermined illumination intensity. Accordingly, the first imager does not image the portion of the predetermined street in which the modified layer is not formed by the laser, but images only the portion of the predetermined street in which the modified layer is formed by the laser and the crack is formed, and thus an image in which the crack more clearly appears can be acquired.

In the dicing device according to the first aspect, the first imager is preferably mounted to the mounting member together with the laser irradiator with a focal position of the laser from the laser irradiator and an optical center of the first imager aligned along the processing direction in a plan view. Accordingly, during processing of the modified layer, a portion of the wafer processed by the laser emitted from the laser irradiator is moved directly below the first imager as the wafer is moved in the processing direction, and thus processing of the modified layer by the laser emitted from the laser irradiator and imaging of the crack of the wafer by the first imager can be performed in parallel.

The dicing device according to the first aspect preferably further includes a second imager mounted to the mounting member together with the first imager and the laser irradiator to image an alignment mark on the wafer, and the first imager preferably has a higher resolution than the second imager. Accordingly, a more detailed image of the crack generated in the wafer can be captured by the first imager having a higher resolution, and thus the crack can be accurately inspected.

The dicing device according to the first aspect preferably further includes a controller configured or programmed to perform a control to continue to expose the first imager to light with respect to a preset portion of a predetermined street of the plurality of streets while forming the modified layer in the wafer by the laser along the processing direction at the predetermined street to create a panning image. Accordingly, the panning image displayed based on a luminance value obtained by accumulating luminance values of the preset portion of the predetermined street can be acquired, and thus the crack generated in the wafer due to the modified layer can be inspected based on a relatively small number of images.

In such a case, the controller is preferably configured or programmed to, when imaging a crack on a surface of the wafer closer to the first imager caused by the modified layer using the first imager while forming the modified layer in the wafer, perform a control to continue to expose the first imager to light to capture the panning image based on an illumination intensity and an exposure time of the first imager, both of which are set to correspond to a value obtained by multiplying together a predetermined illumination intensity and a predetermined exposure time, both of which enable the crack to be recognized. Accordingly, the crack clearly appears in the panning image captured by continuing to expose the first imager to light, and thus the controller can reliably recognize the crack.

In such a case, the controller is preferably configured or programmed to control the first imager to image the crack based on an imaging execution section for the first imager set to further satisfy an imaging condition that the first imager is exposed to light with respect to a portion of the predetermined street in which the modified layer is formed by the laser, and the first imager is not exposed to light with respect to a portion of the predetermined street in which the modified layer is not formed by the laser, the predetermined exposure time, and the predetermined illumination intensity. Accordingly, the first imager does not image the portion of the predetermined street in which the modified layer is not formed by the laser, but images only the portion of the predetermined street in which the modified layer is formed by the laser and the crack is formed, and thus a panning image in which the crack more clearly appears can be acquired.

In such a case, the controller is preferably configured or programmed to perform a control to acquire an illumination intensity to image the preset portion of the predetermined street using the first imager while forming the modified layer in the wafer by the laser along the processing direction based on an exposure time preset for the first imager to image the preset portion of the predetermined street using the first imager while forming the modified layer in the wafer by emitting the laser along the processing direction, and an exposure time and an illumination intensity preset for the first imager to inspect the crack formed due to the modified layer after the modified layer is formed at all of the plurality of streets. Accordingly, the illumination intensity for imaging the predetermined street by the first imager can be appropriately adjusted, and thus the possibility that the panning image captured by the first imager becomes too dark or too bright can be reduced or prevented.

In the dicing device including the controller, the controller is preferably configured or programmed to perform a control to perform a first inspection to inspect whether processing of the modified layer by the laser is bad or not based on a plurality of average luminance values acquired for a plurality of respective pixel groups by averaging luminance values of a plurality of pixels included in the plurality of pixel groups of the panning image in which the plurality of pixel groups including the plurality of pixels aligned in the processing direction are aligned in a direction perpendicular to the processing direction. Accordingly, the luminance values of the plurality of pixels included in the pixel groups can be combined into average luminance values, and then the first inspection process can be performed. Thus, the complexity of the process of the controller to perform the first examination can be prevented.

In the dicing device including the controller configured or programmed to perform the first inspection based on the plurality of average luminance values, the controller is preferably configured or programmed to perform a control to acquire a plurality of crack luminance values that are equal to or greater than a preset threshold, and a position range in the direction perpendicular to the processing direction of the plurality of pixel groups having the plurality of crack luminance values based on average luminance values within a position range of the predetermined street among the plurality of average luminance values and the preset threshold. Accordingly, the plurality of crack luminance values corresponding to the crack portion formed due to the modified layer are acquired from among the plurality of average luminance values within the position range of the predetermined street such that it is possible to exclude the average luminance values that are not required for the first inspection from the inspection, and thus the inspection accuracy of the first inspection can be ensured.

In the dicing device including the controller configured or programmed to perform a control to acquire the plurality of crack luminance values, the controller is preferably configured or programmed to perform a control to acquire an amount of positional deviation of the crack formed due to the modified layer based on a difference between a position within the position range of the plurality of crack luminance values and a preset reference position, and perform the first inspection. Accordingly, the amount of positional deviation of the crack is acquired such that the relative positional deviation in the horizontal direction between the laser irradiator and the wafer can be corrected so as to reduce the amount of positional deviation of the crack before processing is performed to form the modified layer at the street at which the modified layer has not been formed. Thus, the modified layer can be formed at an appropriate position in the wafer.

In the dicing device including the controller configured or programmed to perform a control to acquire the amount of positional deviation, the controller is preferably configured or programmed to perform a control to correct a positional deviation of a focal position of the laser in the direction perpendicular to the processing direction based on the amount of positional deviation before processing of the modified layer by the laser at a street after a street next to the predetermined street on which the plurality of average luminance values have been acquired. Accordingly, at least the time required for processing of the modified layer in the wafer by the laser at the next street can be ensured as the processing time for performing a process to acquire the amount of positional deviation, and thus sufficient processing time for the controller required to acquire the amount of positional deviation can be ensured.

In the dicing device including the controller configured or programmed to perform a control to acquire the plurality of crack luminance values, the controller is preferably configured or programmed to perform a control to perform the first inspection to inspect whether the crack formed due to the modified layer is appropriate or not based on at least one of a comparison between an average value of the plurality of crack luminance values and a preset reference average luminance value range or a comparison between a width as a range in a direction in which the plurality of pixel groups corresponding to the plurality of crack luminance values Bra are aligned and that is perpendicular to the processing direction and a preset reference width range. Accordingly, in the first inspection, the average value of the plurality of crack luminance values is compared with the preset reference average luminance value range such that it is possible to determine whether the luminance value of the portion corresponding to the crack is sufficiently large or not, and thus it is possible to identify a decrease in the luminance value caused by the crack being interrupted midway. Furthermore, the width as the range of the plurality of crack luminance values is compared with the preset reference width range such that it is possible to identify an increase in the width of the crack luminance values, which is a portion of the panning image corresponding to the crack, caused by the wafer or the laser irradiator moving in a direction inclined with respect to the processing direction extending along the street when the modified layer is formed in the wafer.

In the dicing device including the controller configured or programmed to perform a control to acquire the plurality of crack luminance values, the controller is preferably configured or programmed to perform a control to notify an operator when an inspection result of the first inspection based on the plurality of crack luminance values is bad. Accordingly, the operator can recognize the defect.

In the dicing device including the controller configured or programmed to perform the first inspection based on the plurality of average luminance values, the dicing device is preferably configured to make a setting to perform a second inspection to re-inspect whether the crack formed due to the modified layer is bad or not after the modified layer is formed at all of the plurality of streets of the wafer, based on an inspection result indicating that the processing of the modified layer is bad among inspection results of the first inspection for the plurality of streets. Accordingly, as compared with a case in which the cracks formed at all of the plurality of streets of the wafer are inspected in the second inspection, the number of inspection targets in the second inspection can be reduced, and thus an increase in the processing load on the controller for the second examination can be reduced or prevented.

A semiconductor chip manufacturing method according to a second aspect of the present disclosure includes forming a modified layer in a wafer including a plurality of semiconductor chips by emitting a laser from a laser irradiator in a processing direction extending along each of a plurality of streets of the wafer, imaging the wafer in which the modified layer has been formed using a first imager mounted to a mounting member shared with the laser irradiator, and expanding an elastic sheet member to divide the wafer into the plurality of semiconductor chips along a dividing line by an expander.

As described above, the semiconductor chip manufacturing method according to the second aspect of the present disclosure includes imaging the wafer in which the modified layer has been formed using the first imager mounted to the mounting member shared with the laser irradiator. Accordingly, the laser irradiator and the first imager are mounted to the shared mounting member such that it is possible to obtain the semiconductor chip manufacturing method capable of reducing or preventing an increase in the number of components in the mounting structure for the laser irradiator and the first imager and the complexity of the mounting structure in the dicing device.

A semiconductor chip according to a third aspect of the present disclosure is manufactured by a dicing device including a laser irradiator configured to emit a laser in a processing direction extending along each of a plurality of streets of a wafer including a plurality of semiconductor chips to form a modified layer in the wafer, a first imager configured to image the wafer in which the modified layer has been formed, and a shared mounting member to which both the laser irradiator and the first imager are mounted.

As described above, the semiconductor chip according to the third aspect of the present disclosure is manufactured by the dicing device including the shared mounting member to which both the laser irradiator and the first imager are mounted. Accordingly, the laser irradiator and the first imager are mounted to the shared mounting member such that it is possible to obtain the semiconductor chip capable of reducing or preventing an increase in the number of components in the mounting structure for the laser irradiator and the first imager and the complexity of the mounting structure in the dicing device.

The dicing device according to the first aspect preferably further includes a controller configured or programmed to perform a control to continue to expose the first imager to light with respect to a preset portion of a predetermined street of the plurality of streets while forming the modified layer in the wafer by the laser along the processing direction at the predetermined street to image a crack on a surface of the wafer closer to the first imager caused by the modified layer to capture a panning image using the first imager. Accordingly, when the panning image is obtained by imaging the crack on the surface closer to the first imager, it can be reliably confirmed that the crack has reached the surface of the wafer, and thus it is possible to confirm a location at which the wafer is not properly divided because the crack has not reached the surface of the wafer. Consequently, it is possible to change the emission conditions of the laser and re-emit the laser to the predetermined street, and it is also possible to identify the location at which the wafer is not properly divided and perform subsequent detailed inspections to reduce or prevent an increase in the number of detailed inspections.

In such a case, the controller is preferably configured or programmed to, when imaging the crack on the surface of the wafer closer to the first imager caused by the modified layer using the first imager while forming the modified layer in the wafer, perform a control to continue to expose the first imager to light to capture the panning image using the first imager based on an illumination intensity and an exposure time of the first imager, both of which are set to correspond to a value obtained by multiplying together a predetermined illumination intensity and a predetermined exposure time, both of which enable the crack to be recognized. Accordingly, the crack clearly appears in the panning image captured by continuing to expose the first imager to light, and thus the controller can reliably recognize the crack.

The dicing device including the controller configured or programmed to acquire the panning image preferably further includes a table unit configured to move the wafer in the processing direction while holding the wafer, the mounting member is preferably fixed in position in a horizontal direction and an upward-downward direction of the dicing device, and the controller is preferably configured or programmed to perform a control to continue to expose the first imager to light with respect to the predetermined street while forming the modified layer in the wafer by the laser at the predetermined street by moving the wafer held by the table unit in the processing direction with respect to the first imager fixed in position by the mounting member to capture the panning image using the first imager. Accordingly, the crack is imaged using the first imager fixed in position such that the focal position of the first imager can be maintained constant, and thus the panning image can be acquired in which the crack clearly appears.

In such a case, the first imager is preferably mounted to the mounting member together with the laser irradiator with a focal position of the laser from the laser irradiator and an optical center of the first imager aligned along the processing direction in a plan view, and the controller is preferably configured or programmed to perform a control to move the wafer in the processing direction relative to the laser irradiator and the first imager until the focal position of the laser reaches an ending point of the predetermined street in the processing direction, and then continue relative movement of the wafer and extend imaging of the crack by the first imager to capture the panning image. Since the focal position of the laser from the laser irradiator and the optical center of the first imager are aligned along the processing direction, the crack in the portion between the focal position of the laser from the laser irradiator and the optical center of the first imager has not been imaged by the first imager when the focal position of the laser reaches the ending point of the predetermined street in the processing direction. Therefore, imaging of the crack by the first imager is extended such that the crack in question can be imaged by the first imager, and thus the crack formed on the predetermined street can be reliably imaged by the first imager to the extent necessary.

In the dicing device including the controller configured or programmed to perform a control to extend imaging to capture the panning image, the controller is preferably configured or programmed to perform a control to extend imaging of the crack by the first imager to capture the panning image based on an imaging condition including information about an imaging execution section based on a larger of a first distance based on a minimum value of an exposure time of the first imager and a second distance based on a maximum value of an illumination intensity of the first imager. Accordingly, the imaging execution section is set so as not to exceed settable numerical limits for the minimum exposure time and maximum illumination intensity of the first imager, and thus the panning image in which the crack is recognizable can be acquired.

In the dicing device including the controller configured or programmed to perform a control to extend imaging to capture the panning image, the controller is preferably configured or programmed to, when an imaging execution section at the predetermined street for imaging the crack by extending imaging by the first imager has a distance that does not enable an exposure time and an illumination intensity, both of which enable the crack to be recognized in the panning image, to be set, perform an image process to amplify a luminance value contained in the panning image captured by extending imaging by the first imager with respect to the predetermined street. Accordingly, even when the exposure time and illumination intensity of the first imager exceed the limits of settable numerical values, the crack is imaged by the first imager within a range of each of the settable numerical values of the exposure time and illumination intensity of the first imager, and then the luminance value included in the acquired panning image is amplified such that the panning image in which the crack is recognizable can be acquired.

In the dicing device including the controller configured or programmed to perform a control to extend imaging to capture the panning image, the controller is preferably configured or programmed to, when a length of the predetermined street in the processing direction is longer than a distance between the focal position of the laser and the optical center of the first imager, perform a control to stop the first imager from imaging the crack and make a movement to a next street at which the modified layer is to be formed when the focal position of the laser reaches the ending point of the predetermined street in the processing direction in a preset imaging execution section in which the crack is imaged by the first imager, and extension of imaging of the crack by the first imager is not set. Accordingly, the time required to move from the predetermined street to the next street can be shortened as much as possible while information about the crack required for inspection based on the crack is acquired. Thus, the accuracy of the inspection can be ensured, and an increase in the processing time required to form the modified layer in the wafer can be reduced or prevented.

In the dicing device including the controller configured or programmed to perform a control to extend imaging to capture the panning image, the controller is preferably configured or programmed to, when a length of the predetermined street in the processing direction is shorter than a distance between the focal position of the laser and the optical center of the first imager, perform a control to continue relative movement of the wafer and extend imaging of the crack by the first imager to capture the panning image after the focal position of the laser reaches the ending point of the predetermined street in the processing direction in a preset imaging execution section in which the crack is imaged by the first imager, and extension of imaging of the crack by the first imager is set. In the case of the short section as described above, when the focal position of the laser reaches the ending point of the predetermined street in the processing direction and then a movement to the street next to the predetermined street is made, the crack at the predetermined street cannot be imaged. Therefore, imaging of the crack by the first imager is extended such that even when the length of the predetermined street in the processing direction is short, the crack can be imaged by the first imager.

According to the present disclosure, as described above, it is possible to reduce or prevent an increase in the number of components in the mounting structure for the laser irradiator and the imager in the dicing device and the complexity of the mounting structure.

### BRIEF DESCRIPTION OF THE DRAWING

FIG. 1 is a plan view showing a semiconductor wafer processing apparatus including a dicing device and an expanding device according to a first embodiment;

FIG. 2 is a plan view showing a wafer ring structure to be processed in the semiconductor wafer processing apparatus according to the first embodiment;

FIG. 3 is a sectional view taken along the line III-III in FIG. 2;

FIG. 4 is a plan view of the dicing device arranged adjacent to the expanding device according to the first embodiment;

FIG. 5 is a side view showing the dicing device arranged adjacent to the expanding device according to the first embodiment, as viewed from the Y2 direction side;

FIG. 6 is a plan view of the expanding device according to the first embodiment;

FIG. 7 is a side view showing the expanding device according to the first embodiment, as viewed from the Y2 direction side;

FIG. 8 is a side view showing the expanding device according to the first embodiment, as viewed from the X1 direction side;

FIG. 9 is a block diagram showing the control configuration of the semiconductor wafer processing apparatus according to the first embodiment;

FIG. 10 is a flowchart of the first half of a semiconductor chip manufacturing process of the semiconductor wafer processing apparatus according to the first embodiment;

FIG. 11 is a flowchart of the second half of the semiconductor chip manufacturing process of the semiconductor wafer processing apparatus according to the first embodiment;

FIG. 12 is a plan view showing a plurality of streets of a wafer in the dicing device according to the first embodiment;

FIG. 13 is a sectional view taken along the line XIII-XIII in FIG. 12;

FIG. 14 is a side view showing a state in which a modified layer is formed in the wafer by a laser irradiator of the dicing device according to the first embodiment;

FIG. 15 is a plan view showing a state in which the modified layer is formed in the wafer by the laser irradiator of the dicing device according to the first embodiment;

FIG. 16 is a side view showing a state in which the modified layer is in the process of being formed in the wafer by the laser irradiator of the dicing device according to the first embodiment;

FIG. 17 is a schematic view showing a panning image of a predetermined street captured by a high-resolution camera of the dicing device according to the first embodiment;

FIG. 18 is a schematic view showing a plurality of average luminance values of a panning image captured by the high-resolution camera of the dicing device according to the first embodiment;

FIG. 19 is a graph showing the plurality of average luminance values of the panning image captured by the high-resolution camera of the dicing device according to the first embodiment;

FIG. 20 is a schematic view showing a range for identifying whether the positional deviation of a crack in the panning image is good or bad in the dicing device according to the first embodiment;

FIG. 21 is a schematic view showing correction of the position of the wafer in a Y direction performed to correct the positional deviation in the dicing device according to the first embodiment;

FIG. 22 is a schematic view showing a range for identifying whether or not the crack in the panning image is continuous in the dicing device according to the first embodiment;

FIG. 23 is a schematic view showing a range for identifying whether the width of the crack in the panning image is good or bad in the dicing device according to the first embodiment;

FIG. 24 is a graph showing a case in which a plurality of widths are acquired in the panning image captured by the high-resolution camera of the dicing device according to the first embodiment;

FIG. 25 is a schematic view showing that a second inspection is performed on a portion for which the inspection result of a first inspection is bad in the dicing device according to the first embodiment;

FIG. 26 is a plan view showing a state in which the modified layer has been formed on all of the plurality of streets of the wafer in the dicing device according to the first embodiment;

FIG. 27 is a schematic view showing cutting channel information of the wafer in the dicing device according to the first embodiment;

FIG. 28 is a schematic view showing cutting line information of the wafer in the dicing device according to the first embodiment;

FIG. 29 is a schematic view showing information about the number of intersections of the wafer in the dicing device according to the first embodiment;

FIG. 30 is a schematic view showing intersections of the wafer other than intersections in a mask region in the dicing device according to the first embodiment;

FIG. 31 is an enlarged view of a Zm portion in FIG. 30;

FIG. 32 is a schematic view showing a state in which an identification figure is superimposed on an intersection image in the dicing device according to the first embodiment;

FIG. 33 is a schematic view showing a state in which an identification figure is further superimposed on the intersection image in the dicing device according to the first embodiment;

FIG. 34 is a schematic view showing a portion of a crack in an intersection image obtained by superimposing the identification figure on the intersection image in the dicing device according to the first embodiment;

FIG. 35 is a schematic view showing an intersection image in which a crack is meandering in the dicing device according to the first embodiment;

FIG. 36 is a schematic view showing an intersection image in which a crack is discontinuous in the dicing device according to the first embodiment;

FIG. 37 is a schematic view showing information about the center points and lengths of a portion of a crack in an intersection image acquired in the dicing device according to the first embodiment;

FIG. 38 is a block diagram showing a semiconductor wafer processing system including the semiconductor wafer processing apparatus and an external control apparatus according to the first embodiment;

FIG. 39 is a schematic view showing a first setting change screen displayed on a display of the external control apparatus of the semiconductor wafer processing system according to the first embodiment;

FIG. 40 is a schematic view showing a second setting change screen displayed on the display of the external control apparatus of the semiconductor wafer processing system according to the first embodiment;

FIG. 41 is a schematic view showing a third setting change screen displayed on the display of the external control apparatus of the semiconductor wafer processing system according to the first embodiment;

FIG. 42 is a schematic view showing a fourth setting change screen displayed on the display of the external control apparatus of the semiconductor wafer processing system according to the first embodiment;

FIG. 43 is a histogram showing the number of bad results and the number of good results displayed on the display of the external control apparatus of the semiconductor wafer processing system according to the first embodiment;

FIG. 44 is a flowchart of a crack inspection process of a dicing control calculator of the semiconductor wafer processing apparatus according to the first embodiment;

FIG. 45 is a plan view showing a semiconductor wafer processing apparatus including a dicing device and an expanding device according to a second embodiment;

FIG. 46 is a side view showing the semiconductor wafer processing apparatus including the dicing device and the expanding device according to the second embodiment, as viewed from the Y2 direction side;

FIG. 47 is a side view showing the semiconductor wafer processing apparatus including the dicing device and the expanding device according to the second embodiment, as viewed from the X1 direction side;

FIG. 48 is a block diagram showing the control configuration of the semiconductor wafer processing apparatus according to the second embodiment;

FIG. 49 is a flowchart of the first half of a semiconductor chip manufacturing process of the semiconductor wafer processing apparatus according to the second embodiment;

FIG. 50 is a flowchart of the second half of the semiconductor chip manufacturing process of the semiconductor wafer processing apparatus according to the second embodiment;

FIG. 51 is a schematic view showing a state in which four identification frames are placed in an intersection image of the dicing device in the first and second embodiments;

FIG. 52 is a schematic view showing a state in which one identification frame is placed in the intersection image of the dicing device in the first and second embodiments;

FIG. 53 is a plan view showing a semiconductor wafer processing apparatus including a dicing device and an expanding device according to a third embodiment;

FIG. 54 is a block diagram showing a semiconductor wafer processing system including the semiconductor wafer processing apparatus and an external control apparatus according to the third embodiment;

FIG. 55 is a schematic view showing a state in which a crack on a surface of a wafer is imaged while a modified layer is formed in the wafer in the dicing device according to the third embodiment;

FIG. 56 A schematic view showing an imaging execution section and a non-imaging execution section when the focal position of a laser irradiator reaches an ending point of a predetermined street that is longer than a distance between the focal position of the laser irradiator and the optical center of a high-resolution camera in the dicing device according to the third embodiment;

FIG. 57 is a schematic view showing a non-imaging execution section when the focal position of the laser irradiator reaches an ending point of a predetermined street that is shorter than the distance between the focal position of the laser irradiator and the optical center of the high-resolution camera in the dicing device according to the third embodiment;

FIG. 58 is a schematic view showing first to fifth still images captured by the high-resolution camera in the dicing device according to the third embodiment;

FIG. 59 is a graph showing an example of luminance values corresponding to pixel positions in the first still image captured by the high-resolution camera in the dicing device according to the third embodiment;

FIG. 60 is a graph showing an example of luminance values corresponding to pixel positions in the third still image captured by the high-resolution camera in the dicing device according to the third embodiment;

FIG. 61 is a graph showing an example of luminance values corresponding to pixel positions in the fifth still image captured by the high-resolution camera in the dicing device according to the third embodiment;

FIG. 62 is a schematic view showing a panning image captured by the high-resolution camera with settings in which a value obtained by multiplying a predetermined exposure time by a predetermined illumination intensity matches a value obtained by multiplying together the exposure time and illumination intensity of the high-resolution camera in the dicing device according to the third embodiment;

FIG. 63 is a schematic view showing that extension of imaging of the crack by the high-resolution camera has been set for the predetermined street that is longer than the distance between the focal position of the laser irradiator and the optical center of the high-resolution camera in the external control apparatus according to the third embodiment;

FIG. 64 is a schematic view showing that extension of imaging of the crack by the high-resolution camera has been set for the predetermined street that is shorter than the distance between the focal position of the laser irradiator and the optical center of the high-resolution camera in the external control apparatus according to the third embodiment;

FIG. 65 is a schematic view showing that imaging of the crack by the high-resolution camera is not extended for the predetermined street that is shorter than the distance between the focal position of the laser irradiator and the optical center of the high-resolution camera in the external control apparatus according to the third embodiment;

FIG. 66 is a schematic view showing a case in which imaging of the crack by the high-resolution camera is extended for the predetermined street that is longer than the distance between the focal position of the laser irradiator and the optical center of the high-resolution camera in the dicing device according to the third embodiment;

FIG. 67 is a schematic view showing a case in which imaging of the crack by the high-resolution camera is extended for the predetermined street that is shorter than the distance between the focal position of the laser irradiator and the optical center of the high-resolution camera in the dicing device according to the third embodiment;

FIG. 68 is a graph showing a state in which a plurality of average luminance values contained in the panning image captured by the high-resolution camera of the dicing device according to the third embodiment are amplified;

FIG. 69 is a plan view showing a case in which imaging of the crack by the high-resolution camera is not extended for the predetermined street that is longer than the distance between the focal position of the laser irradiator and the optical center of the high-resolution camera, and a movement to the next street is made in the dicing device according to the third embodiment; and

FIG. 70 is a flowchart of a crack inspection process of a dicing control calculator of the semiconductor wafer processing apparatus according to the third embodiment.

### DETAILED DESCRIPTION

Embodiments embodying the present disclosure are hereinafter described on the basis of the drawings.

### First Embodiment

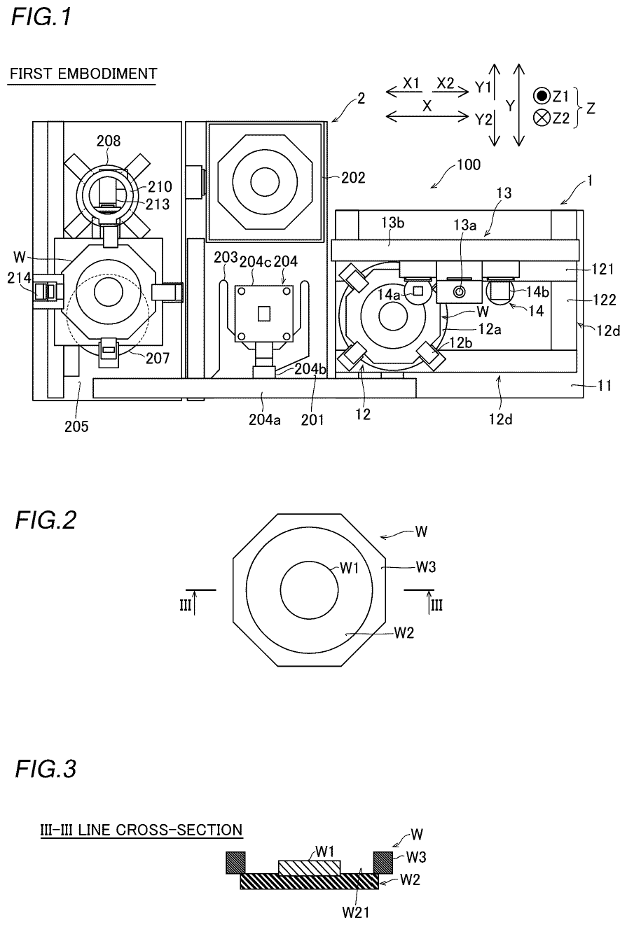

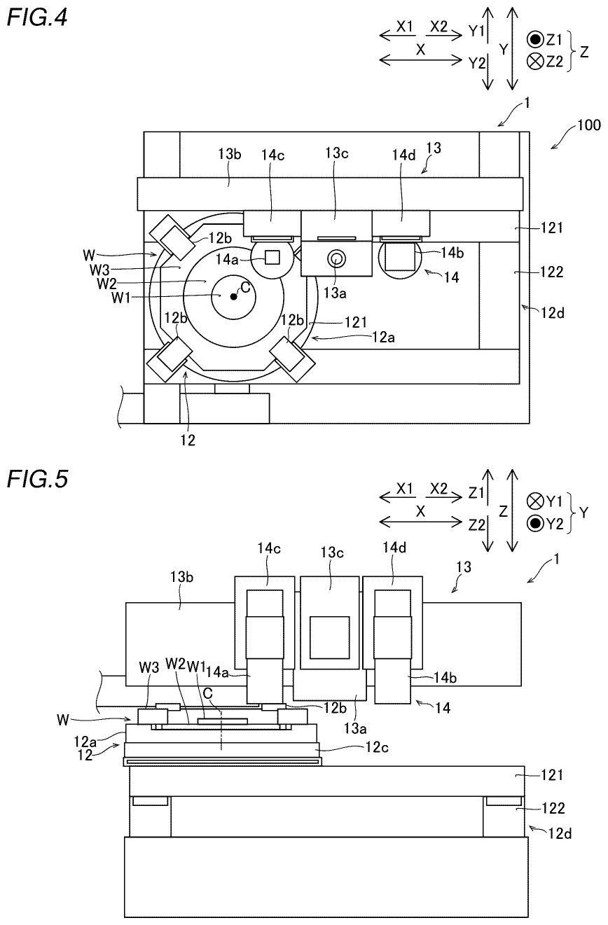

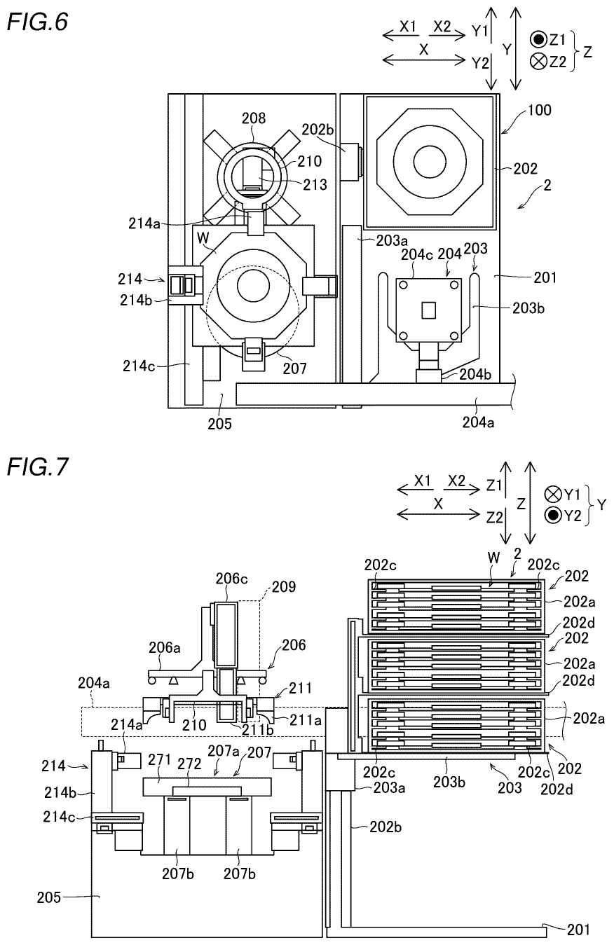

The configuration of a semiconductor wafer processing apparatus 100 according to a first embodiment of the present disclosure is now described with reference to FIGS. 1 to 44.

### Semiconductor Wafer Processing Apparatus

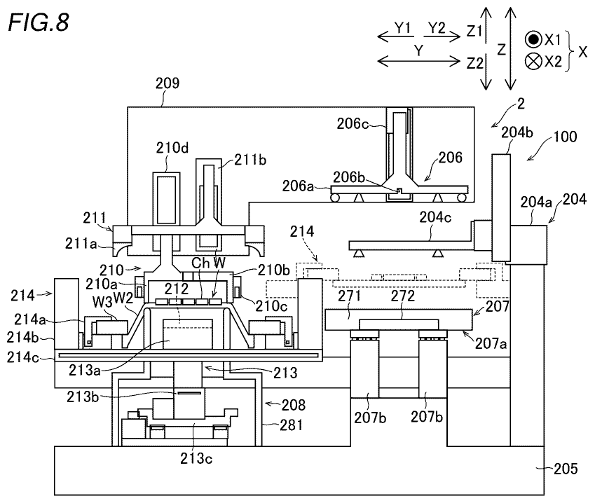

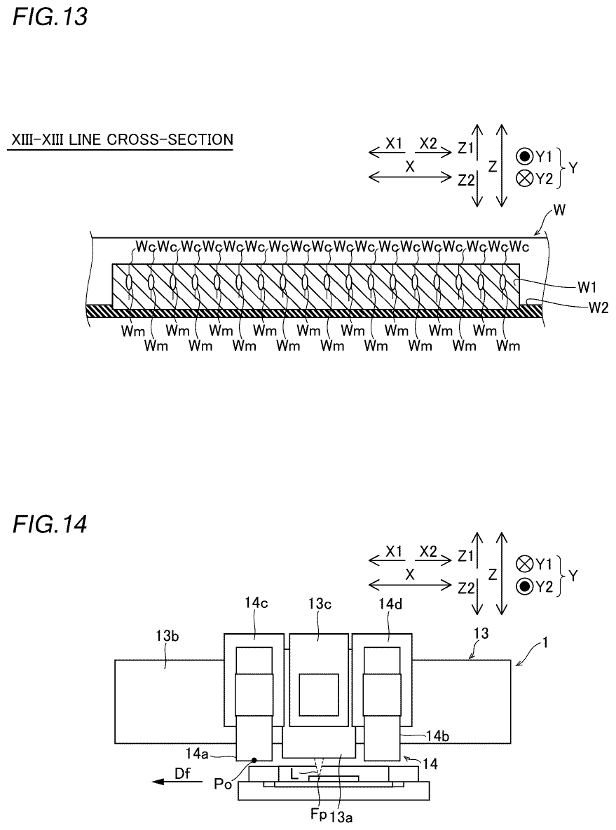

As shown in FIG. 1, the semiconductor wafer processing apparatus 100 is an apparatus that processes a wafer W1 provided on a wafer ring structure W. The semiconductor wafer processing apparatus 100 forms a modified layer Wm (see FIG. 13) in the wafer W1 and divides the wafer W1 along the modified layer Wm to form a plurality of semiconductor chips Ch (see FIG. 8).

The wafer ring structure W shown in FIGS. 2 and 3 is now described. The wafer ring structure W includes the wafer W1, a sheet member W2, and a ring-shaped member W3.

The wafer W1 is a circular thin plate made of a crystal of a semiconductor material that is used as a material for a semiconductor integrated circuit. Inside the wafer W1, the modified layer Wm is formed by modifying the inside along a dividing line by processing in the semiconductor wafer processing apparatus 100. That is, the wafer W1 is processed so as to be divisible along the dividing line. The sheet member W2 is an elastic adhesive tape. An adhesive layer is provided on the upper surface W21 of the sheet member W2. The wafer W1 is attached to the adhesive layer on the sheet member W2. The ring-shaped member W3 is a ring-shaped metal frame in a plan view. The ring-shaped member W3 is attached to the adhesive layer on the sheet member W2 while surrounding the wafer W1.

The semiconductor wafer processing apparatus 100 includes a dicing device 1 and an expanding device 2. Hereinafter, an upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 2 are aligned is defined as an X direction, a direction from the dicing device 1 toward the expanding device 2 in the X direction is defined as an X1 direction, and a direction from the expanding device 2 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

As shown in FIGS. 1, 4, and 5, the dicing device 1 emits a laser L having a wavelength transmissive to the wafer W1 along the dividing line (street Ws) to form the modified layer Wm. The modified layer Wm refers to a crack, a void, or the like formed inside the wafer W1 by the laser L. A method for forming the modified layer Wm in the wafer W1 in this manner is called dicing.

Specifically, the dicing device 1 includes a base 11, a chuck table unit 12, a laser 13, and an imager 14. The chuck table unit 12 is an example of a “table unit” in the claims.

The base 11 is a base on which the chuck table unit 12 is installed. The base 11 has a rectangular shape in the plan view.

### Chuck Table Unit

The chuck table unit 12 includes a suction unit 12a, clamps 12b, a rotation mechanism 12c, and a table movement mechanism 12d. The suction unit 12a suctions the wafer ring structure W on the upper surface of the suction unit 12a on the Z1 direction side. The suction unit 12a is a table including a suction hole, a suction pipe line, etc. to suction the lower surface of the ring-shaped member W3 of the wafer ring structure W on the Z2 direction side. The suction unit 12a is supported by the table movement mechanism 12d via the rotation mechanism 12c. The clamps 12b are provided at an upper end of the suction unit 12a. The clamps 12b hold the wafer ring structure W suctioned by the suction unit 12a. The clamps 12b hold the ring-shaped member W3 of the wafer ring structure W suctioned by the suction unit 12a from the Z1 direction side. In this manner, the wafer ring structure W is held by the suction unit 12a and the clamps 12b.

The rotation mechanism 12c rotates the suction unit 12a in a circumferential direction around a rotation center axis C extending parallel to the Z direction. The rotation mechanism 12c is attached to an upper end of the table movement mechanism 12d. The table movement mechanism 12d moves the wafer ring structure W in the X and Y directions. The table movement mechanism 12d includes an X-direction movement mechanism 121 and a Y-direction movement mechanism 122. The X-direction movement mechanism 121 moves the rotation mechanism 12c in the X1 direction or the X2 direction. The X-direction movement mechanism 121 includes a linear conveyor module, or a ball screw and a drive including a motor with an encoder, for example. The Y-direction movement mechanism 122 moves the rotation mechanism 12c in the Y1 direction or the Y2 direction. The Y-direction movement mechanism 122 includes a linear conveyor module, or a ball screw and a drive including a motor with an encoder, for example.

### Laser

The laser 13 emits the laser L to the wafer W1 of the wafer ring structure W held by the chuck table unit 12. The laser 13 is arranged on the Z1 direction side of the chuck table unit 12. The laser 13 includes a laser irradiator 13a, a mounting member 13b, and a Z-direction movement mechanism 13c. The laser irradiator 13a emits a pulsed laser beam. The mounting member 13b is a frame to which the laser 13 and the imager 14 are mounted. The Z-direction movement mechanism 13c moves the laser 13 in the Z1 direction or the Z2 direction. The Z-direction movement mechanism 13c includes a linear conveyor module, or a ball screw and a drive including a motor with an encoder, for example. The laser irradiator 13a may be a laser irradiator that oscillates a continuous wave laser beam other than a pulsed laser beam as the laser L as long as a modified layer Wm can be formed by multiphoton absorption.

### Imager

The imager 14 images the wafer W1 of the wafer ring structure W held by the chuck table unit 12. The imager 14 is arranged on the Z1 direction side of the chuck table unit 12. The imager 14 includes a high-resolution camera 14a, a wide-angle camera 14b, a Z-direction movement mechanism 14c, and a Z-direction movement mechanism 14d. The high-resolution camera 14a is an example of a “first imager” in the claims. The wide-angle camera 14b is an example of a “second imager” in the claims.

The high-resolution camera 14a and the wide-angle camera 14b are near-infrared imaging cameras. The high-resolution camera 14a has a narrower viewing angle than the wide-angle camera 14b. The high-resolution camera 14a has a higher resolution than the wide-angle camera 14b. The wide-angle camera 14b has a wider viewing angle than the high-resolution camera 14a. The wide-angle camera 14b has a lower resolution than the high-resolution camera 14a. The high-resolution camera 14a is arranged on the X1 direction side of the laser irradiator 13a. The wide-angle camera 14b is arranged on the X2 direction side of the laser irradiator 13a. Thus, the high-resolution camera 14a, the laser irradiator 13a, and the wide-angle camera 14b are arranged adjacent to each other in this order from the X1 direction side toward the X2 direction side.

The Z-direction movement mechanism 14c moves the high-resolution camera 14a in the Z1 direction or the Z2 direction. The Z-direction movement mechanism 14c includes a linear conveyor module, or a ball screw and a drive including a motor with an encoder, for example. The Z-direction movement mechanism 14d moves the wide-angle camera 14b in the Z1 direction or the Z2 direction. The Z-direction movement mechanism 14d includes a linear conveyor module, or a ball screw and a drive including a motor with an encoder, for example. The chuck table unit 12, the laser 13, and the imager 14 of the dicing device 1 are described in detail below.

### Expanding Device

As shown in FIGS. 1, 6, and 7, the expanding device 2 divides the wafer W1 to form the plurality of semiconductor chips Ch (see FIG. 8). The expanding device 2 forms a sufficient gap between the plurality of semiconductor chips Ch. A modified layer Wm is formed in the wafer W1 by emitting a laser L having a wavelength transmissive to the wafer W1 along the dividing line (street Ws) in the dicing device 1. In the expanding device 2, the plurality of semiconductor chips Ch are formed by dividing the wafer W1 along the modified layer Wm formed in advance in the dicing device 1.

Therefore, in the expanding device 2, the wafer W1 is divided along the modified layer Wm by expanding the sheet member W2. Furthermore, in the expanding device 2, the gap between the plurality of semiconductor chips Ch formed by division is widened by expanding the sheet member W2.

The expanding device 2 includes a base 201, a cassette unit 202, a lift-up hand unit 203, a suction hand unit 204, a base 205, a cool air supplier 206, a cooling unit 207, an expander 208, a base 209, an expansion maintaining member 210, a heat shrinker 211, an ultraviolet irradiator 212, a squeegee unit 213, and a clamp unit 214.

### Base

The base 201 is a base on which the cassette unit 202 and the lift-up hand unit 203 are installed. The base 201 has a rectangular shape in the plan view.

### Cassette Unit

The cassette unit 202 can accommodate a plurality of wafer ring structures W. The cassette unit 202 includes wafer cassettes 202a, a Z-direction movement mechanism 202b, and pairs of placement portions 202c.

A plurality of (three) wafer cassettes 202a are arranged in the Z direction. Each of the wafer cassettes 202a has an accommodation space capable of accommodating a plurality of (five) wafer ring structures W. The wafer ring structure W is manually supplied and placed in the wafer cassette 202a. The wafer cassette 202a may accommodate one to four wafer ring structures W, or may accommodate six or more wafer ring structures W. Furthermore, one, two, or four or more wafer cassettes 202a may be arranged in the Z direction.

The Z-direction movement mechanism 202b moves the wafer cassettes 202a in the Z1 direction or the Z2 direction. The Z-direction movement mechanism 202b includes a linear conveyor module or a ball screw, for example. The Z-direction movement mechanism 202b also includes mounting tables 202d that support the wafer cassettes 202a from below. A plurality of (three) mounting tables 202d are arranged according to the positions of the plurality of wafer cassettes 202a.

A plurality of (five) pairs of placement portions 202c are arranged inside the wafer cassette 202a. The ring-shaped member W3 of the wafer ring structure W is placed on the pair of placement portions 202c from the Z1 direction side. One of the pair of placement portions 202c protrudes in the X2 direction from the inner surface of the wafer cassette 202a on the X1 direction side. The other of the pair of placement portions 202c protrudes in the X1 direction from the inner surface of the wafer cassette 202a on the X2 direction side.

### Lift-Up Hand Unit

The lift-up hand unit 203 can take out the wafer ring structure W from the cassette unit 202. Furthermore, the lift-up hand unit 203 can take the wafer ring structure W into the cassette unit 202.

Specifically, the lift-up hand unit 203 includes a Y-direction movement mechanism 203a and a lift-up hand 203b. The Y-direction movement mechanism 203a includes a linear conveyor module or a ball screw, for example. The lift-up hand 203b supports the ring-shaped member W3 of the wafer ring structure W from the Z2 direction side.

### Suction Hand Unit

The suction hand unit 204 suctions the ring-shaped member W3 of the wafer ring structure W from the Z1 direction side.

Specifically, the suction hand unit 204 includes an X-direction movement mechanism 204a, a Z-direction movement mechanism 204b, and a suction hand 204c. The X-direction movement mechanism 204a moves the suction hand 204c in the X direction. The Z-direction movement mechanism 204b moves the suction hand 204c in the Z direction. Each of the X-direction movement mechanism 204a and the Z-direction movement mechanism 204b includes a linear conveyor module or a ball screw, for example. The suction hand 204c suctions and supports the ring-shaped member W3 of the wafer ring structure W from the Z1 direction side. The suction hand 204c supports the ring-shaped member W3 of the wafer ring structure W by generating a negative pressure.

### Base

As shown in FIGS. 7 and 8, the base 205 is a base on which the expander 208, the cooling unit 207, the ultraviolet irradiator 212, and the squeegee unit 213 are installed. The base 205 has a rectangular shape in the plan view. In FIG. 8, the clamp unit 214 arranged on the Z1 direction side of the cooling unit 207 is indicated by dotted lines.

### Cool Air Supplier

The cool air supplier 206 supplies cool air to the sheet member W2 from the Z1 direction side when the sheet member W2 is expanded by the expander 208.

Specifically, the cool air supplier 206 includes a supplier main body 206a, a cool air supply port 206b, and a movement mechanism 206c. The cool air supply port 206b allows cool air supplied from a cool air supply device to flow out therethrough. The cool air supply port 206b is provided at an end of the supplier main body 206a on the Z2 direction side. The cool air supply port 206b is arranged in a central portion of the end of the supplier main body 206a on the Z2 direction side. The movement mechanism 206c includes a linear conveyor module or a ball screw, for example.

The cool air supply device is a device that generates cool air. The cool air supply device supplies air cooled by a cooling system such as a heat pump, for example. Such a cool air supply device is installed on the base 205. The cool air supplier 206 and the cool air supply device are connected to each other by a hose (not shown).

### Cooling Unit

The cooling unit 207 cools the sheet member W2 from the Z2 direction side.

Specifically, the cooling unit 207 includes a cooling member 207a including a cooling body 271 and a Peltier element 272, and a Z-direction movement mechanism 207b. The cooling body 271 is made of a member having a large heat capacity and a high thermal conductivity. The cooling body 271 is made of metal such as aluminum. The Peltier element 272 cools the cooling body 271. The cooling body 271 is not limited to aluminum, and may be another member having a large heat capacity and a high thermal conductivity. The Z-direction movement mechanism 207b is a cylinder.

The cooling unit 207 is movable in the Z1 direction or the Z2 direction by the Z-direction movement mechanism 207b. Thus, the cooling unit 207 is movable to a position contacting the sheet member W2 and a position spaced apart from the sheet member W2.

### Expander

The expander 208 expands the sheet member W2 of the wafer ring structure W to divide the wafer W1 along the dividing line.

Specifically, the expander 208 includes an expanding ring 281. The expanding ring 281 expands the sheet member W2 by supporting the sheet member W2 from the Z2 direction side. The expanding ring 281 has a ring shape in the plan view.

### Base

The base 209 is a base material on which the cool air supplier 206, the expansion maintaining member 210, and the heat shrinker 211 are installed.

### Expansion Maintaining Member

As shown in FIGS. 7 and 8, the expansion maintaining member 210 holds down the sheet member W2 from the Z1 direction side such that the sheet member W2 in the vicinity of the wafer W1 does not shrink due to heating by a heating ring 211a.

Specifically, the expansion maintaining member 210 includes a pressing ring 210a, a lid 210b, and an intake 210c. The pressing ring 210a has a ring shape in the plan view. The lid 210b is provided on the pressing ring 210a to cover an opening of the pressing ring 210a. The intake 210c is an intake ring having a ring shape in the plan view. A plurality of intake ports are formed in the lower surface of the intake 210c on the Z2 direction side. The pressing ring 210a is moved in the Z direction by a Z-direction movement mechanism 210d. That is, the Z-direction movement mechanism 210d moves the pressing ring 210a to a position at which the sheet member W2 is held down and a position away from the sheet member W2. The Z-direction movement mechanism 210d includes a linear conveyor module, or a ball screw and a drive including a motor with an encoder, for example.

### Heat Shrinker

The heat shrinker 211 shrinks the sheet member W2 expanded by the expander 208 by heating while maintaining the gap between the plurality of semiconductor chips Ch.

The heat shrinker 211 includes the heating ring 211a and a Z-direction movement mechanism 211b. The heating ring 211a has a ring shape in the plan view. The heating ring 211a includes a sheathed heater that heats the sheet member W2. The Z-direction movement mechanism 211b moves the heating ring 211a in the Z direction. The Z-direction movement mechanism 211b includes a linear conveyor module, or a ball screw and a drive including a motor with an encoder, for example.

### Ultraviolet Irradiator

The ultraviolet irradiator 212 emits ultraviolet rays Ut to the sheet member W2 in order to reduce the adhesive strength of the adhesive layer of the sheet member W2. Specifically, the ultraviolet irradiator 212 includes an ultraviolet illuminator. The ultraviolet irradiator 212 is arranged at an end of a press 213a of the squeegee unit 213, which is described below, on the Z1 direction side. The ultraviolet irradiator 212 emits the ultraviolet rays Ut to the sheet member W2 while moving together with the squeegee unit 213.

### Squeegee Unit

The squeegee unit 213 further divides the wafer W1 along the modified layer Wm by locally pressing the wafer W1 from the Z2 direction side after the sheet member W2 is expanded. Specifically, the squeegee unit 213 includes the press 213a, a Z-direction movement mechanism 213b, an X-direction movement mechanism 213c, and a rotation mechanism 213d.

The press 213a generates a bending stress in the wafer W1 to divide the wafer W1 along the modified layer Wm by being moved by the rotation mechanism 213d and the X-direction movement mechanism 213c while pressing the wafer W1 from the Z2 direction side via the sheet member W2. The press 213a presses the wafer W1 via the sheet member W2 by being raised to a raised position on the Z1 direction side by the Z-direction movement mechanism 213b. When the press 213a is lowered to a lowered position on the Z2 direction side by the Z-direction movement mechanism 213b, the wafer W1 is no longer pressed. The press 213a is a squeegee.

The press 213a is attached to an end of the Z-direction movement mechanism 213b on the Z1 direction side. The Z-direction movement mechanism 213b linearly moves the press 213a in the Z1 direction or the Z2 direction. The Z-direction movement mechanism 213b is a cylinder, for example. The Z-direction movement mechanism 213b is attached to an end of the X-direction movement mechanism 213c on the Z1 direction side.

The X-direction movement mechanism 213c is attached to an end of the rotation mechanism 213d on the Z1 direction side. The X-direction movement mechanism 213c linearly moves the press 213a in one direction. The X-direction movement mechanism 213c includes a linear conveyor module, or a ball screw and a drive including a motor with an encoder, for example.

In the squeegee unit 213, the press 213a is raised to the raised position by the Z-direction movement mechanism 213b. In the squeegee unit 213, the press 213a is moved in the Y direction by the X-direction movement mechanism 213c while locally pressing the wafer W1 from the Z2 direction side via the sheet member W2 such that the wafer W1 is divided. In the squeegee unit 213, the press 213a is lowered to the lowered position by the Z-direction movement mechanism 213b. In the squeegee unit 213, after the press 213a finishes moving in the Y direction, the press 213a is rotated 90 degrees by the rotation mechanism 213d.

In the squeegee unit 213, the press 213a is raised to the raised position by the Z-direction movement mechanism 213b. In the squeegee unit 213, after the press 213a is rotated 90 degrees, the press 213a is moved in the X direction by the X-direction movement mechanism 213c while locally pressing the wafer W1 from the Z2 direction side via the sheet member W2 such that the wafer W1 is divided.

### Clamp Unit

The clamp unit 214 holds the ring-shaped member W3 of the wafer ring structure W. Specifically, the clamp unit 214 includes a gripper 214a, a Z-direction movement mechanism 214b, and a Y-direction movement mechanism 214c. The gripper 214a supports the ring-shaped member W3 from the Z2 direction side and holds down the ring-shaped member W3 from the Z1 direction side. Thus, the ring-shaped member W3 is held by the gripper 214a. The gripper 214a is attached to the Z-direction movement mechanism 214b.

The Z-direction movement mechanism 214b moves the clamp unit 214 in the Z direction. Specifically, the Z-direction movement mechanism 214b moves the gripper 214a in the Z1 direction or the Z2 direction. The Z-direction movement mechanism 214b includes a linear conveyor module, or a ball screw and a drive including a motor with an encoder, for example. The Z-direction movement mechanism 214b is attached to the Y-direction movement mechanism 214c. The Y-direction movement mechanism 214c moves the Z-direction movement mechanism 214b in the Y1 direction or the Y2 direction. The Y-direction movement mechanism 214c includes a linear conveyor module, or a ball screw and a drive including a motor with an encoder, for example.

### Control Configuration of Semiconductor Wafer Processing Apparatus

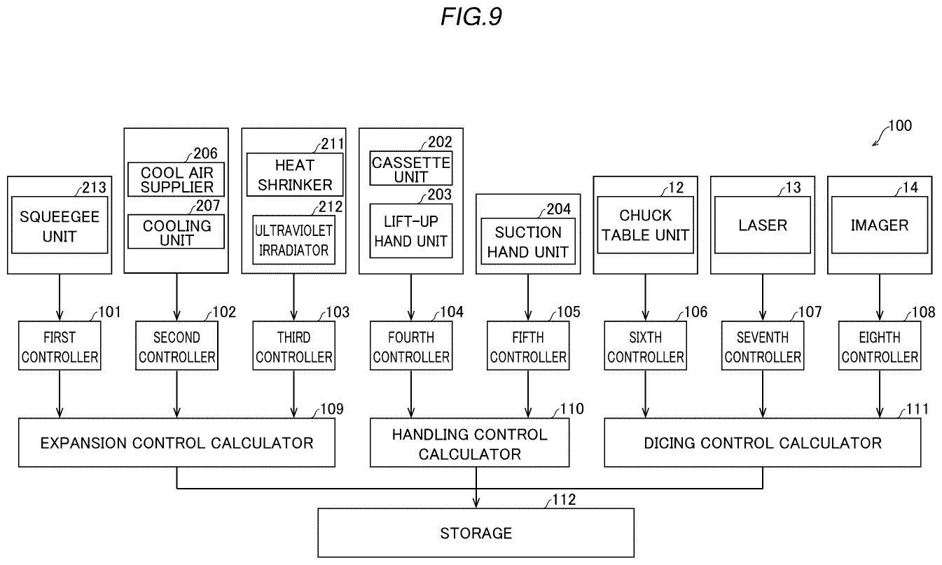

As shown in FIG. 9, the semiconductor wafer processing apparatus 100 includes a first controller 101, a second controller 102, a third controller 103, a fourth controller 104, a fifth controller 105, a sixth controller 106, a seventh controller 107, an eighth controller 108, an expansion control calculator 109, a handling control calculator 110, a dicing control calculator 111, and a storage 112. The dicing control calculator 111 is an example of a “controller” in the claims.

The first controller 101 controls the squeegee unit 213. The first controller 101 includes a central processing unit (CPU) and a storage including a read-only memory (ROM) and a random access memory (RAM), for example. The first controller 101 may include, as a storage, a hard disk drive (HDD) that retains stored information even after the voltage is cut off, for example. The HDD may be provided in common for the first controller 101, the second controller 102, the third controller 103, the fourth controller 104, the fifth controller 105, the sixth controller 106, the seventh controller 107, and the eighth controller 108.

The second controller 102 controls the cool air supplier 206 and the cooling unit 207. The second controller 102 includes a CPU and a storage including a ROM and a RAM, for example. The third controller 103 controls the heat shrinker 211 and the ultraviolet irradiator 212. The third controller 103 includes a CPU and a storage including a ROM and a RAM, for example. The second controller 102 and the third controller 103 may include, as a storage, an HDD that retains stored information even after the voltage is cut off.

The fourth controller 104 controls the cassette unit 202 and the lift-up hand unit 203. The fourth controller 104 includes a CPU and a storage including a ROM and a RAM, for example. The fifth controller 105 controls the suction hand unit 204. The fifth controller 105 includes a CPU and a storage including a ROM and a RAM, for example. The fourth controller 104 and the fifth controller 105 may include, as a storage, an HDD that retains stored information even after the voltage is cut off, for example.

The sixth controller 106 controls the chuck table unit 12. The sixth controller 106 includes a CPU and a storage including a ROM and a RAM, for example. The seventh controller 107 controls the laser 13. The seventh controller 107 includes a CPU and a storage including a ROM and a RAM, for example. The eighth controller 108 controls the imager 14. The eighth controller 108 includes a CPU and a storage including a ROM and a RAM, for example. The sixth controller 106, the seventh controller 107, and the eighth controller 108 may include, as a storage, an HDD that retains stored information even after the voltage is cut off, for example.

The expansion control calculator 109 performs calculations regarding a process to expand the sheet member W2 based on the processing results of the first controller 101, the second controller 102, and the third controller 103. The expansion control calculator 109 includes a CPU and a storage including a ROM and a RAM, for example.

The handling control calculator 110 performs calculations regarding a process to move the wafer ring structure W based on the processing results of the fourth controller 104 and the fifth controller 105. The handling control calculator 110 includes a CPU and a storage including a ROM and a RAM, for example.

The dicing control calculator 111 performs calculations regarding a process to dice the wafer W1 based on the processing results of the sixth controller 106, the seventh controller 107, and the eighth controller 108. The dicing control calculator 111 includes a CPU and a storage including a ROM and a RAM, for example. The configuration of the dicing control calculator 111 is described in detail below.

The storage 112 stores programs for operating the dicing device 1 and the expanding device 2. The storage 112 includes a ROM, a RAM, and an HDD, for example.

### Semiconductor Chip Manufacturing Process

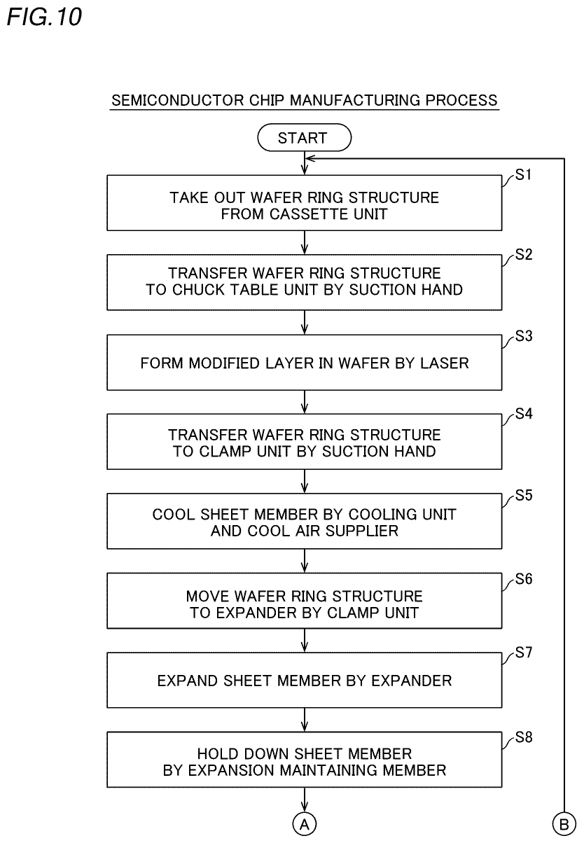

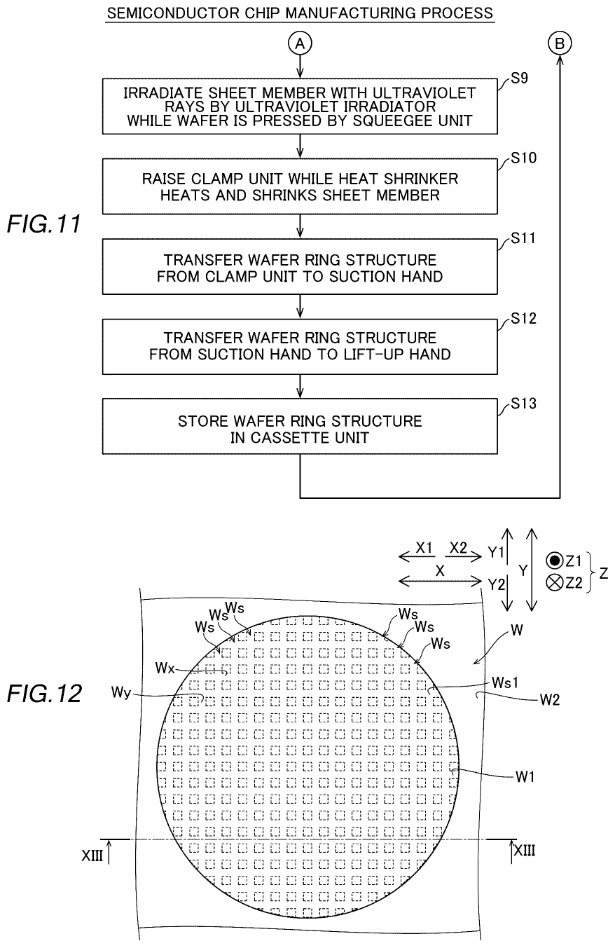

The overall operation of the semiconductor wafer processing apparatus 100 is described below with reference to FIGS. 10 and 11.

In step S1, the wafer ring structure W is taken out from the cassette unit 202. That is, after the wafer ring structure W stored in the cassette unit 202 is supported by the lift-up hand 203b, the lift-up hand 203b is moved in the Y1 direction by the Y-direction movement mechanism 203a such that the wafer ring structure W is taken out from the cassette unit 202. In step S2, the wafer ring structure W is transferred to the chuck table unit 12 of the dicing device 1 by the suction hand 204c. That is, the wafer ring structure W taken out from the cassette unit 202 is moved in the X2 direction by the X-direction movement mechanism 204a while being suctioned by the suction hand 204c. The wafer ring structure W that has been moved in the X2 direction is transferred from the suction hand 204c to the chuck table unit 12 and then held by the chuck table unit 12.

In step S3, a modified layer Wm is formed in the wafer W1 by the laser 13. In step S4, the wafer ring structure W including the wafer W1 in which the modified layer Wm has been formed is transferred to the clamp unit 214 by the suction hand 204c. In step S5, the sheet member W2 is cooled by the cool air supplier 206 and the cooling unit 207. That is, the wafer ring structure W held by the clamp unit 214 is moved (lowered) in the Z2 direction by the Z-direction movement mechanism 214b to contact the cooling unit 207, and the cool air supplier 206 supplies cool air from the Z1 direction side to cool the sheet member W2.

In step S6, the wafer ring structure W is moved to the expander 208 by the clamp unit 214. That is, the wafer ring structure W with the cooled sheet member W2 is moved in the Y1 direction by the Y-direction movement mechanism 214c while being held by the clamp unit 214. In step S7, the sheet member W2 is expanded by the expander 208. That is, the wafer ring structure W is moved in the Z2 direction by the Z-direction movement mechanism 214b while being held by the clamp unit 214. Then, the sheet member W2 contacts the expanding ring 281 and is expanded by being pulled by the expanding ring 281. Thus, the wafer W1 is divided along the dividing line (modified layer Wm).

In step S8, the expanded sheet member W2 is held down from the Z1 direction side by the expansion maintaining member 210. That is, the pressing ring 210a is moved (lowered) in the Z2 direction by the Z-direction movement mechanism 210d until it contacts the sheet member W2. Then, the process advances from a point A in FIG. 10 through a point A in FIG. 11 to step S9.

As shown in FIG. 11, in step S9, after the sheet member W2 is held down by the expansion maintaining member 210, the sheet member W2 is irradiated with ultraviolet rays Ut by the ultraviolet irradiator 212 while the wafer W1 is pressed by the squeegee unit 213. Thus, the wafer W1 is further divided by the squeegee unit 213. In addition, the adhesive strength of the sheet member W2 is reduced by the ultraviolet rays Ut emitted from the ultraviolet irradiator 212.

In step S10, while the heat shrinker 211 heats and shrinks the sheet member W2, the clamp unit 214 is raised. At this time, the intake 210c takes in air in the vicinity of the heated sheet member W2. In step S11, the wafer ring structure W is transferred from the clamp unit 214 to the suction hand 204c. That is, the wafer ring structure W is moved in the Y2 direction by the Y-direction movement mechanism 214c while being held by the clamp unit 214. Then, the wafer ring structure W is suctioned by the suction hand 204c after the holding by the clamp unit 214 is released on the Z1 direction side of the cooling unit 207.

In step S12, the wafer ring structure W is transferred to the lift-up hand 203b by the suction hand 204c. In step S13, the wafer ring structure W is stored in the cassette unit 202. That is, the wafer ring structure W supported by the lift-up hand 203b is moved in the Y1 direction by the Y-direction movement mechanism 203a to be stored in the cassette unit 202. Thus, the process performed on one wafer ring structure W is terminated. Then, the process returns from a point B in FIG. 11 through a point B in FIG. 10 to step S1.

### Detailed Configuration of Chuck Table Unit, Laser, and Imager

The detailed configuration of the chuck table unit 12, the laser 13, and the imager 14 is described below.

As shown in FIGS. 12 and 13, in the dicing device 1, the laser L is emitted from the laser irradiator 13a along the street Ws to partition the semiconductor chips (integrated circuits) Ch formed on the wafer W1, and the modified layer Wm that serves as a starting point for dividing the wafer W1 is formed inside the wafer W1 along the street Ws. In the wafer W1 in which the modified layer Wm is formed, cracks Wc are generated from the modified layer Wm in the Z1 and Z2 directions. When the cracks Wc reach a surface of the wafer W1 on the Z1 direction side, the wafer W1 becomes more likely to be divided by the modified layer Wm.

A plurality of streets Ws are set in advance for the wafer W1. That is, the streets Ws are set based on the size of the semiconductor chip Ch, the size of the modified layer Wm to be formed in the wafer W1 by the laser L, and a distance from the modified layer Wm to the semiconductor chip Ch, for example. The streets Ws include an X-direction street Wx extending in the X-direction and a Y-direction street Wy extending in the Y-direction.

As shown in FIGS. 13 and 14, the chuck table unit 12 moves the wafer W1 in a Df direction while holding the wafer W1. The Df direction is a processing direction in which the chuck table unit 12 moves the wafer W1 for processing to form the modified layer Wm in the wafer W1.

That is, in the dicing device 1, while the wafer ring structure W is held by the suction unit 12a and the clamp unit 12b, the laser L is emitted from the laser irradiator 13a, and the chuck table unit 12 is moved along the X1 direction or the X2 direction as the Df direction by the X-direction movement mechanism 121 such that the modified layer Wm is formed at the X-direction street Wx.

In the dicing device 1, while the wafer ring structure W is held by the suction unit 12a and the clamp unit 12b, the chuck table unit 12 is moved along the Y1 direction to the next X-direction street Wx adjacent on the Y1-direction side by the Y-direction movement mechanism 122, and then the modified layer Wm is formed at the next X-direction street Wx by the method described above.

These steps are repeated such that modified layers Wm are formed at a plurality of X-direction streets Wx aligned in the Y-direction. After the wafer W1 is rotated 90 degrees by the rotation mechanism 12c, the same method is repeated for the Y-direction streets Wy.

Thus, the laser irradiator 13a forms the modified layer Wm in the wafer W1 by emitting the laser L in the Df direction extending along each of the plurality of streets Ws of the wafer W1. At this time, the wafer W1 is moved in the Df direction relative to the laser irradiator 13a by the chuck table unit 12, while the laser irradiator 13a is positioned in the horizontal direction.

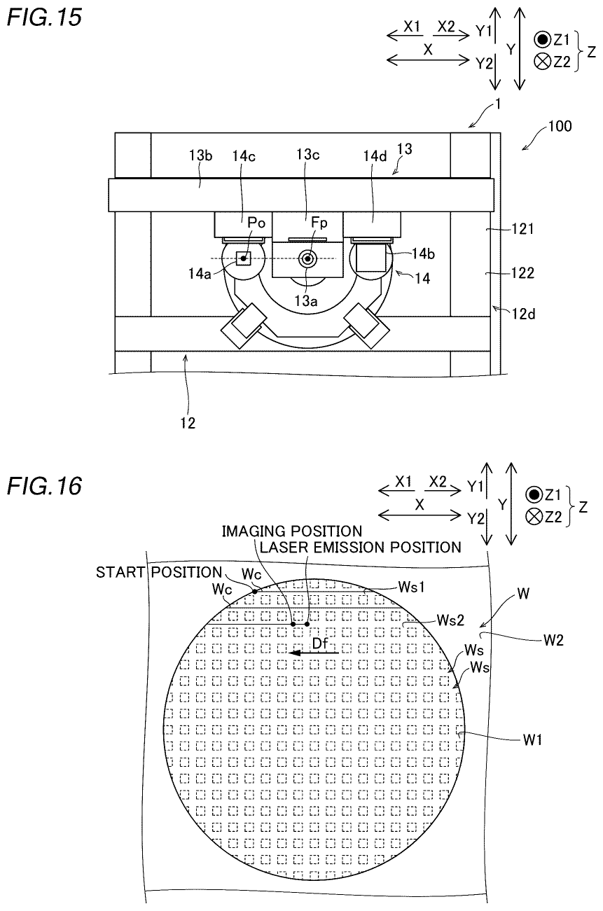

As shown in FIGS. 14 and 15, the high-resolution camera 14a can image the wafer W1 in which the modified layer Wm has been formed. The high-resolution camera 14a is fixed in position in the horizontal direction and images the wafer W1 in which the modified layer Wm has been formed by the laser L emitted from the laser irradiator 13a while the wafer W1 is moved in the Df direction by the chuck table unit 12.

Both the high-resolution camera 14a and the laser irradiator 13a are mounted to the shared mounting member 13b. The mounting member 13b is fixed in position in the horizontal direction and the upward-downward direction. Furthermore, the high-resolution camera 14a and the laser irradiator 13a are fixed in position in the horizontal direction and mounted to the mounting member 13b. The high-resolution camera 14a and the laser irradiator 13a are mounted to the mounting member 13b so as to be movable in the Z direction.

The high-resolution camera 14a is mounted to the mounting member 13b together with the laser irradiator 13a with the focal position Fp of the laser L from the laser irradiator 13a and the optical center Po of the high-resolution camera 14a aligned along the Df direction in the plan view. The high-resolution camera 14a is arranged on the X1 direction side with respect to the laser irradiator 13a in the plan view.

As described above, the high-resolution camera 14a has a higher resolution than the wide-angle camera 14b. The wide-angle camera 14b is mounted to the mounting member 13b together with the high-resolution camera 14a and the laser irradiator 13a. The wide-angle camera 14b has a function of imaging an alignment mark on the wafer W1.

### Detailed Configuration of Dicing Control Calculator

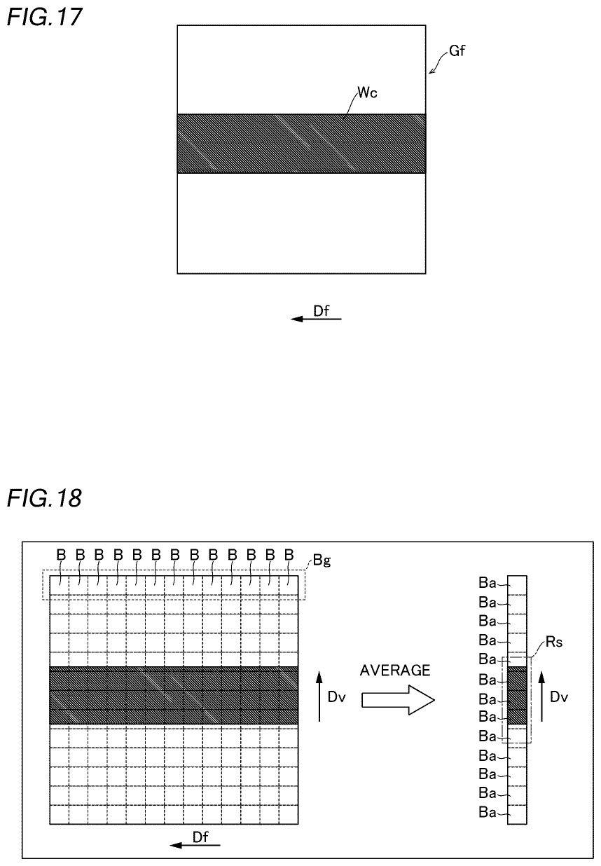

As shown in FIGS. 16 and 17, the dicing control calculator 111 according to the first embodiment inspects whether or not the modified layer Wm is properly formed based on the crack Wc on the surface on the Z1 direction side caused by the modified layer Wm. The inspection includes a first inspection and a second inspection. The first inspection is performed while the modified layer Wm is formed in the wafer W1. The second inspection is performed after the formation of the modified layer Wm in the wafer W1 is completed. The first inspection and the second inspection are performed based on images captured by the high-resolution camera 14a.

### First Inspection

The dicing control calculator 111 performs a control to continue to expose the high-resolution camera 14a to light with respect to a preset portion of a predetermined street Ws1 of the plurality of streets Ws while forming the modified layer Wm in the wafer W1 by the laser L along the Df direction at the predetermined street Ws1 to create a panning image Gf. The panning image Gf is an image captured by the high-resolution camera 14a and used in the first inspection. The panning image Gf is an image acquired by continuing exposure to light while the preset portion of the predetermined street Ws1 is imaged.

The preset portion may be, for example, the entirety of the predetermined street Ws1, or a portion (such as an end on the X1 direction side, an end on the X2 direction side, or an intermediate portion in the X direction) of the predetermined street Ws1.

As shown in FIG. 16 as an example, a case is described below in which the start position of processing to form the modified layer Wm in the wafer W1 is an X1-direction end of the predetermined street Ws1 located closest to the Y1 direction side. Furthermore, it is assumed that a current position at which processing to form the modified layer Wm in the wafer W1 is being performed is a predetermined street Ws2 that is located two streets away from the predetermined street Ws1 in the Y2 direction.

Specifically, as shown in FIGS. 17 and 18, the dicing control calculator 111 performs a control to perform the first inspection to inspect whether the processing of the modified layer Wm by the laser L is bad or not based on a plurality of average luminance values Ba acquired for respective pixel groups Bg by averaging the luminance values (pixel values) of a plurality of pixels B included in a plurality of pixel groups Bg of the panning image Gf. The pixel group Bg includes a plurality of pixels B of the panning image Gf aligned in the Df direction. A plurality of pixel groups Bg are aligned in the Dv direction. The Dv direction is a direction perpendicular to the Df direction in the horizontal direction. The plurality of average luminance values Ba are luminance values acquired corresponding to the positions of the plurality of pixel groups Bg in the panning image Gf in the Dv direction. In addition, in the right diagram of FIG. 18, a plurality of average luminance values Ba of a cracked portion are shown by hatching a plurality of rectangles aligned in the Dv direction so as to be able to be visually understood.

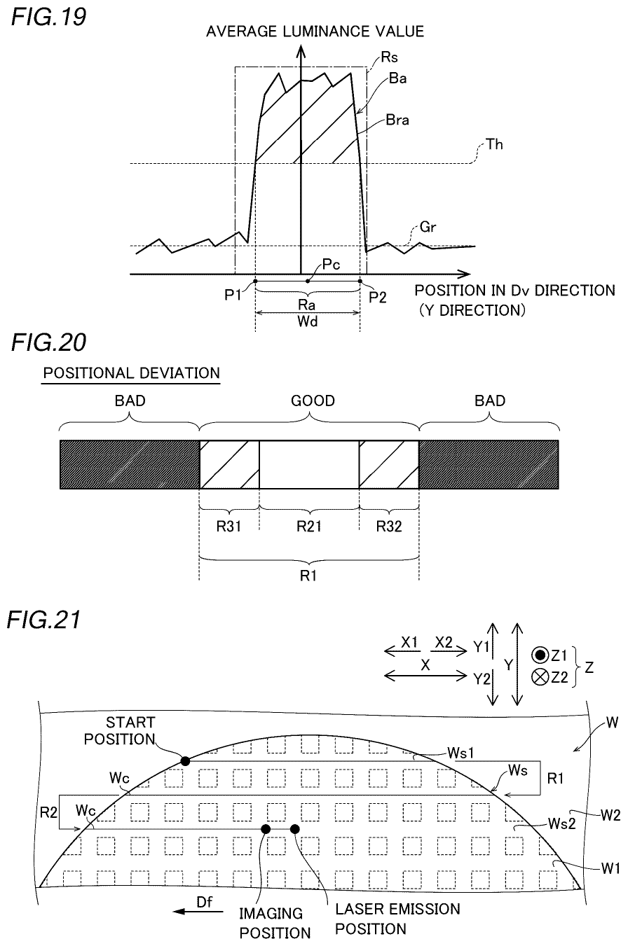

As shown in FIGS. 18 and 19, the dicing control calculator 111 performs a control to acquire a plurality of crack luminance values Bra aligned in the Dv direction that are equal to or greater than a preset threshold Th, and a position range Ra in the Dv direction of the plurality of pixel groups Bg having the plurality of crack luminance values Bra based on average luminance values Ba within a position range Rs of the predetermined street Ws1 among the plurality of average luminance values Ba aligned in the Dv direction and the threshold Th.

FIG. 19 shows the position in the Dv direction (Y direction) of the pixel group Bg corresponding to each of the plurality of average luminance values Ba in the panning image Gf, and the magnitude of the average luminance value Ba corresponding to each position in the Dv direction. On the vertical axis of the graph in FIG. 19, as the average luminance value Ba approaches the lower limit, the color is closer to white, and as the average luminance value Ba approaches the upper limit, the color is closer to black.

The position range Rs corresponding to the position of the predetermined street Ws1 is set in advance by a user based on the width of each of the plurality of streets Ws in the Dv direction, for example. The threshold Th is set for each panning image Gf.

That is, the threshold Th is set by adding a set value preset by the user to a reference value Gr (ground level) acquired for each panning image Gf. The reference value Gr is set by the average value of all of the lower limit average luminance values Ba of the panning image Gf, the average value of some (such as ⅓ or ⅔) of the lower limit average luminance values Ba, or the minimum value of the lower limit average luminance values Ba, for example.

In the first inspection, the positional deviation, the brightness, the width, the number of cracks Wc, etc. are inspected.

Specifically, as shown in FIG. 19, the dicing control calculator 111 performs a control to acquire the amount of positional deviation of the crack Wc formed due to the modified layer Wm based on a difference between the center position Pc of the position range Ra of the plurality of crack luminance values Bra and a preset reference position, and perform the first inspection. The reference position is the center position of the predetermined street Ws1 in the Dv direction. Thus, in the first inspection, the positional deviation in the Dv direction (Y direction) of the focal position Fp of the laser L of the laser irradiator 13a on the wafer W1 is inspected. The center position Pc is an example of a “position within the position range of the plurality of crack luminance values” in the claims.

The dicing control calculator 111 performs a control to perform the first inspection to inspect whether the size of the crack Wc formed due to the modified layer Wm is appropriate or not based on a comparison between the average value of the plurality of crack luminance values Bra and a preset reference average luminance value range. Thus, in the first inspection, it is identified whether or not the crack Wc is sufficiently formed based on the brightness based on the average value of the plurality of crack luminance values Bra. When the crack Wc is not sufficiently formed, it is identified that the modified layer Wm is not properly formed.

The dicing control calculator 111 also performs a control to perform the first inspection to inspect whether the size of the crack Wc formed due to the modified layer Wm is appropriate or not based on a comparison between the width Wd as the position range Ra of the plurality of crack luminance values Bra and a preset reference width range. Thus, in the first inspection, it is identified whether the crack Wc is inclined or curved based on the width Wd. When the crack Wc is inclined or curved, it is identified that the modified layer Wm is not properly formed.

The dicing control calculator 111 also performs a control to perform the first inspection to inspect whether or not a plurality of widths Wd are acquired as position ranges Ra of the plurality of crack luminance values Bra. Thus, in the first inspection, it is identified whether or not a plurality of cracks Wc are formed based on the width Wd. When a plurality of cracks Wc are formed, it is identified that an unexpected defect has occurred.

The dicing control calculator 111 performs a control to notify an operator when the inspection result of the first inspection based on the plurality of crack luminance values Bra is bad.

### Positional Deviation

As shown in FIG. 20, the dicing control calculator 111 performs a control to notify the operator when in the first inspection, the amount of positional deviation is outside an allowable range R1, or the number of times that the amount of positional deviation is outside a non-additive range R21 in the allowable range R1 and is within the allowable range R1 exceeds a first predetermined number of times. A range in which the amount of positional deviation is outside the non-additive range R21 in the allowable range R1 and is within the allowable range R1 includes a warning range R31 and a warning range R32.

When the amount of positional deviation is outside the allowable range R1, the wafer ring structure W including a semiconductor chip Ch at a location at which the positional deviation has been identified cannot be supplied to the next process (such as bonding), and thus the wafer W1 is discarded, the wafer W1 is reprocessed, or the operator re-inspects the wafer W1 using a microscope or the like.

When the number of times that the amount of positional deviation is within the warning range R31 or R32 is less than the first predetermined number of times, the positional deviation is automatically corrected in the dicing device 1. When the number of times that the amount of positional deviation is within the warning range R31 or R32 exceeds the first predetermined number of times, the operator is notified of an instruction to manually correct the positional deviation. When the amount of positional deviation is within the warning range R31 and the warning range R32, the inspection result of the first inspection is good until the first predetermined number of times is exceeded.

As shown in FIG. 21, the dicing control calculator 111 performs a control to correct a deviation of the focal position Fp of the laser L in the Dv direction based on the amount of positional deviation before processing of the modified layer Wm by the laser L at the street Ws after the street Ws next to the predetermined street Ws1 on which the plurality of average luminance values Ba have been acquired.

Specifically, the dicing control calculator 111 performs a control to correct a deviation of the focal position Fp of the laser L in the Dv direction based on the amount of positional deviation before processing of the modified layer Wm by the laser L at the predetermined street Ws2 after the street Ws next to the predetermined street Ws1 on which the plurality of average luminance values Ba have been acquired.

That is, the dicing control calculator 111 performs a control to capture the panning image Gf of the crack Wc at the predetermined street Ws1. At the street Ws next to the predetermined street Ws1, the dicing control calculator 111 performs a control to perform the first inspection on the panning image Gf captured at the predetermined street Ws1. When the amount of positional deviation in the first inspection at the next street Ws is within the warning range R31 or R32, the dicing control calculator 111 performs a control to adjust the amount of movement of the chuck table unit 12 in the Y direction by an amount by which the amount of positional deviation is corrected when a movement from the next street Ws to the next-next predetermined street Ws2 via a route R is made.

### Brightness

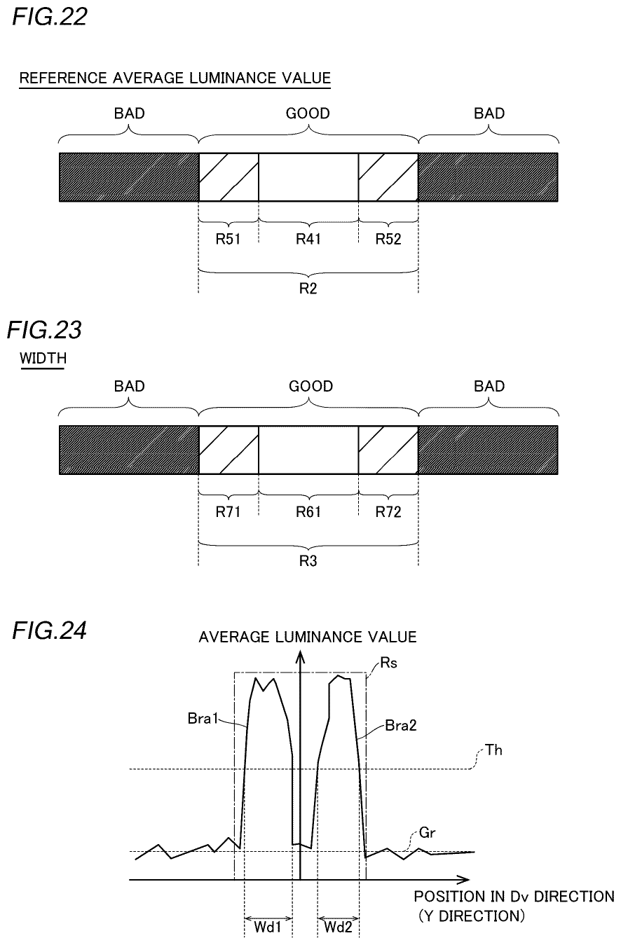

As shown in FIG. 22, the dicing control calculator 111 performs a control to notify the operator when in the first inspection, the average value of the plurality of crack luminance values Bra is outside an allowable range R2, or the number of times that the average value of the plurality of crack luminance values Bra is outside a non-additive range R41 in the allowable range R2 and is within the allowable range R2 exceeds a second predetermined number of times. A range in which the amount of positional deviation is outside the non-additive range R41 in the allowable range R2 and is within the allowable range R2 includes a warning range R51 and a warning range R52. Each of the allowable range R2, the non-additive range R41, the warning range R51, and the warning range R52 is a reference average luminance value range.

When the average value of the plurality of crack luminance values Bra is outside the allowable range R2, the wafer ring structure W including a semiconductor chip Ch at a location at which the bad average value of the plurality of crack luminance values Bra has been identified cannot be supplied to the next process (such as bonding), and thus the wafer W1 is discarded, the wafer W1 is reprocessed, or the operator re-inspects the wafer W1 using a microscope or the like.

When the number of times that the average value of the plurality of crack luminance values Bra is within the warning range R51 or R52 is less than the second predetermined number of times, the laser irradiator 13a is automatically corrected in the dicing device 1. When the number of times that the average value of the plurality of crack luminance values Bra is within the warning range R51 or R52 exceeds the second predetermined number of times, the operator is notified of an instruction to manually correct the laser irradiator 13a. When the average value of the plurality of crack luminance values Bra is within the warning range R51 and the warning range R52, the inspection result of the first inspection is good until the second predetermined number of times is exceeded.

### Width

As shown in FIG. 23, the dicing control calculator 111 performs a control to notify the operator when in the first inspection, the width Wd as the position range Ra of the plurality of crack luminance values Bra is outside an allowable range R3, or the number of times that the width Wd as the position range Ra of the plurality of crack luminance values Bra is outside a non-additive range R61 in the allowable range R3 and is within the allowable range R3 exceeds a third predetermined number of times. A range in which the width Wd is outside the non-additive range R61 in the allowable range R3 and is within the allowable range R3 includes a warning range R71 and a warning range R72. Each of the allowable range R3, the non-additive range R61, the warning range R71, and the warning range R72 is a reference width range.

When the width Wd as the position range Ra of the plurality of crack luminance values Bra is outside the allowable range R3, the wafer ring structure W including a semiconductor chip Ch at a location at which the bad width Wd as the position range Ra of the plurality of crack luminance values Bra has been identified cannot be supplied to the next process (such as bonding), and thus the wafer W1 is discarded, the wafer W1 is reprocessed, or the operator re-inspects the wafer W1 using a microscope or the like.

When the number of times that the width Wd as the position range Ra of the plurality of crack luminance values Bra is within the warning range R71 or R72 is less than the third predetermined number of times, the laser irradiator 13a is automatically corrected in the dicing device 1. When the number of times that the width Wd as the position range Ra of the plurality of crack luminance values Bra is within the warning range R71 or R72 exceeds the third predetermined number of times, the operator is notified of an instruction to manually correct the laser irradiator 13a. When the width Wd as the position range Ra of the plurality of crack luminance values Bra is within the warning range R71 and the warning range R72, the inspection result of the first inspection is good until the third predetermined number of times is exceeded.

### Number of Cracks

As shown in FIG. 24, when a plurality of widths Wd are acquired as the position range Ra of the plurality of crack luminance values Bra in the first inspection, the dicing control calculator 111 performs a control to notify the operator that an unexpected defect has occurred. For example, when two widths Wd1 and Wd2 are acquired in the first inspection, the dicing control calculator 111 performs a control to notify the operator that an unexpected defect has occurred.

The illumination intensity of the high-resolution camera 14a for performing the first inspection described above is automatically set. That is, the dicing control calculator 111 performs a control to acquire the illumination intensity for performing the first inspection based on the exposure time for performing the first inspection and the exposure time and illumination intensity for performing the second inspection.

The exposure time for performing the first inspection is a time preset for the high-resolution camera 14a to image a preset portion of the predetermined street Ws1 with the high-resolution camera 14a while forming the modified layer Wm in the wafer W1 by emitting the laser L along the Df direction. The exposure time and illumination intensity for performing the second inspection are each determined by a time preset for the high-resolution camera 14a to inspect the cracks Wc formed due to the modified layer Wm after forming the modified layer Wm at all of the plurality of streets Ws. The illumination intensity for performing the first inspection is the brightness of the illumination to image the preset portion of the predetermined street Ws1 with the high-resolution camera 14a while forming the modified layer Wm in the wafer W1 by the laser L along the Df direction.

### Second Inspection

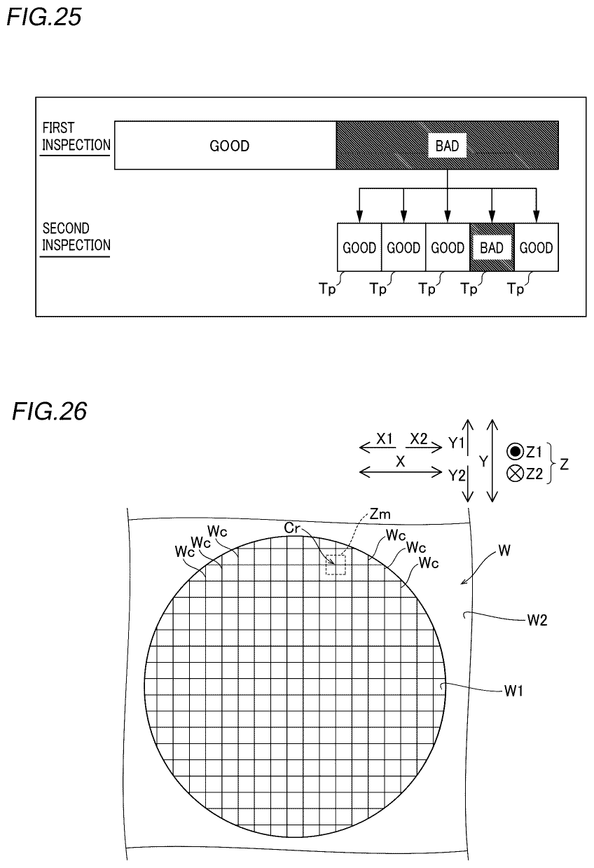

As shown in FIG. 25, the second inspection performed in the dicing control calculator 111 requires more inspection time than the first inspection due to the need to inspect the cracks Wc in more detail, and thus the inspection time is to be shortened. The shortening of the inspection time is achieved by minimizing the number of objects to be inspected in the second inspection.

The dicing control calculator 111 makes a setting to perform the second inspection to re-inspect whether the cracks Wc formed due to the modified layer Wm are bad or not after the modified layer Wm is formed at all of the plurality of streets Ws of the wafer W1, based on the inspection result indicating that the processing of the modified layer Wm is bad among the inspection results of the first inspection for the plurality of streets Ws.

Specifically, the dicing control calculator 111 performs a control to make a setting to perform the second inspection on the street Ws for which it is identified that the inspection result of the first inspection is bad among the plurality of streets Ws. In other words, the dicing control calculator 111 performs a control to perform the second inspection on a plurality of inspection points Tp set on the street Ws identified as bad.

### Details of Second Inspection

Details of the second inspection are described below.

As shown in FIG. 26, the second inspection is performed on the shape of the crack Wc in the vicinity of an intersection Cr between the cracks Wc of the wafer W1 in which the modified layer Wm is formed at all of the streets Ws of the wafer W1. The second inspection is performed on the street Ws including an intersection Cr for which it is identified that the result of the first inspection is bad among a plurality of intersections Cr between the cracks Wc of the wafer W1. Thus, the second inspection is performed on some, but not all, of the intersections Cr.

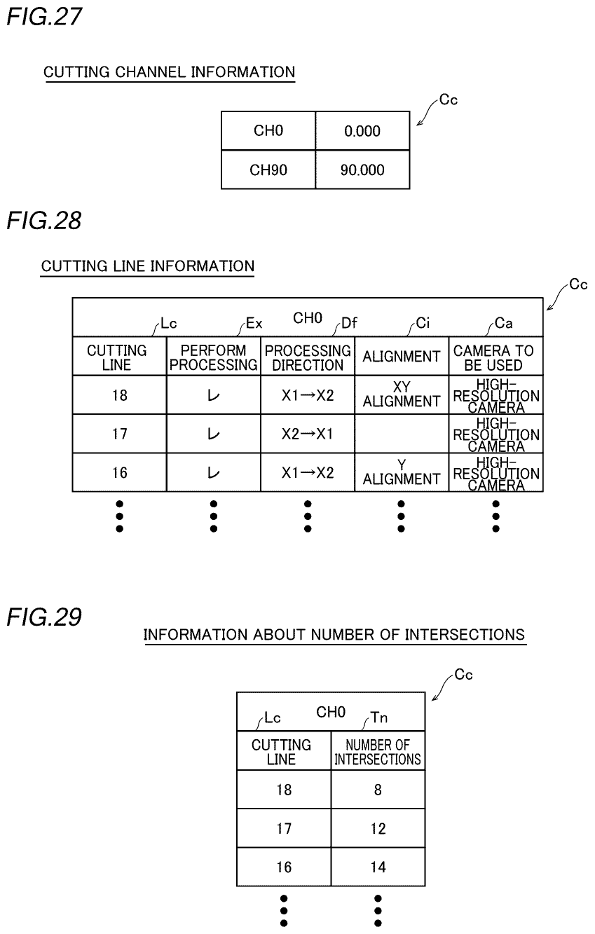

As shown in FIGS. 27 and 28, the dicing control calculator 111 performs a control to add numbers to parallel cutting lines Lc included in a cutting channel Cc. The cutting channel Cc indicates the state of the wafer W1 when processing is performed to form the modified layer Wm along the Df direction at the X-direction street Wx of the wafer W1. That is, the state of the wafer W1 when processing is performed to form the modified layer Wm along the Df direction at the X-direction street Wx of the wafer W1 is a state in which the cutting channel Cc is 0. In addition, the state of the wafer W1 when processing is performed to form the modified layer Wm along the Df direction at the Y-direction street Wy of the wafer W1 after the wafer W1 is rotated by 90 degrees by the rotation mechanism 12c is a state in which the cutting channel Cc is 90. The cutting line Lc indicates the crack Wc formed at the plurality of streets Ws.

For example, a plurality of cutting lines Lc are registered in the cutting channel Cc. In the cutting channel Cc, for each of the plurality of cutting lines Lc, information about whether or not to perform processing to form a modified layer Wm, about the Df direction when forming the modified layer Wm, about whether or not to perform alignment Ci before performing processing to form the modified layer Wm, and about the camera Ca to be used when performing processing to form the modified layer Wm are registered.

As shown in FIG. 29, the total number Tn of intersections Cr on the plurality of cutting lines Lc is registered in the cutting channel Cc.

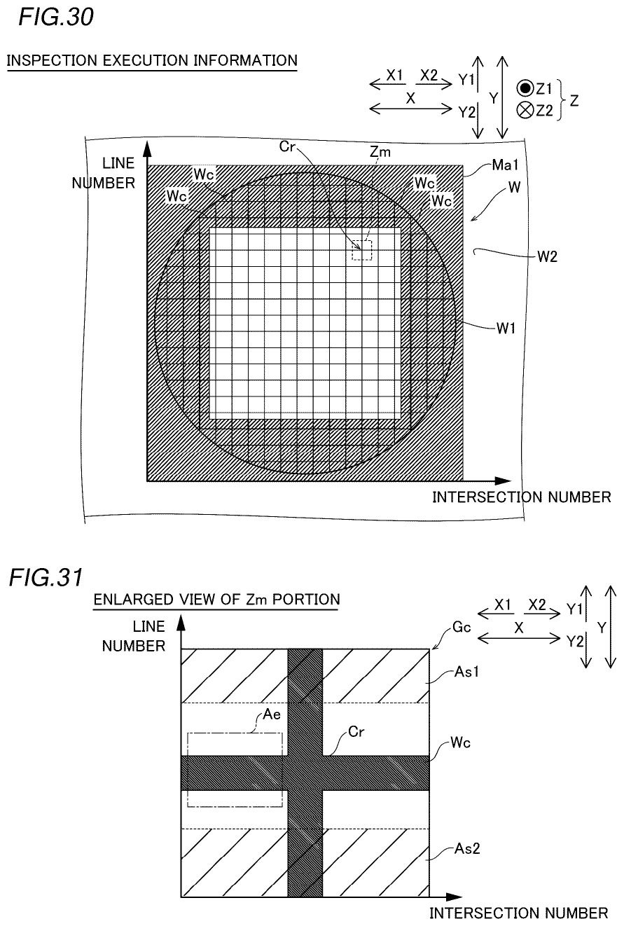

As shown in FIG. 30, the dicing control calculator 111 performs a control to acquire, based on a mask area Mal, intersections Cr that are located inside the outer edge of the wafer W1 in the radial direction among the plurality of intersections Cr between the cracks Wc of the wafer W1. The acquired inner intersections Cr are between upper and lower limit values set on an intersection number axis extending in the X direction, and between upper and lower limit values set on a line number axis extending in the Y direction. The acquired inner intersections Cr may be intersections Cr radially inward of the wafer W1.

As shown in FIG. 31, the dicing control calculator 111 performs a control to perform the second inspection for the crack Wc based on an intersection image Gc including the acquired intersection Cr and the vicinity of the intersection Cr. The dicing control calculator 111 performs a control to acquire, based on a designated area As1 and a designated area As2 that are set in advance, a designated portion between the designated area As1 and the designated area As2 of the intersection image Gc. After acquiring the designated portion, the dicing control calculator 111 performs a control to acquire a portion of the intersection image Gc within an identification frame Ae based on the identification frame Ae for identifying whether the crack Wc is bad or not.

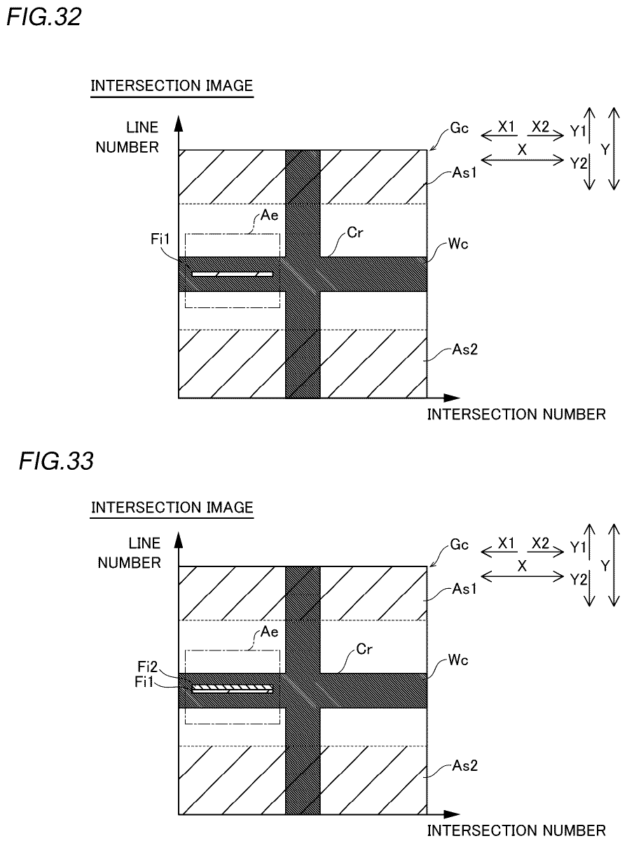

As shown in FIG. 32, the dicing control calculator 111 performs a control to acquire the center point of a crack Wc portion in the identification frame Ae of the intersection image Gc and the X-direction size and Y-direction size of the crack Wc portion in the identification frame Ae of the intersection image Gc based on the crack Wc portion in the identification frame Ae of the intersection image Gc. The dicing control calculator 111 performs a control to superimpose an identification figure Fi1 on the crack Wc portion in the identification frame Ae of the intersection image Gc by aligning the center point of the crack Wc portion in the identification frame Ae with the center point of the identification figure Fi1. The dicing control calculator 111 performs a control to identify a portion on which the identification figure Fi1 is superimposed as a portion of the crack Wc when the luminance value of each of the plurality of pixels B included in the portion on which the identification figure Fi1 is superimposed is equal to or greater than the threshold Th. In FIG. 32, the identification frame Ae is superimposed on a portion of the crack Wc on the left side of the intersection image Gc.

As shown in FIG. 33, the dicing control calculator 111 performs a control to superimpose the next identification figure Fi2 on the crack Wc portion in the identification frame Ae of the intersection image Gc when the identification figure Fi1 can be superimposed on the crack Wc portion in the identification frame Ae of the intersection image Gc. The identification figures Fi1 and Fi2 are partially superimposed on each other. In an area in which the identification figures Fi1 and Fi2 are superimposed, a comparison process between the luminance value and the threshold Th is not performed, and the processing result when the identification figure Fi1 is superimposed is maintained. Thus, an increase in the processing load on the dicing control calculator 111 is reduced or prevented. The process described above is repeated for all of the crack Wc portions in the identification frame Ae of the intersection image Gc.

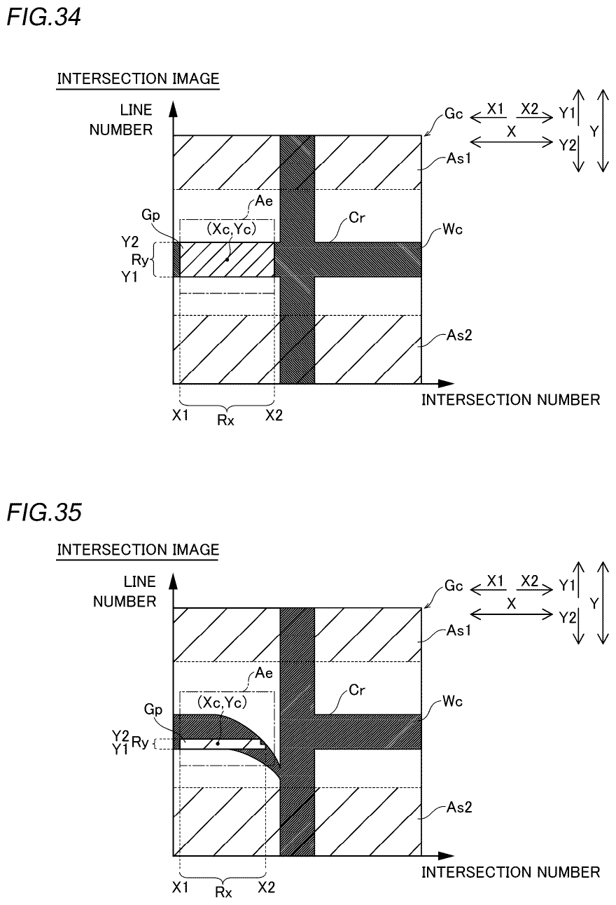

As shown in FIG. 34, the dicing control calculator 111 performs a control to perform the second inspection based on a portion Gp of the crack Wc in the intersection image Gc identified based on superimposing a plurality of identification figures including the identification figure Fi1 and the identification figure Fi2 on each other.

The dicing control calculator 111 performs a control to acquire the minimum X coordinate X1 on the X1 side in the X direction and the maximum X coordinate X2 on the X2 side in the X direction of the portion Gp of the crack Wc in the intersection image Gc. The dicing control calculator 111 performs a control to acquire the minimum Y coordinate Y1 on the Y2 side in the Y direction and the maximum Y coordinate Y2 on the Y2 side in the Y direction of the portion Gp of the crack Wc in the intersection image Gc.

The dicing control calculator 111 performs a control to acquire the center point Xc in the X direction of the portion Gp of the crack Wc in the intersection image Gc based on the minimum X coordinate X1 and the maximum X coordinate X2. The dicing control calculator 111 performs a control to acquire the length (range) Rx in the X direction of the portion Gp of the crack Wc in the intersection image Gc based on the minimum X coordinate X1 and the maximum X coordinate X2.

The dicing control calculator 111 performs a control to acquire the center point Yc in the X direction of the portion Gp of the crack Wc in the intersection image Gc based on the minimum Y coordinate Y1 and the maximum Y coordinate Y2. The dicing control calculator 111 performs a control to acquire the length (range) Ry in the Y direction of the portion Gp of the crack Wc in the intersection image Gc based on the minimum Y coordinate Y1 and the maximum Y coordinate Y2.

The dicing control calculator 111 performs a control to identify whether the crack Wc at the intersection Cr is bad or not based on the center point Xc, the length Rx, the center point Yc, and the length Ry. The crack Wc at the intersection Cr in FIG. 34 is identified as good.

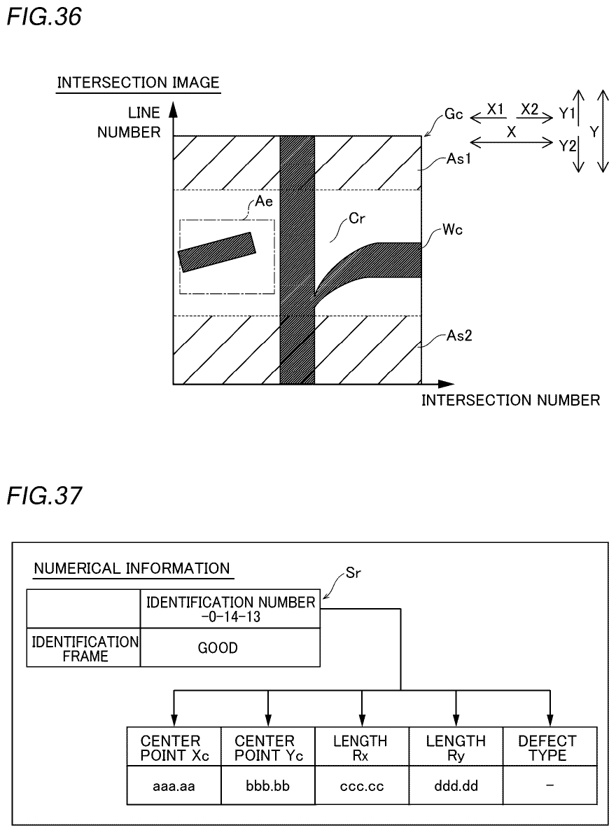

The crack Wc at the intersection Cr in FIG. 35 is identified as bad because the length Ry in the Y direction is short. The crack Wc at the intersection Cr in FIG. 36 is identified as bad because the identification figure Fi1 cannot be superimposed on the crack Wc portion in the identification frame Ae of the intersection image Gc.

The dicing control calculator 111 can perform a control to store the intersection image Gc in the storage based on the inspection result being bad. The dicing control calculator 111 may store the intersection image Gc in the storage regardless of whether the inspection result is good or bad, or may not store the intersection image Gc in the storage.

As shown in FIG. 37, the dicing control calculator 111 can perform a control to store numerical information Sr in the storage based on the inspection result being bad. The dicing control calculator 111 may store the numerical information Sr in the storage regardless of whether the inspection result is good or bad, or may not store the numerical information Sr in the storage.

The numerical information Sr includes an identification number, a cutting channel Cc, a line number, an intersection number, a center point Xc, a center point Yc, a length Rx, a length Ry, and a defect type. The identification number is a number for identifying each of a plurality of wafers W1 produced by the semiconductor wafer processing apparatus 100. The defect type is a type of defect corresponding to an inspection result, preset by the operator.

The dicing control calculator 111 performs a control to stop the dicing device 1 based on the inspection result of the second inspection being bad. The timing to stop the dicing device 1 is the timing after all of the plurality of wafer ring structures W stored in the cassette unit 202 have been processed, for example.

### Setting Change for Second Inspection and Test Inspection for Setting Change

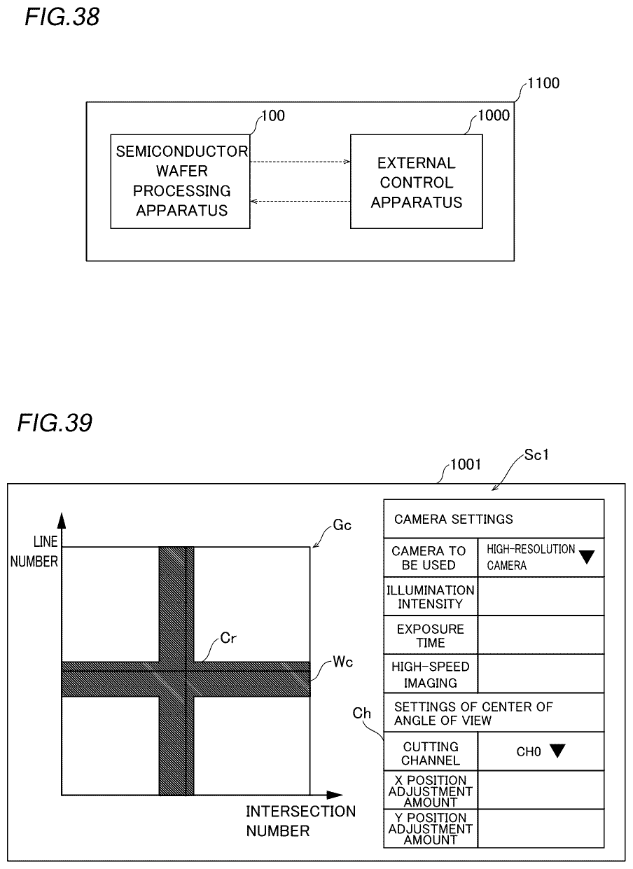

As shown in FIG. 38, an external control apparatus 1000 is provided outside the semiconductor wafer processing apparatus 100. A semiconductor wafer processing system 1100 is configured by combining the semiconductor wafer processing apparatus 100 and the external control apparatus 1000. The external control apparatus 1000 makes a setting change for the second inspection and performs a test inspection for setting change.

The external control apparatus 1000 includes a CPU, a storage including a ROM and a RAM, for example, and a display 1001 (see FIG. 39). The external control apparatus 1000 may include, as a storage, an HDD that retains stored information even after the voltage is cut off, for example.

### Setting Change

As shown in FIG. 39, the external control apparatus 1000 controls the display 1001 to display a first setting change screen Sc1. The external control apparatus 1000 performs a control to acquire an operator's operation of selecting a camera to be used in the second inspection from among the high-resolution camera 14a and the wide-angle camera 14b on the first setting change screen Sc1. The external control apparatus 1000 performs a control to acquire an operator's operation of changing the illumination intensity and exposure time of the camera to be used in the second inspection on the first setting change screen Sc1. The external control apparatus 1000 performs a control to acquire an operator's operation of selecting whether or not to perform high-speed imaging to be transmitted from the dicing device 1 to the external control apparatus 1000 by reducing the number of pixels of the intersection image Gc on the first setting change screen Sc1.

The external control apparatus 1000 performs a control to acquire an operator's operation of changing the setting of the center of the angle of view of the intersection image Gc on the first setting change screen Sc1. In changing the setting of the center of the angle of view of the intersection image Gc, the operator designates the cutting channel Cc and then inputs the X position adjustment amount and the Y position adjustment amount of the center of the angle of view of the intersection image Gc such that the setting is changed.

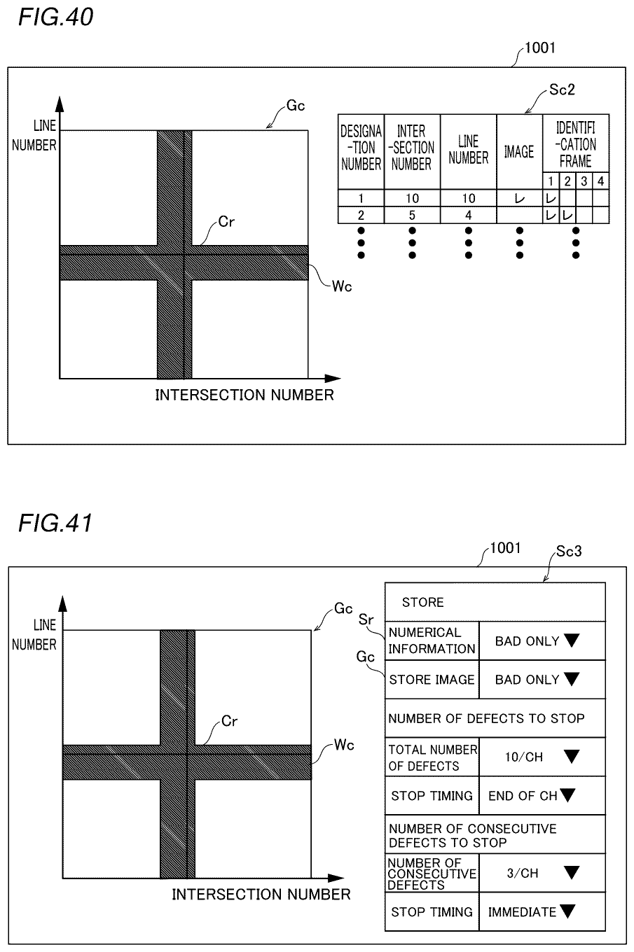

As shown in FIG. 40, the external control apparatus 1000 controls the display 1001 to display a second setting change screen Sc2. The external control apparatus 1000 performs a control to display an intersection Cr at which the contents of the second inspection are individually designated by the operator on the second setting change screen Sc2 among the plurality of intersections Cr. The external control apparatus 1000 performs a control to receive a user's operation of changing the setting as to whether or not to perform imaging by the high-resolution camera 14a (wide-angle camera 14b) at the intersection Cr designated based on the number (coordinate) of the intersection number axis extending in the X direction and the number (coordinate) of the line number axis extending in the Y direction. The external control apparatus 1000 performs a control to receive a setting change by the operator for the number and position of the identification frames Ae to be superimposed at the designated intersection Cr.

As shown in FIG. 41, the external control apparatus 1000 controls the display 1001 to display a third setting change screen Sc3. The external control apparatus 1000 performs a control to acquire a setting change by the operator regarding storing of the numerical information Sr and the intersection image Gc in the storage on the third setting change screen Sc3.

The external control apparatus 1000 performs a control to receive a setting change by the operator for stopping the dicing device 1, based on the total number of defects for each cutting channel Cc. The external control apparatus 1000 performs a control to receive a setting change by the operator of the timing to stop the dicing device 1 (after processing the last cutting line Lc in the cutting channel Cc in FIG. 41), based on the total number of defects for each cutting channel Cc.

The external control apparatus 1000 performs a control to receive a setting change by the operator for stopping the dicing device 1, based on the number of consecutive occurrences of defects. The external control apparatus 1000 performs a control to receive a setting change by the operator for the timing of stopping the dicing device 1 (immediate in FIG. 41), based on the number of consecutive occurrences of defects.

### Test Inspection for Setting Change

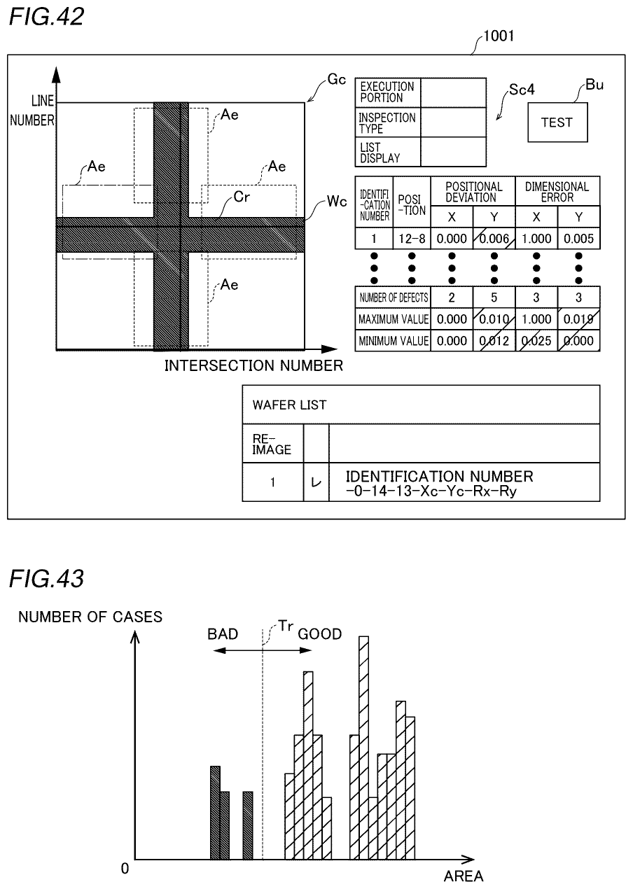

As shown in FIG. 42, the external control apparatus 1000 controls the display 1001 to display a fourth setting change screen Sc4. The external control apparatus 1000 performs a control to receive execution of a test inspection for adjusting the second inspection on the fourth setting change screen Sc4. The execution of the test inspection is received based on an operator's operation on a test button Bu.

The external control apparatus 1000 performs a control to receive, in an “execution portion”, an operator's designation of an intersection Cr at which a test inspection is to be performed to adjust the second inspection among the plurality of intersections Cr. The external control apparatus 1000 performs a control to receive, in an “inspection type”, an operator's designation of an inspection type of the second inspection (such as a full inspection in which all intersections Cr are inspected or a partial inspection in which some of all intersections Cr are inspected).

The external control apparatus 1000 performs a control to receive, in a “list display”, an operator's designation of the inspection result of the test inspection corresponding to the identification frame Ae (the identification frame Ae on the left side of the intersection image Gc in FIG. 42). The external control apparatus 1000 performs a control to display a list of the inspection result of the test inspection corresponding to the identification frame Ae based on receiving the operator's designation of the inspection result of the test inspection corresponding to the identification frame Ae. In the list, the identification number, the position (shown by the intersection number and the line number), the positional deviation, and the dimensional error are displayed. The positional deviation is shown by a difference between the center point Xc and the reference position, and a difference between the center point Yc and the reference position. The dimensions are shown by a difference between the length Rx and the reference length, and a difference between the length Ry and the reference length position. In the list, the number of defects, the maximum and minimum values of the positional deviation, and the maximum and minimum values of the dimensional error are also displayed. As an example, a portion identified as a defect in the list is hatched.

The external control apparatus 1000 performs a control to perform an inspection by including the intersection image Gc and the numerical information Sr of the wafer W1 displayed in a “wafer list” field in the current test inspection. The wafer W1 displayed in the “wafer list” field is information about the wafer W1 that has been subjected to the first and second inspections in the past.

As shown in FIG. 43, the external control apparatus 1000 controls the display 1001 to display, in a graph, the number of cases in which the inspection result of the second inspection of the wafer W1 is good and the number of cases in which the inspection result of the second inspection of the wafer W1 is bad. The number of cases in which the inspection result of the second inspection of the wafer W1 is good and the number of cases in which the inspection result of the second inspection of the wafer W1 is bad are displayed in different colors (displayed by different hatching in FIG. 43). In addition, the external control apparatus 1000 performs a control to change the threshold Tr based on receiving an operator's operation of the line of the threshold Tr.

### Crack Inspection Process

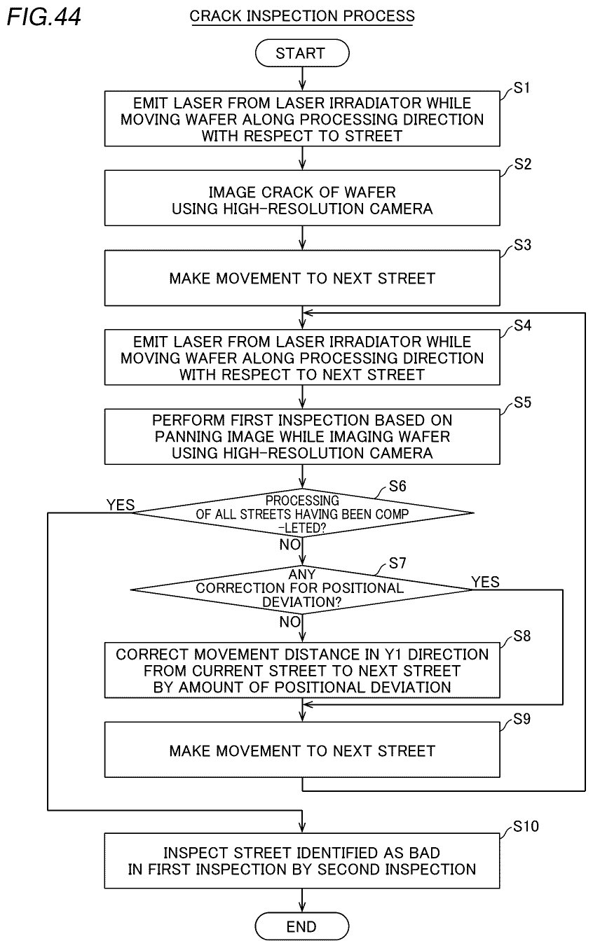

A crack inspection process of the semiconductor wafer processing apparatus 100 is described below with reference to FIG. 44.

In step S1, the laser L is emitted from the laser irradiator 13a toward the wafer W1 while the wafer W1 is moved along the Df direction with respect to the street Ws. Thus, the modified layer Wm is formed in the wafer W1. In step S2, the high-resolution camera 14a images the crack Wc of the wafer W1. Thus, the panning image Gf of the street Ws is captured. In step S3, a movement from the street Ws at which the modified layer Wm has been formed in the wafer W1 to the next street Ws is made. That is, the chuck table unit 12 moves the wafer W1 such that the position of the laser irradiator 13a is aligned from the street Ws at which the modified layer Wm has been formed in the wafer W1 to the next street Ws at which processing to form the modified layer Wm in the wafer W1 is to be performed.

In step S4, the laser L is emitted from the laser irradiator 13a while the wafer W1 is moved along the Df direction with respect to the next street Ws. In step S5, the first inspection is performed based on the panning image Gf while the wafer W1 is imaged by the high-resolution camera 14a. The panning image Gf on which the first inspection is to be performed is an image of the vicinity of the crack We captured at the previous street Ws. In step S6, it is determined whether or not processing of all the streets Ws has been completed. When processing of all the streets Ws has been completed, the process advances to step S10. When processing of all the streets Ws has not been completed, the process advances to step S7.

In step S7, it is determined whether or not there is any correction for the positional deviation in the inspection result of the first inspection. When there is a correction for the positional deviation, the process advances to step S8. When there is not a correction for the positional deviation, the process advances to step S9. In step S8, a movement distance in the Y1 direction from the current street Ws to the next street Ws is corrected by the amount of positional deviation. In step S9, after a movement to the next street Ws is made, the process returns to step S4, and the same process is performed.

In step S10, the street Ws identified as bad in the first inspection is inspected by the second inspection. That is, the second inspection is performed based on the intersection image Gc of the intersection Cr at the street Ws identified as bad in the first inspection. After step S10, the crack inspection process is terminated.

As a process other than the crack inspection process in a manufacturing method for the semiconductor chip Ch (semiconductor chip manufacturing process described above), which is a manufacturing method for manufacturing the semiconductor chip Ch, the semiconductor chip manufacturing process includes a step of forming the modified layer Wm in the wafer W1 by emitting the laser L from the laser irradiator 13a in the Df direction extending along each of the plurality of streets Ws of the wafer W1 on which the plurality of semiconductor chips Ch are provided. The semiconductor chip manufacturing process includes a step of imaging the wafer W1 in which the modified layer Wm has been formed with the high-resolution camera 14a mounted to the mounting member 13b shared with the laser irradiator 13a. The semiconductor chip manufacturing process includes a step of expanding the elastic sheet member W2 to divide the wafer W1 into the plurality of semiconductor chips Ch along the dividing line (street Ws) by the expander 208.

Thus, the semiconductor chip Ch manufactured by the semiconductor chip manufacturing process is manufactured by the dicing device 1 including the laser irradiator 13a, the high-resolution camera 14a, and the shared mounting member 13b.

### Advantageous Effects of First Embodiment

According to the first embodiment, the following advantageous effects are achieved.

According to the first embodiment, as described above, the dicing device 1 includes the shared mounting member 13b to which both the laser irradiator 13a and the high-resolution camera 14a are mounted. Accordingly, the laser irradiator 13a and the high-resolution camera 14a are mounted to the shared mounting member 13b such that an increase in the number of components used in the mounting structure for the laser irradiator 13a and the high-resolution camera 14a in the dicing device 1 can be reduced or prevented. Thus, an increase in the number of components and the complexity of the mounting structure for the laser irradiator 13a and the high-resolution camera 14a in the dicing device 1 can be reduced or prevented.

According to the first embodiment, as described above, the mounting member 13b is fixed in position in the horizontal direction and the upward-downward direction. The laser irradiator 13a and the high-resolution camera 14a are fixed in position in the horizontal direction and mounted to the mounting member 13b. Accordingly, as compared with a case in which a movement mechanism is provided to move each of the laser irradiator 13a and the high-resolution camera 14a in the horizontal direction, an increase in the number of components in the movement mechanism for the laser irradiator 13a and the movement mechanism for the high-resolution camera 14a and the complexity of the movement mechanism for the laser irradiator 13a and the movement mechanism for the high-resolution camera 14a can be reduced or prevented.

According to the first embodiment, as described above, the dicing device 1 includes the chuck table unit 12 to move the wafer W1 in the Df direction while holding the wafer W1. The high-resolution camera 14a is fixed in position in the horizontal direction and images the wafer W1 in which the modified layer Wm has been formed by the laser L emitted to the wafer W1 from the laser irradiator 13a while the wafer W1 is moved in the Df direction by the chuck table unit 12. Accordingly, the wafer W1 is moved by the chuck table unit 12 such that the crack Wc formed in the wafer W1 can be imaged, and thus the need for a movement mechanism to move the high-resolution camera 14a in the horizontal direction can be eliminated.

According to the first embodiment, as described above, the high-resolution camera 14a is mounted to the mounting member 13b together with the laser irradiator 13a with the focal position Fp of the laser L from the laser irradiator 13a and the optical center Po of the high-resolution camera 14a aligned along the Df direction in the plan view. Accordingly, during processing of the modified layer Wm, a portion of the wafer W1 processed by the laser L emitted from the laser irradiator 13a is moved directly below the high-resolution camera 14a as the wafer W1 is moved in the Df direction, and thus processing of the modified layer Wm by the laser L emitted from the laser irradiator 13a and imaging of the crack Wc of the wafer W1 by the high-resolution camera 14a can be performed in parallel.

According to the first embodiment, as described above, the dicing device 1 includes the wide-angle camera 14b mounted to the mounting member 13b together with the high-resolution camera 14a and the laser irradiator 13a to image the alignment marks on the wafer W1. The high-resolution camera 14a has a higher resolution than the wide-angle camera 14b. Accordingly, a more detailed image of the crack Wc generated in the wafer W1 can be captured by the high-resolution camera 14a having a higher resolution, and thus the crack Wc can be accurately inspected.

According to the first embodiment, as described above, the dicing device 1 includes the dicing control calculator 111 configured or programmed to perform a control to continue to expose the high-resolution camera 14a to light with respect to the preset portion of the predetermined street Ws1 of the plurality of streets Ws while forming the modified layer Wm in the wafer W1 by the laser L along the Df direction at the predetermined street Ws1 to create the panning image Gf. Accordingly, the panning image Gf displayed based on a luminance value obtained by accumulating luminance values of the preset portion of the predetermined street Ws1 can be acquired, and thus the crack Wc generated in the wafer W1 due to the modified layer Wm can be inspected based on a relatively small number of images.

According to the first embodiment, as described above, the dicing control calculator is configured or programmed to perform a control to acquire the illumination intensity to image the preset portion of the predetermined street Ws1 using the high-resolution camera 14a while forming the modified layer Wm in the wafer W1 by the laser L along the Df direction based on the exposure time preset for the high-resolution camera 14a to image the preset portion of the predetermined street Ws1 using the high-resolution camera 14a while forming the modified layer Wm in the wafer W1 by emitting the laser L along the Df direction, and the exposure time and illumination intensity preset for the high-resolution camera 14a to inspect the crack Wc formed due to the modified layer Wm after the modified layer Wm is formed at all of the streets Ws. Accordingly, the illumination intensity for imaging the predetermined street Ws1 by the high-resolution camera 14a can be appropriately adjusted, and thus the possibility that the panning image Gf captured by the high-resolution camera 14a becomes too dark or too bright can be reduced or prevented.

According to the first embodiment, as described above, the dicing control calculator 111 is configured or programmed to perform a control to perform the first inspection to inspect whether processing of the modified layer Wm by the laser L is bad or not based on the plurality of average luminance values Ba acquired for the respective pixel groups Bg by averaging the luminance values of the plurality of pixels B included in the plurality of pixel groups Bg of the panning image Gf in which the plurality of pixel groups Bg including the plurality of pixels B aligned in the Df direction are aligned in the Dv direction. Accordingly, the luminance values of the plurality of pixels B included in the pixel groups Bg can be combined into average luminance values Ba, and then the first inspection process can be performed. Thus, the complexity of the process of the dicing control calculator 111 to perform the first examination can be prevented.

According to the first embodiment, as described above, the dicing control calculator 111 is configured or programmed to perform a control to acquire the plurality of crack luminance values Bra that are equal to or greater than the preset threshold Th, and the position range in the direction perpendicular to the Df direction of the plurality of pixel groups Bg having the plurality of crack luminance values Bra based on the average luminance values Ba within the position range of the predetermined street Ws1 among the plurality of average luminance values Ba and the threshold Th. Accordingly, the plurality of crack luminance values Bra corresponding to the crack Wc portion formed due to the modified layer Wm are acquired from among the plurality of average luminance values Ba within the position range of the predetermined street Ws1 such that it is possible to exclude the average luminance values Ba that are not required for the first inspection from the inspection, and thus the inspection accuracy of the first inspection can be ensured.

According to the first embodiment, as described above, the dicing control calculator 111 is configured or programmed to perform a control to acquire the amount of positional deviation of the crack Wc formed due to the modified layer Wm based on the difference between the center position Pc of the position range of the plurality of crack luminance values Bra and the preset reference position, and perform the first inspection. Accordingly, the amount of positional deviation of the crack Wc is acquired such that the relative positional deviation in the horizontal direction between the laser irradiator 13a and the wafer W1 can be corrected so as to reduce the amount of positional deviation of the crack Wc before processing is performed to form the modified layer Wm at the street Ws at which the modified layer Wm has not been formed. Thus, the modified layer Wm can be formed at an appropriate position in the wafer W1.

According to the first embodiment, as described above, the dicing control calculator 111 is configured or programmed to perform a control to correct the positional deviation of the focal position Fp of the laser L in the Dv direction based on the amount of positional deviation before processing of the modified layer Wm by the laser L at the street Ws after the street Ws next to the predetermined street Ws1 on which the plurality of average luminance values Ba have been acquired. Accordingly, at least the time required for processing of the modified layer Wm in the wafer W1 by the laser L at the next street Ws can be ensured as the processing time for performing a process to acquire the amount of positional deviation, and thus sufficient processing time for the dicing control calculator 111 required to acquire the amount of positional deviation can be ensured.

According to the first embodiment, as described above, the dicing control calculator 111 is configured or programmed to perform a control to perform the first inspection to inspect whether the crack Wc formed due to the modified layer Wm is appropriate or not based on a comparison between the average value of the plurality of crack luminance values Bra and the preset reference average luminance value range, and a comparison between the width Wd as the position range Ra in the Dv direction in which the plurality of pixel groups Bg corresponding to the plurality of crack luminance values Bra are aligned and the preset reference width range. Accordingly, in the first inspection, the average value of the plurality of crack luminance values Bra is compared with the preset reference average luminance value range such that it is possible to determine whether the luminance value of the portion corresponding to the crack Wc is sufficiently large or not, and thus it is possible to identify a decrease in the luminance value caused by the crack Wc being interrupted midway. Furthermore, the width Wd as the position range Ra of the plurality of crack luminance values Bra is compared with the preset reference width range such that it is possible to identify an increase in the width Wd of the crack luminance values Bra, which is a portion of the panning image Gf corresponding to the crack Wc, caused by the wafer W1 or the laser irradiator 13a moving in a direction inclined with respect to the Df direction extending along the street Ws when the modified layer Wm is formed in the wafer W1.

According to the first embodiment, as described above, the dicing control calculator 111 is configured or programmed to perform a control to notify the operator when the inspection result of the first inspection based on the plurality of crack luminance values Bra is bad. Accordingly, the operator can reliably recognize the defect.

According to the first embodiment, as described above, the dicing device 1 is configured to make a setting to perform the second inspection to re-inspect whether the crack Wc formed due to the modified layer Wm is bad or not after the modified layer Wm is formed at all of the plurality of streets Ws of the wafer W1, based on the inspection result indicating that the processing of the modified layer Wm is bad among the inspection results of the first inspection for the plurality of streets Ws. Accordingly, as compared with a case in which the cracks Wc formed at all of the plurality of streets Ws of the wafer W1 are inspected in the second inspection, the number of inspection targets in the second inspection can be reduced, and thus an increase in the processing load on the dicing control calculator 111 for the second examination can be reduced or prevented.

According to the first embodiment, as described above, the manufacturing method for the semiconductor chip Ch includes a step of imaging the wafer W1 in which the modified layer Wm has been formed using the high-resolution camera 14a mounted to the mounting member 13b shared with the laser irradiator 13a. Accordingly, the laser irradiator 13a and the high-resolution camera 14a are mounted to the shared mounting member 13b such that it is possible to obtain the manufacturing method for the semiconductor chip Ch capable of reducing or preventing an increase in the number of components in the mounting structure for the laser irradiator 13a and the high-resolution camera 14a and the complexity of the mounting structure in the dicing device 1.

According to the first embodiment, as described above, the semiconductor chip Ch is manufactured by the dicing device 1 including the shared mounting member 13b to which both the laser irradiator 13a and the high-resolution camera 14a are mounted. Accordingly, the laser irradiator 13a and the high-resolution camera 14a are mounted to the shared mounting member 13b such that it is possible to obtain the semiconductor chip Ch capable of reducing or preventing an increase in the number of components in the mounting structure for the laser irradiator 13a and the high-resolution camera 14a and the complexity of the mounting structure in the dicing device 1.

According to the first embodiment, as described above, the dicing device 1 includes the chuck table unit 12 to move the wafer W1 in the Df direction while holding the wafer W1. The mounting member 13b is fixed in position in the horizontal direction and the upward-downward direction. The dicing control calculator 111 is configured or programmed to perform a control to continue to expose the high-resolution camera 14a to light at the predetermined street Ws1 while forming the modified layer Wm in the wafer W1 at the predetermined street Ws1 by the laser L by moving the wafer W1 held by the chuck table unit 12 in the Df direction with respect to the high-resolution camera 14a fixed in position by the mounting member 13b to capture the panning image Gf using the high-resolution camera 14a. Accordingly, the crack Wc is imaged using the high-resolution camera 14a fixed in position such that the focal position Fp of the high-resolution camera 14a can be maintained constant, and thus the panning image Gf can be acquired in which the crack Wc clearly appears.

### Second Embodiment

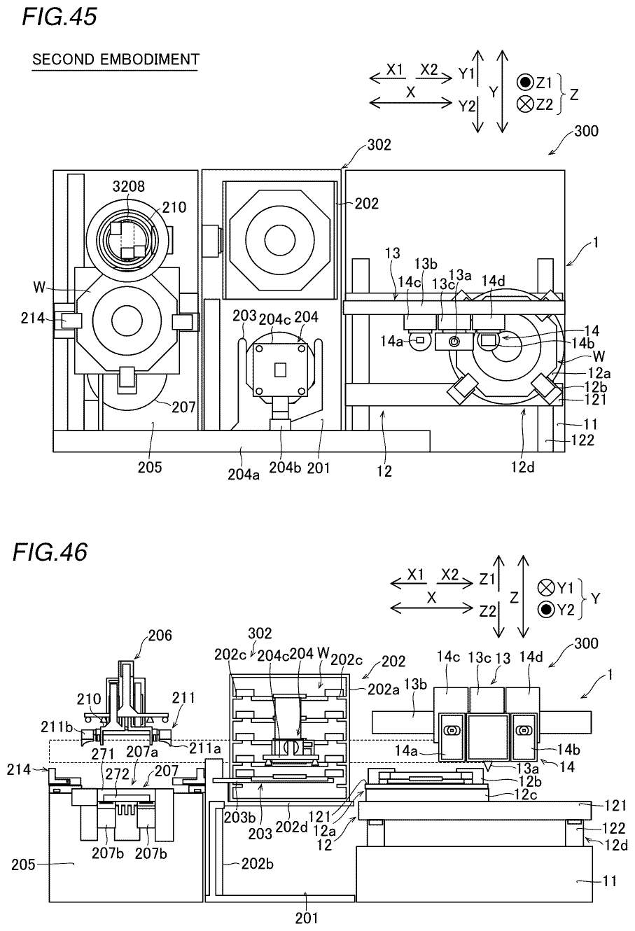

The configuration of a semiconductor wafer processing apparatus 300 according to a second embodiment is now described with reference to FIGS. 45 to 50. In the second embodiment, a squeegee unit 3213 is arranged outside an expanding ring 3281, unlike the first embodiment. In the second embodiment, detailed description of the same or similar configurations as those of the first embodiment is omitted.

### Semiconductor Wafer Processing Apparatus

As shown in FIGS. 45 and 46, the semiconductor wafer processing apparatus 300 is an apparatus that processes a wafer W1 provided on a wafer ring structure W.

The semiconductor wafer processing apparatus 300 includes a dicing device 1 and an expanding device 302. An upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 302 are aligned is defined as an X direction, a direction from the dicing device 1 toward the expanding device 302 in the X direction is defined as an X1 direction, and a direction from the expanding device 302 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

The dicing device 1 emits a laser L having a wavelength transmissive to the wafer W1 along a dividing line (street Ws) to form a modified layer Wm.

Specifically, the dicing device 1 includes a base 11, a chuck table unit 12, a laser 13, and an imager 14.

### Expanding Device

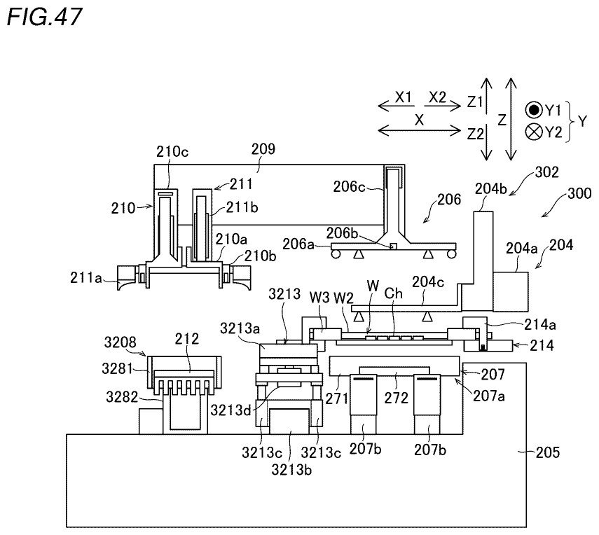

As shown in FIGS. 46 and 47, the expanding device 302 divides the wafer W1 to form a plurality of semiconductor chips Ch.

The expanding device 302 includes a base 201, a cassette unit 202, a lift-up hand unit 203, a suction hand unit 204, a base 205, a cool air supplier 206, a cooling unit 207, an expander 3208, a base 209, an expansion maintaining member 210, a heat shrinker 211, an ultraviolet irradiator 212, a squeegee unit 3213, and a clamp unit 214.

### Expander

The expander 3208 expands a sheet member W2 of the wafer ring structure W to divide the wafer W1 along the dividing line.

Specifically, the expander 3208 includes the expanding ring 3281 and a Z-direction movement mechanism 3282.

The expanding ring 3281 expands the sheet member W2 by supporting the sheet member W2 from the Z2 direction side. The expanding ring 3281 has a ring shape in a plan view. The Z-direction movement mechanism 3282 moves the expanding ring 3281 in the Z1 direction or the Z2 direction. The Z-direction movement mechanism 3282 includes a linear conveyor module, or a ball screw and a drive including a motor with an encoder, for example. The Z-direction movement mechanism 3282 is attached to the base 205.

### Squeegee Unit

The squeegee unit 3213 further divides the wafer W1 along the modified layer Wm by pressing the wafer W1 from the Z2 direction side after the sheet member W2 is expanded. Specifically, the squeegee unit 3213 includes a press 3213a, an X-direction movement mechanism 3213b, a Z-direction movement mechanism 3213c, and a rotation mechanism 3213d.

The press 3213a generates a bending stress in the wafer W1 to divide the wafer W1 along the modified layer Wm by being moved by the rotation mechanism 3213d and the X-direction movement mechanism 3213b while pressing the wafer W1 from the Z2 direction side via the sheet member W2 after being moved in the Z1 direction by the Z-direction movement mechanism 3213c. The press 3213a is a squeegee. The press 3213a is attached to an end of the rotation mechanism 3213d on the Z1 direction side. The Z-direction movement mechanism 3213c moves the rotation mechanism 3213d in the Z1 direction or the Z2 direction. The Z-direction movement mechanism 3213c includes a cylinder, for example. The Z-direction movement mechanism 3213c is attached to an end of the X-direction movement mechanism 3213b on the Z1 direction side. The X-direction movement mechanism 3213b includes a linear conveyor module, or a ball screw and a drive including a motor with an encoder, for example. The X-direction movement mechanism 3213b is attached to an end of the base 205 on the Z1 direction side.

In the squeegee unit 3213, the press 3213a divides the wafer W1 by being moved in the Y direction by the X-direction movement mechanism 3213b while pressing the wafer W1 from the Z2 direction side via the sheet member W2 after being moved in the Z1 direction by the Z-direction movement mechanism 3213c. Furthermore, in the squeegee unit 3213, after the press 3213a finishes moving in the Y direction, the press 3213a is rotated 90 degrees by the rotation mechanism 3213d. Moreover, in the squeegee unit 3213, the press 3213a divides the wafer W1 by being moved in the X direction by the X-direction movement mechanism 3213b while pressing the wafer W1 from the Z2 direction side via the sheet member W2 after being rotated 90 degrees.

### Control Configuration of Semiconductor Wafer Processing Apparatus

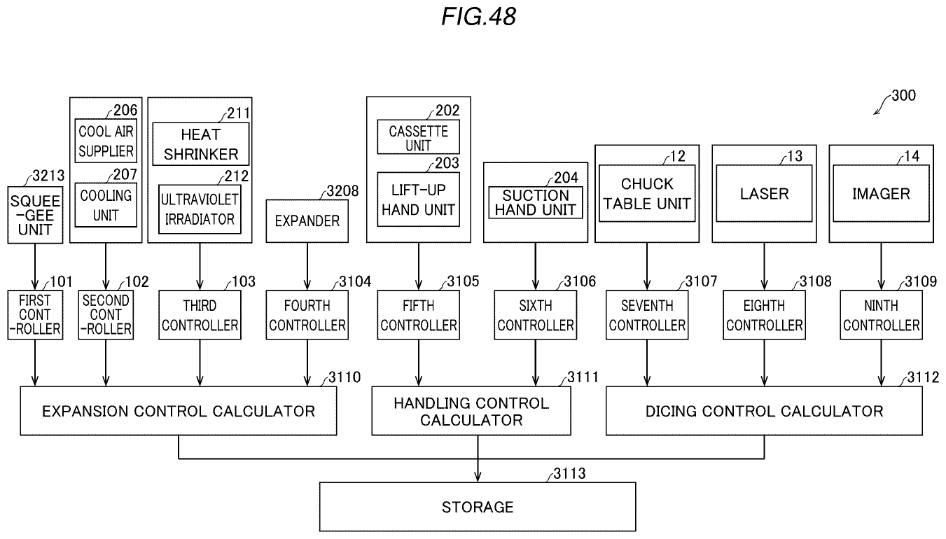

As shown in FIG. 48, the semiconductor wafer processing apparatus 300 includes a first controller 101, a second controller 102, a third controller 103, a fourth controller 3104, a fifth controller 3105, a sixth controller 3106, a seventh controller 3107, an eighth controller 3108, a ninth controller 3109, an expansion control calculator 3110, a handling control calculator 3111, a dicing control calculator 3112, and a storage 3113. The first controller 101, the second controller 102, the third controller 103, the fifth controller 3105, the sixth controller 3106, the seventh controller 3107, the eighth controller 3108, the ninth controller 3109, the expansion control calculator 3110, the handling control calculator 3111, the dicing control calculator 3112, and the storage 3113 have the same configurations as the first controller 101, the second controller 102, the third controller 103, the fourth controller 104, the fifth controller 105, the sixth controller 106, the seventh controller 107, the eighth controller 108, the expansion control calculator 109, the handling control calculator 110, the dicing control calculator 111, and the storage 112 according to the first embodiment, respectively, and thus description thereof is omitted.

The fourth controller 3104 controls the expander 3208. The fourth controller 3104 includes a CPU and a storage including a ROM and a RAM, for example. The fourth controller 3104 may include, as a storage, an HDD that retains stored information even after the voltage is cut off, for example.

### Semiconductor Chip Manufacturing Process

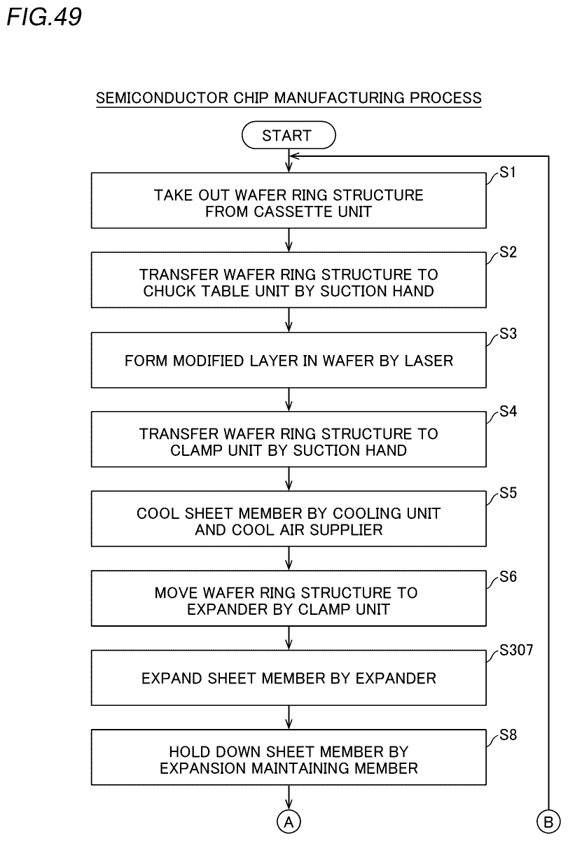

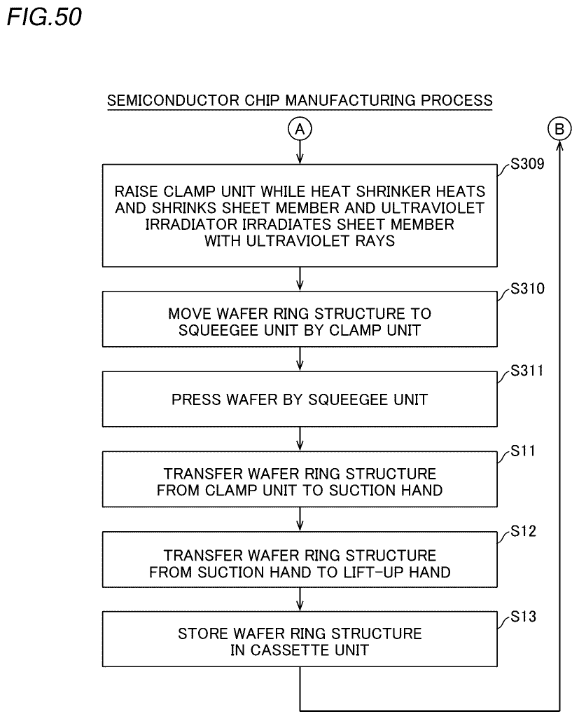

The overall operation of the semiconductor wafer processing apparatus 300 is described below with reference to FIGS. 49 and 50.

Process operations in step S1 to step S6, step S8, and step S11 are the same as the process operations in step S1 to step S6, step S8, and step S11 in the semiconductor chip manufacturing process according to the first embodiment, respectively, and thus description thereof is omitted.

In step S307, the sheet member W2 is expanded by the expander 3208. That is, the expanding ring 3281 is moved in the Z1 direction by the Z-direction movement mechanism 3282. The wafer ring structure W is moved in the Z2 direction by a Z-direction movement mechanism 214b while being held by the clamp unit 214. Then, the sheet member W2 is expanded by contacting the expanding ring 3281 and being pulled by the expanding ring 3281. Thus, the wafer W1 is divided along the dividing line (modified layer Wm).

As shown in FIG. 50, in step S309, while the heat shrinker 211 heats and shrinks the sheet member W2 and the ultraviolet irradiator 212 irradiates the sheet member W2 with ultraviolet rays Ut, the clamp unit 214 is raised. At this time, an intake 210c takes in air in the vicinity of the heated sheet member W2. In step S310, the wafer ring structure W is moved to the squeegee unit 3213 by the clamp unit 214. That is, the wafer ring structure W is moved in the Y2 direction by a Y-direction movement mechanism 214c while being held by the clamp unit 214.

In step S311, after the wafer ring structure W is moved to the squeegee unit 3213, the wafer W1 is pressed by the squeegee unit 3213. Thus, the wafer W1 is further divided by the squeegee unit 3213.

### Detailed Configuration of Dicing Control Calculator

The detailed configuration of the dicing control calculator 3112 is the same as the detailed configuration of the dicing control calculator 111 according to the first embodiment, and thus description thereof is omitted. The remaining configurations of the second embodiment are similar to those of the first embodiment, and thus description thereof is omitted.

### Advantageous Effects of Second Embodiment

According to the second embodiment, the following advantageous effects are achieved.

According to the second embodiment, similarly to the first embodiment, the dicing device 1 includes a shared mounting member 13b to which both a laser irradiator 13a and a high-resolution camera 14a are mounted. Accordingly, an increase in the number of components and the complexity of the mounting structure for the laser irradiator 13a and the high-resolution camera 14a in the dicing device 1 can be reduced or prevented.

According to the second embodiment, similarly to the first embodiment, the dicing device 1 includes the chuck table unit 12 to move the wafer W1 in a Df direction while holding the wafer W1. The mounting member 13b is fixed in position in the horizontal direction and the upward-downward direction. The dicing control calculator 3112 is configured or programmed to perform a control to continue to expose the high-resolution camera 14a to light with respect to a predetermined street Ws1 while forming the modified layer Wm in the wafer W1 at the predetermined street Ws1 by the laser L by moving the wafer W1 held by the chuck table unit 12 in the Df direction with respect to the high-resolution camera 14a fixed in position by the mounting member 13b to capture a panning image Gf using the high-resolution camera 14a. Accordingly, a crack Wc is imaged using the high-resolution camera 14a fixed in position such that the focal position Fp of the high-resolution camera 14a can be maintained constant, and thus the panning image Gf can be acquired in which the crack Wc clearly appears. The remaining advantageous effects of the second embodiment are similar to those of the first embodiment, and thus description thereof is omitted.

### Third Embodiment

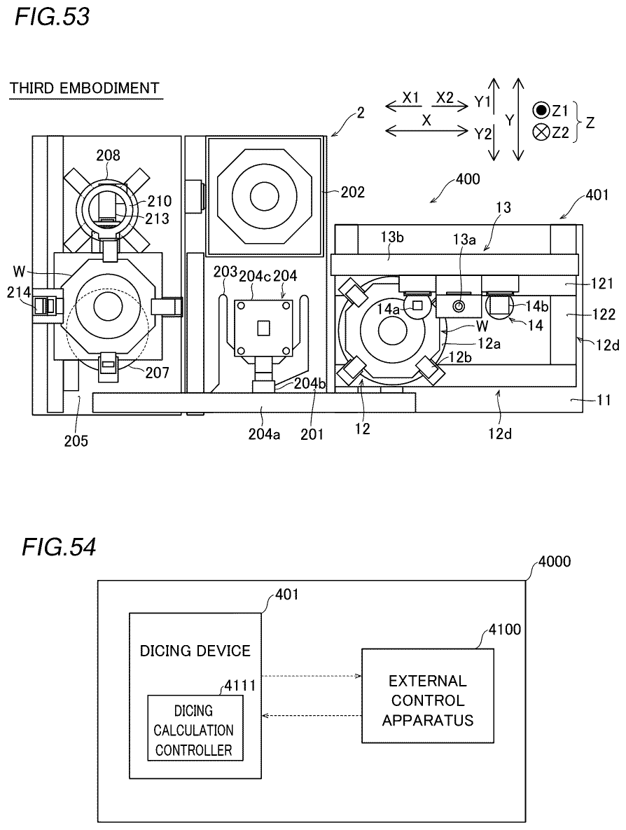

The configuration of a semiconductor wafer processing apparatus 400 according to a third embodiment is now described with reference to FIGS. 53 to 70. In the third embodiment, a high-resolution camera 14a is controlled to extend imaging to image a crack Wc, unlike the first embodiment. In the third embodiment, detailed description of the same or similar configurations as those of the first embodiment is omitted.

As shown in FIG. 53, the semiconductor wafer processing apparatus 400 according to the third embodiment includes a dicing device 401 and an expanding device 2.

Hereinafter, an upward-downward direction is defined as a Z direction, an upward direction is defined as a Z1 direction, and a downward direction is defined as a Z2 direction. In a horizontal direction perpendicular to the Z direction, a direction in which the dicing device 401 and the expanding device 2 are aligned is defined as an X direction, a direction from the dicing device 401 toward the expanding device 2 in the X direction is defined as an X1 direction, and a direction from the expanding device 2 toward the dicing device 401 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

As shown in FIG. 53, the dicing device 1 includes a base 11, a chuck table unit 12, a laser 13, and an imager 14. The chuck table unit 12 is an example of a “table unit” in the claims.

### Laser

The laser 13 emits a laser L to a wafer W1 of a wafer ring structure W held by the chuck table unit 12. The laser 13 is arranged on the Z1 direction side of the chuck table unit 12. The laser 13 includes a laser irradiator 13a, a mounting member 13b, and a Z-direction movement mechanism 13c.

### Imager

The imager 14 images the wafer W1 of the wafer ring structure W held by the chuck table unit 12. The imager 14 is arranged on the Z1 direction side of the chuck table unit 12. The imager 14 includes the high-resolution camera 14a, a wide-angle camera 14b, a Z-direction movement mechanism 14c, and a Z-direction movement mechanism 14d. The high-resolution camera 14a is an example of a “first imager” in the claims. The wide-angle camera 14b is an example of a “second imager” in the claims.

### Control Configuration of Semiconductor Wafer Processing System

As shown in FIG. 54, the dicing device 401 includes a dicing control calculator 4111. Furthermore, an external control apparatus 4100 is provided outside the dicing device 401. A semiconductor wafer processing system 4000 is configured by combining the semiconductor wafer processing apparatus 400 including the dicing device 401 and the external control apparatus 4100. In the external control apparatus 4100, conditions for imaging the crack Wc using the high-resolution camera 14a are set. The dicing control calculator 4111 is an example of a “controller” in the claims.

The external control apparatus 4100 includes a CPU, a storage including a ROM and a RAM, for example, and a display. The external control apparatus 4100 may include, as the storage, an HDD that retains stored information even after the voltage is cut off, for example.

### Setting of Conditions for Imaging Crack Using High-Resolution Camera

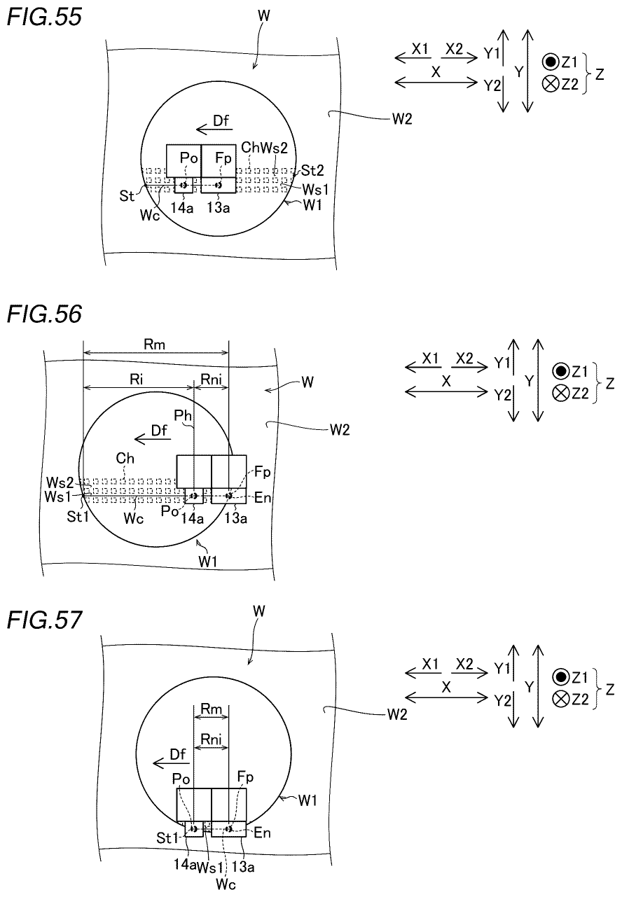

As shown in FIG. 55, the dicing device 401 captures a panning image Gf using the high-resolution camera 14a by continuing to expose the high-resolution camera 14a to light with respect to a preset portion of a predetermined street Ws1 while forming a modified layer Wm in the wafer W1 at the predetermined street Ws1 by the laser irradiator 13a along the Df direction to image the crack Wc on a surface closer to the high-resolution camera 14a (the Z1 direction side) generated due to the modified layer Wm. In the dicing device 401, a first inspection shown in the first embodiment is performed based on the panning image Gf. The panning image Gf is an image (long-time exposure image) of the crack Wc on the surface of the wafer W1 captured by holding the shutter of the high-resolution camera 14a open while moving the wafer W1 relative to the laser irradiator 13a and the high-resolution camera 14a in the Df direction by the chuck table unit 12. The Df direction is an example of a “processing direction” in the claims.

In FIGS. 55 to 57 and 63 to 65, of a plurality of streets Ws on the wafer W1, only the predetermined street Ws1 or both the predetermined street Ws1 and a predetermined street Ws2 are shown for the convenience of illustration. Furthermore, in FIGS. 55 to 57 and 63 to 65, the laser irradiator 13a and the high-resolution camera 14a are shown in a simplified form for the convenience of illustration.

As shown in FIG. 56, the dicing device 401 stops emitting the laser L from the laser irradiator 13a and stops imaging the crack Wc using the high-resolution camera 14a, when the focal position Fp of the laser irradiator 13a reaches an ending point En from a starting point St1 of the predetermined street Ws1. Then, in the dicing device 401, the wafer W1 is moved in the Y2 direction relative to the laser irradiator 13a and the high-resolution camera 14a from the predetermined street Ws1 toward a starting point St2 in the Df direction of the next predetermined street Ws2 in order to reduce or prevent an increase in the processing time for forming the modified layer Wm in the wafer W1.

In a case shown in FIG. 56, the modified layer Wm is formed in the wafer W1 by the laser irradiator 13a in a processing section Rm from the starting point St1 to the ending point En of the predetermined street Ws1 in the Df direction. Furthermore, the crack Wc on the surface of the wafer W1 on the Z1 direction side is imaged by the high-resolution camera 14a in an imaging execution section Ri from the starting point St1 to a point Ph before the ending point En of the predetermined street Ws1 in the Df direction. Therefore, the crack Wc on the surface of the wafer W1 on the Z1 direction side is not imaged by the high-resolution camera 14a in a non-imaging execution section Rni from the point Ph to the ending point En.

The imaging execution section Ri is set in advance in the external control apparatus 4100 before the dicing device 401 starts to process the wafer W1. The dicing control calculator 4111 performs a control to acquire the imaging conditions including the imaging execution section Ri from the external control apparatus 4100 before the laser irradiator 13a starts to form the modified layer Wm in the wafer W1. In a case shown in FIG. 56, even when the high-resolution camera 14a does not image the crack Wc in the non-imaging execution section Rni, the high-resolution camera 14a images the crack Wc in the imaging execution section Ri, and thus the first inspection described in the first embodiment can be performed.

However, as shown in FIG. 57, in the wafer W1 that is circular as viewed from the Z1 direction side, the length in the Df direction of the predetermined street Ws1 at a position close to the outer periphery of the wafer W1 is short. When the length in the Df direction of the predetermined street Ws1 is shorter than a distance between the focal position Fp of the laser irradiator 13a and the optical center Po, the focal position Fp of the laser irradiator 13a reaches the ending point En of the predetermined street Ws1 before the high-resolution camera 14a starts to image the crack Wc on the surface of the wafer W1 on the Z1 direction side. In such a case, the high-resolution camera 14a cannot image the crack Wc on the surface of the wafer W1 on the Z1 direction side.

Therefore, the external control apparatus 4100 performs a control to receive a setting of the imaging execution section Ri for extending imaging of the crack Wc by the high-resolution camera 14a after the focal position Fp of the laser irradiator 13a reaches the ending point En in the Df direction of the predetermined street Ws1. The setting of the imaging execution section Ri for extending imaging of the crack Wc by the high-resolution camera 14a may be made to image the crack Wc in the non-imaging execution section Rni by the high-resolution camera 14a not only in a case in which the crack We cannot be imaged at all by the high-resolution camera 14a as shown in FIG. 57, but also in a case in which the crack Wc can be imaged by the high-resolution camera 14a as shown in FIG. 56.

Specifically, the external control apparatus 4100 performs a control to determine whether or not the imaging execution section Ri in which the crack Wc is imaged by the high-resolution camera 14a can be set based on the larger of a first distance based on the minimum value of the exposure time of the high-resolution camera 14a and a second distance based on the maximum value of the illumination intensity of the high-resolution camera 14a. That is, the external control apparatus 4100 is configured or programmed to determine whether or not the imaging execution section Ri requires an exposure time smaller than the time resolution of the high-resolution camera 14a. Furthermore, the external control apparatus 4100 is configured or programmed to determine whether or not the imaging execution section Ri requires an illumination intensity exceeding the maximum value of the illumination intensity of the high-resolution camera 14a. Thus, each of the first distance and the second distance is a condition required for the imaging execution section Ri in order not to exceed the limits of settings of the high-resolution camera 14a when imaging of the crack We by the high-resolution camera 14a is extended.

The first distance is calculated by multiplying the minimum value of the exposure time of the high-resolution camera 14a by the moving speed of the wafer W1 in the Df direction (first distance=“minimum value Tmin of exposure time”×“moving speed V”). The moving speed of the wafer W1 in the Df direction is a constant speed that is set in advance.

The second distance is calculated by dividing a predetermined coefficient, which is a coefficient for setting the luminance value (average luminance value Ba) of the crack Wc in the panning image Gf, by the maximum value of the illumination intensity of the high-resolution camera 14a (second distance=“predetermined coefficient C”/“maximum value Lmax of illumination intensity”). The predetermined coefficient is calculated by multiplying a predetermined illumination intensity L₀, a predetermined exposure time T₀, and the moving speed of the wafer W1 in the Df direction together (predetermined coefficient C=“predetermined illumination intensity L₀”×“predetermined exposure time T₀”×“moving speed V”). Each of the predetermined illumination intensity L₀ and the predetermined exposure time T₀ is set by the external control apparatus 4100 based on an image of the crack Wc captured by the high-resolution camera 14a.

Thus, each of the minimum value of the exposure time of the high-resolution camera 14a, the moving speed of the wafer W1 in the Df direction, the predetermined coefficient, and the maximum value of the illumination intensity of the high-resolution camera 14a is a preset constant.

The length in the Df direction of each of the plurality of streets Ws of the wafer W1 is also a preset constant.. Therefore, a user performs an operation to set the imaging execution section Ri in the length in the Df direction of each of the plurality of streets Ws of the wafer W1 based on the length in the Df direction of each of the plurality of streets Ws of the wafer W1, the minimum value of the exposure time of the high-resolution camera 14a, the moving speed of the wafer W1 in the Df direction, the predetermined coefficient, and the maximum value of the illumination intensity of the high-resolution camera 14a.

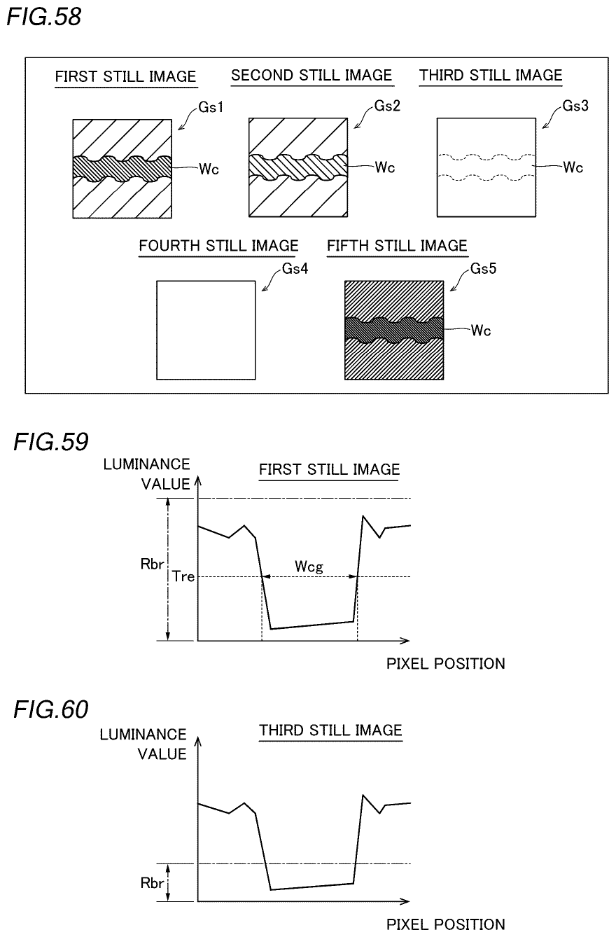

The setting of the predetermined illumination intensity L₀ and the predetermined exposure time T₀ is now described with reference to FIGS. 58 to 61.

As an example, the predetermined illumination intensity L₀ and the predetermined exposure time T₀ are set by the external control apparatus 4100 based on a first still image Gs1, a second still image Gs2, a third still image Gs3, a fourth still image Gs4, and a fifth still image Gs5 as shown in FIG. 58.

Each of the first still image Gs1, the second still image Gs2, the third still image Gs3, the fourth still image Gs4, and the fifth still image Gs5 is a still image captured by the high-resolution camera 14a when the wafer W1 held by the chuck table unit 12 is stationary and not moved in the Df direction with respect to the high-resolution camera 14a fixed in position by the mounting member 13b.

The illumination intensity Lx1 of the high-resolution camera 14a in capturing the first still image Gs1 is the same as the illumination intensity Lx2 of the high-resolution camera 14a in capturing the second still image Gs2, the illumination intensity Lx3 of the high-resolution camera 14a in capturing the third still image Gs3, and the illumination intensity Lx4 of the high-resolution camera 14a in capturing the fourth still image Gs4. Furthermore, the exposure time Tx2 of the high-resolution camera 14a in capturing the second still image Gs2 is twice as long as the exposure time Tx1 of the high-resolution camera 14a in capturing the first still image Gs1, the exposure time Tx3 of the high-resolution camera 14a in capturing the third still image Gs3 is three times as long as the exposure time Tx1 of the high-resolution camera 14a in capturing the first still image Gs1, and the exposure time Tx4 of the high-resolution camera 14a in capturing the fourth still image Gs4 is four times as long as the exposure time Tx1 of the high-resolution camera 14a in capturing the first still image Gs1.

As shown in the first still image Gs1, the second still image Gs2, the third still image Gs3, and the fourth still image Gs4 in FIG. 58, when only the exposure time is increased, the luminance value exceeds the upper limit (overflows), and thus it becomes impossible to acquire accurate luminance value information of the image.

The illumination intensity Lx1 of the high-resolution camera 14a in capturing the first still image Gs1 is the same as the illumination intensity Lx2 of the high-resolution camera 14a in capturing the fifth still image Gs5. The exposure time Tx2 of the high-resolution camera 14 a in capturing the fifth still image Gs5 is captured is ⅕ of the exposure time Tx1 of the high-resolution camera 14a in capturing the first still image Gs1. In this case as well, the contrast (light-dark difference) between the crack Wc and the background (a portion other than the crack Wc in the image) cannot be sufficiently ensured or the luminance value exceeds the lower limit (overflows), and thus it becomes impossible to acquire accurate luminance value information of the image.

Therefore, the exposure time Tx is calculated by dividing the imaging execution section Ri by the moving speed of the wafer W1 in the Df direction (exposure time Tx=“imaging execution section Ri”/“moving speed V”), but unless an illumination intensity Lx appropriate for the exposure time Tx is set, it is not possible to acquire a panning image Gf with sufficient contrast.

Therefore, the external control apparatus 4100 is configured or programmed to determine, as an image for setting the predetermined illumination intensity L₀ and the predetermined exposure time T₀, an optimal still image with sufficient contrast that satisfies the condition that some luminance values do not reach the upper limit from among the first still image Gs1, the second still image Gs2, the third still image Gs3, the fourth still image Gs4, and the fifth still image Gs5 described above, and store information such as the luminance value of the optimal still image as one of the image inspection conditions.

Specifically, as shown in FIG. 59, the external control apparatus 4100 performs a control to determine whether the still image is optimal or not based on the luminance value detectable range Rbr of the high-resolution camera 14a and a non-defective item determination reference width range Wcg corresponding to an extraction threshold Tre. That is, the external control apparatus 4100 performs a control to determine, as an optimal still image, a still image in which the luminance value is within the luminance value detectable range Rbr and a range that is equal to or less than the extraction threshold Tre is within the non-defective item determination reference width range Wcg. The extraction threshold Tre in the still image is a luminance value determined by the external control apparatus 4100 to have the largest gradient in a graph showing the relationship between the position of a pixel in the still image and the luminance value of the corresponding pixel. The non-defective item determination reference width range Wcg is set in advance. The luminance value detectable range Rbr is the gray level of the high-resolution camera 14a. The gray level refers to the shade of black and white expressed by a value from 0 to 255 in the case of 8-bit black and white, or the shade of black and white expressed by a value from 0 to 4095 in the case of 12-bit black and white.

FIG. 59 shows a graph showing the relationship between the position of a pixel in the first still image Gs1 and the luminance value of the corresponding pixel. The external control apparatus 4100 performs a control to determine that the first still image Gs1 is an optimal still image when the luminance value of the first still image Gs1 is within the luminance value detectable range Rbr and a range that is equal to or less than the extraction threshold Tre in the first still image Gs1 is within the non-defective item determination reference width range Wcg.

FIG. 60 shows a graph showing the relationship between the position of a pixel in the third still image Gs3 and the luminance value of the corresponding pixel. The measured luminance value does not exceed the luminance value detectable range Rbr. Therefore, the luminance value of a portion outside the luminance value detectable range Rbr actually overflows and becomes the upper limit value of the luminance value detectable range Rbr. The external control apparatus 4100 performs a control to determine that the third still image Gs3 is not an optimal still image when the luminance value of the third still image Gs3 is not within the luminance value detectable range Rbr (i.e., it overflows).

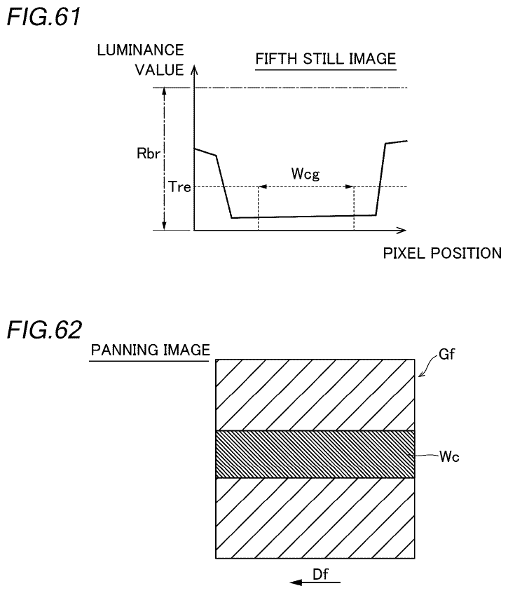

FIG. 61 shows a graph showing the relationship between the position of a pixel in the fifth still image Gs5 and the luminance value of the corresponding pixel. The external control apparatus 4100 performs a control to determine that the fifth still image Gs5 is not an optimal still image based on the determination that the contrast is insufficient because the maximum value of the luminance value in the fifth still image Gs5 is low, about half the luminance value range of the luminance value detectable range Rbr. Description of the second still image Gs2 and the fourth still image Gs4 is omitted.

Thus, the first still image Gs1 is selected (determined) by the external control apparatus 4100 as the optimal still image for setting the predetermined illumination intensity L₀ and the predetermined exposure time T₀.

The external control apparatus 4100 performs a control to set the illumination intensity Lx of the panning image Gf based on the predetermined illumination intensity L₀, which is the illumination intensity of a still image (the first still image Gs1 in the above example) that is determined to enable acquisition of an image with sufficient contrast, the predetermined exposure time T₀, which is the exposure time of the still image, and the exposure time Tx.

That is, the illumination intensity Lx of the panning image Gf is calculated by dividing, by the exposure time Tx, a value obtained by multiplying the predetermined illumination intensity L₀ by the predetermined exposure time T₀ (illumination intensity Lx=“predetermined illumination intensity L₀”×“predetermined exposure time T₀”/“exposure time Tx”).

Thus, the panning image Gf with sufficient contrast is acquired as shown in FIG. 62. When the distance of the imaging execution section Ri is very short and the exposure time Tx is smaller than the minimum value of the exposure time of the high-resolution camera 14a, the panning image Gf with sufficient contrast cannot be acquired. However, as described above, the imaging execution section Ri can be extended by extending imaging of the crack Wc by the high-resolution camera 14a, and thus the exposure time Tx can be increased. Therefore, the panning image Gf with sufficient contrast can be acquired. The exposure time Tx is smaller than the maximum value of the exposure time of the high-resolution camera 14a.

Therefore, the illumination intensity Lx and exposure time Tx of the high-resolution camera 14a are set to correspond to the value obtained by multiplying the predetermined illumination intensity L₀ by the predetermined exposure time T₀ in order to acquire the panning image Gf with sufficient contrast. Specifically, a value obtained by multiplying together the illumination intensity Lx and exposure time Tx of the high-resolution camera 14a matches the value obtained by multiplying the predetermined illumination intensity L₀ by the predetermined exposure time T₀. That is, as an example, when the illumination intensity Lx of the high-resolution camera 14a is doubled relative to the predetermined illumination intensity L₀, the exposure time Tx of the high-resolution camera 14a is halved relative to the predetermined exposure time T₀. Thus, the relationship between the illumination intensity Lx and exposure time Tx of the high-resolution camera 14a is an inversely proportional relationship in which a change in the illumination intensity Lx of the high-resolution camera 14a relative to the predetermined illumination intensity L₀ is offset by a change in the exposure intensity of the high-resolution camera 14a relative to the predetermined exposure time T₀.

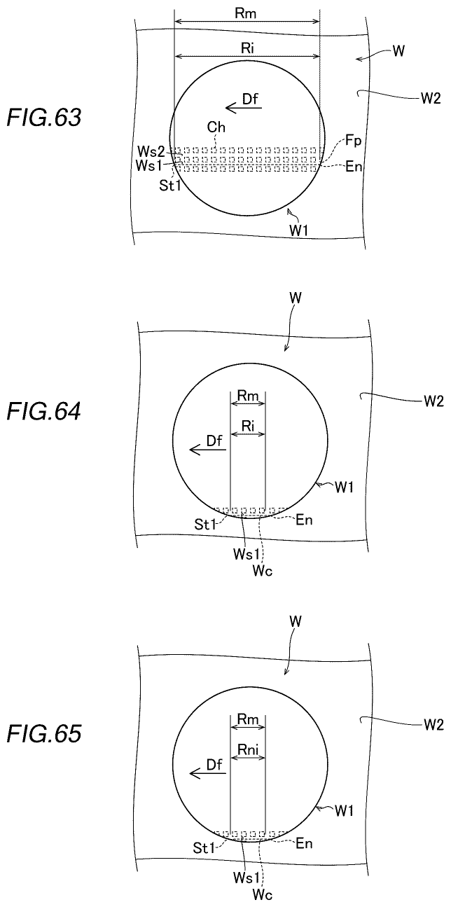

As shown in FIG. 63, the external control apparatus 4100 performs a control to acquire the imaging execution section Ri based on an operation being received to set the imaging execution section Ri. The external control apparatus 4100 performs a control to determine that the imaging execution section Ri can be set when the acquired imaging execution section Ri is equal to or greater than the larger of the first distance and the second distance based on a comparison between the acquired imaging execution section Ri and the larger of the first distance and the second distance. In such a case, the external control apparatus 4100 performs a control to store, in the storage, imaging conditions including the imaging execution section Ri, the exposure time corresponding to the imaging execution section Ri, the illumination intensity corresponding to the imaging execution section Ri, etc. when receiving an operation to determine the setting of the imaging execution section Ri in order to transmit the imaging conditions to the dicing device 401.

The imaging conditions include exposing the high-resolution camera 14a to light in a portion of the predetermined street Ws1 in which the modified layer Wm is formed by the laser L, and not exposing the high-resolution camera 14a to light in a portion of the predetermined street Ws1 in which the modified layer Wm is not formed by the laser L. That is, when the focal position Fp of the laser irradiator 13a reaches the starting point St1 of the predetermined street Ws1, emission of the laser L from the laser irradiator 13a is started to form the modified layer Wm at the predetermined street Ws1, but imaging by the high-resolution camera 14a is not performed in a section from the start of emission of the laser L to the arrival of the high-resolution camera 14a at the starting point St1 of the predetermined street Ws1. Thus, the imaging execution section Ri does not include the section from the start of emission of the laser L to the arrival of the high-resolution camera 14a at the starting point St1 of the predetermined street Ws1, and therefore the condition that the high-resolution camera 14a is not exposed to light with respect to the portion of the predetermined street Ws1 in which the modified layer Wm is not formed by the laser L is satisfied. In addition, the imaging execution section Ri includes a section from the arrival of the focal position Fp of the laser irradiator 13a at the starting point Stl of the predetermined street Ws1 to the arrival at the ending point En, and therefore the condition that the high-resolution camera 14a is exposed to light with respect to the portion of the predetermined street Ws1 in which the modified layer Wm is formed by the laser L is satisfied.

As shown in FIGS. 64 and 65, the external control apparatus 4100 performs a control to determine that the imaging execution section Ri cannot be set when the acquired imaging execution section Ri is small based on a comparison between the acquired imaging execution section Ri and the larger of the first distance and the second distance.

As shown in FIG. 64, the external control apparatus 4100 performs a control to store, in the storage, imaging conditions including the imaging execution section Ri, the exposure time corresponding to the imaging execution section Ri, the illumination intensity corresponding to the imaging execution section Ri, performing an image process to amplify (see FIG. 68) the average luminance value Ba included in the panning image Gf, etc. when acquiring a user operation indicating that the image process is to be performed based on the user's determination as to whether or not to perform the image process to amplify the luminance value (average luminance value Ba) included in the panning image Gf in order to transmit the imaging conditions to the dicing device 401.

As shown in FIG. 65, the external control apparatus 4100 performs a control to store, in the storage, an imaging condition, the non-imaging execution section Rni, when acquiring a user operation indicating that the user does not set the imaging execution section Ri in order to transmit the imaging condition to the dicing device 401.

The external control apparatus 4100 performs a control to transmit the imaging conditions to the dicing device 401 via the network based on an inquiry about imaging conditions from the dicing control calculator 4111.

### Detailed Configuration of Dicing Control Calculator

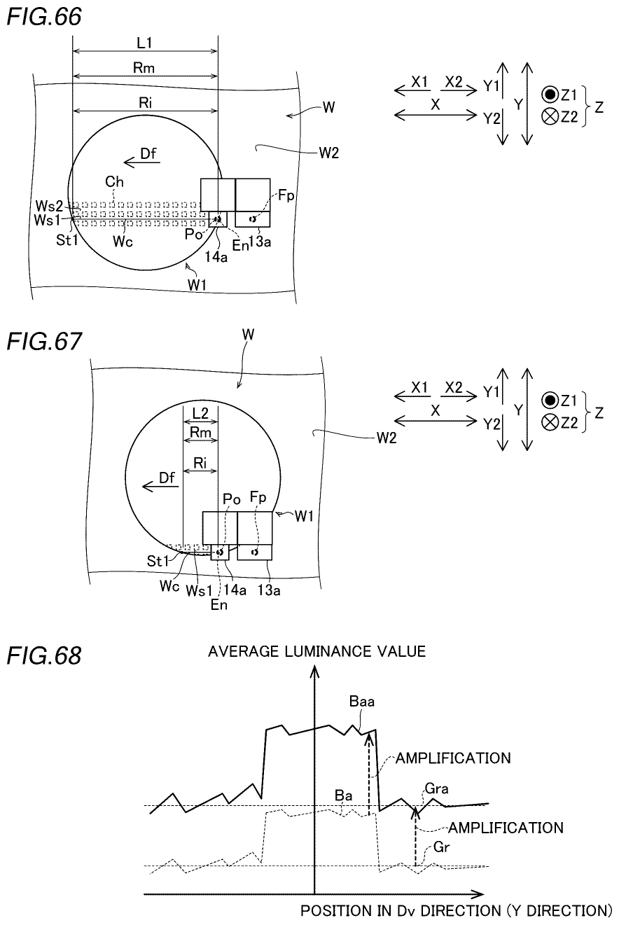

As shown in FIGS. 66 and 67, the dicing control calculator 4111 according to the third embodiment performs a control to move the wafer W1 in the Df direction relative to the laser irradiator 13a and the high-resolution camera 14a until the focal position Fp of the laser L reaches the ending point En of the predetermined street Ws1 in the Df direction, and then continue relative movement of the wafer W1 and extend imaging of the crack Wc by the high-resolution camera 14a to capture the panning image Gf, based on the acquired imaging conditions.

The dicing control calculator 4111 performs a control to continue to expose the high-resolution camera 14a to light with respect to the predetermined street Ws1 while forming the modified layer Wm in the wafer W1 at the predetermined street Ws1 by the laser L by moving the wafer W1 held by the chuck table unit 12 in the Df direction with respect to the high-resolution camera 14a fixed in position by the mounting member 13b to capture the panning image Gf using the high-resolution camera 14a. Such a control is also performed in the dicing control calculator 111 according to the first embodiment and the dicing control calculator 3112 according to the second embodiment.

That is, the dicing control calculator 4111 performs a control to continue to expose the high-resolution camera 14a to light to capture the panning image Gf using the high-resolution camera 14a based on the illumination intensity Lx and exposure time Tx of the high-resolution camera 14a, both of which are set to correspond to the value obtained by multiplying together the predetermined illumination intensity L₀ and the predetermined exposure time T₀, both of which enable the crack Wc to be recognized, when imaging, using the high-resolution camera 14a, the crack Wc on a surface of the wafer W1 closer to the high-resolution camera 14a caused by the modified layer Wm while forming the modified layer Wm in the wafer W1. As described above, the illumination intensity Lx and exposure time Tx of the high-resolution camera 14a are set to correspond to the value obtained by multiplying together the illumination intensity Lx and exposure time Tx of the high-resolution camera 14a with the value obtained by multiplying the predetermined illumination intensity L₀ by the predetermined exposure time T₀.

The dicing control calculator 4111 performs a control to extend imaging of the crack Wc by the high-resolution camera 14a to capture the panning image Gf based on the imaging conditions including information about the imaging execution section Ri based on the larger of the first distance based on the minimum value of the exposure time of the high-resolution camera 14a and the second distance based on the maximum value of the illumination intensity of the high-resolution camera 14a. The laser L is emitted from the starting point St1 to the ending point En of the predetermined street Ws1 in the Df direction.

Specifically, as shown in FIG. 66, when the length L1 of the predetermined street Ws1 in the Df direction is longer than a distance between the focal position Fp of the laser L and the optical center Po, the dicing control calculator 4111 continues relative movement of the wafer W1 and stops imaging the crack Wc by the high-resolution camera 14a when the focal position Fp of the laser L reaches the ending point En of the predetermined street Ws1 in the Df direction in the preset imaging execution section Ri in which the crack Wc is imaged by the high-resolution camera 14a, and the extension of imaging of the crack Wc by the high-resolution camera 14a is not set. When the focal position Fp of the laser L reaches the ending point En of the predetermined street Ws1 in the Df direction, emission of the laser L from the laser irradiator 13a is stopped.

As shown in FIG. 67, when the length L2 of the predetermined street Ws1 in the Df direction is shorter than a distance between the focal position Fp of the laser L and the optical center Po, the dicing control calculator 4111 performs a control to continue relative movement of the wafer W1 and extend imaging of the crack Wc by the high-resolution camera 14a to capture the panning image Gf after the focal position Fp of the laser L reaches the ending point En of the predetermined street Ws1 in the Df direction in the preset imaging execution section Ri in which the crack Wc is imaged by the high-resolution camera 14a, and the extension of imaging of the crack Wc by the high-resolution camera 14a is set. When the focal position Fp of the laser L reaches the ending point En of the predetermined street Ws1 in the Df direction, emission of the laser L from the laser irradiator 13a is stopped.

As shown in FIG. 68, when the imaging execution section Ri at the predetermined street Ws1 for imaging the crack We by extending imaging by the high-resolution camera 14a has a distance that does not enable the exposure time and illumination intensity, both of which enable the crack Wc to be recognized in the panning image Gf, to be set, the dicing control calculator 4111 performs the image process to amplify the luminance value (average luminance value Ba) contained in the panning image Gf captured by extending imaging by the high-resolution camera with respect to the predetermined street Ws1 based on the acquired imaging conditions. That is, the dicing control calculator 4111 performs a control to multiply a reference value Gr (ground level) of the panning image Gf by a predetermined value to amplify the reference value Gr to a reference value Gra, and to multiply the average luminance value Ba in the panning image Gf by the predetermined value to amplify the average luminance value Ba to an average luminance value Baa. An appropriate value is set in advance as the predetermined value by the user. Thus, the contrast is also enhanced.

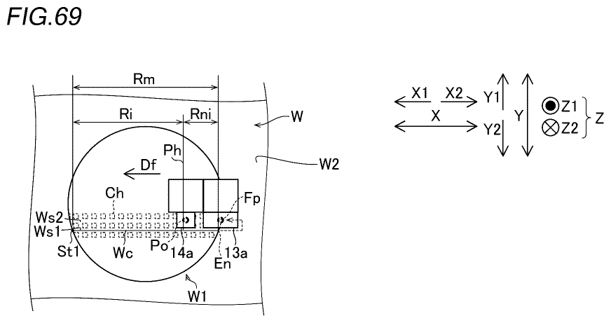

As shown in FIG. 69, when the imaging execution section Ri in which the crack Wc is imaged by the high-resolution camera 14a is longer than the distance between the focal position Fp of the laser L and the optical center Po, the dicing control calculator 4111 performs a control to stop the high-resolution camera 14a from imaging the crack Wc and make a movement to the next predetermined street Ws2 (starting point St2 (see FIG. 55)) at which the modified layer Wm is to be formed based on the extension of imaging of the crack We by the high-resolution camera 14a not being set in the imaging execution section Ri included in the acquired imaging conditions, when the focal position Fp of the laser L reaches the ending point En of the predetermined street Ws1 in the Df direction.

The imaging execution section Ri shown in each of FIGS. 66, 67, and 69 satisfies the condition that the high-resolution camera 14a is not exposed to light with respect to the portion of the predetermined street Ws1 in which the modified layer Wm is not formed by the laser L, and the condition that the high-resolution camera 14a is exposed to light with respect to the portion of the predetermined street Ws1 in which the modified layer Wm is formed by the laser L. Thus, the dicing control calculator 4111 controls the high-resolution camera 14a to image the crack Wc based on the imaging execution section Ri for the high-resolution camera 14a set to further satisfy the imaging condition that the high-resolution camera 14a is exposed to light with respect to the portion of the predetermined street Ws1 in which the modified layer Wm is formed by the laser L, and the high-resolution camera 14a is not exposed to light with respect to the portion of the predetermined street Ws1 in which the modified layer Wm is not formed by the laser L, the predetermined illumination intensity L₀, and the predetermined exposure time T₀.

The remaining configurations of the third embodiment are similar to those of the first embodiment, and thus description thereof is omitted.

### Crack Inspection Process

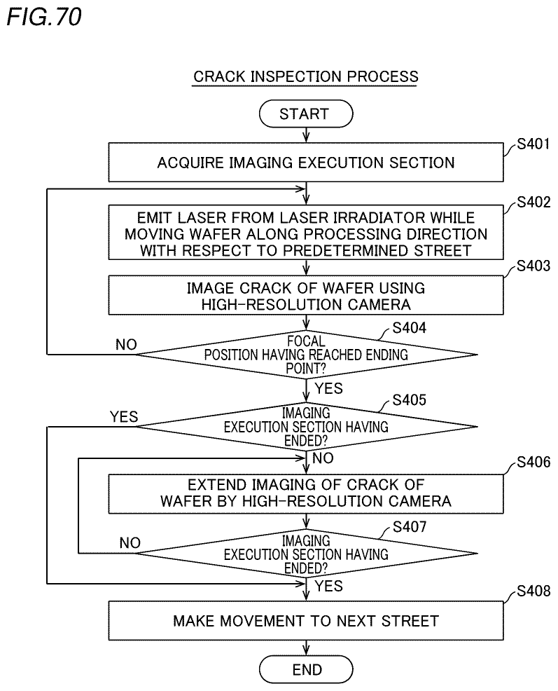

A crack inspection process performed by the dicing control calculator 4111 is described below with reference to FIG. 70.

In step S401, the dicing control calculator 4111 acquires the imaging execution section Ri from the external control apparatus 4100. In step S402, the dicing control calculator 4111 emits the laser L from the laser irradiator 13a while moving the wafer W1 relative to the laser irradiator 13a and the high-resolution camera 14a along the Df direction (processing direction) with respect to the predetermined street Ws1 using the chuck table unit 12. In step S403, the dicing control calculator 4111 images the crack Wc on the surface of the wafer W1 using the high-resolution camera 14a.

Thus, in step S401 to step S403, the dicing control calculator 4111 performs a process to continue to expose the high-resolution camera 14a to light with respect to the predetermined street Ws1 while forming the modified layer Wm in the wafer W1 at the predetermined street Ws1 by the laser L by moving the wafer W1 held by the chuck table unit 12 in the Df direction with respect to the high-resolution camera 14a fixed in position by the mounting member 13b to cause the high-resolution camera 14a to capture the panning image Gf. Such a process is also performed in the dicing control calculator 111 according to the first embodiment and the dicing control calculator 3112 according to the second embodiment. The illumination intensity Lx and exposure time Tx of the high-resolution camera 14a are set such that the value obtained by multiplying the illumination intensity Lx by the exposure time Tx matches the value obtained by multiplying together the predetermined illumination intensity and the predetermined exposure time, both of which enable the crack Wc to be recognized.

In step S404, the dicing control calculator 4111 determines whether or not the focal position Fp of the laser irradiator 13a has reached the ending point En of the predetermined street Ws1 in the Df direction. When the focal position Fp of the laser irradiator 13a has reached the ending point En of the predetermined street Ws1 in the Df direction, the process advances to step S405. When the focal position Fp of the laser irradiator 13a has not reached the ending point En of the predetermined street Ws1 in the Df direction, the process returns to step S402.

In step S405, the dicing control calculator 4111 determines whether or not the imaging execution section Ri has ended. When the imaging execution section Ri has ended, the process advances to step S408, a movement to the next street Ws is made, and then the crack inspection process is terminated. When the imaging execution section Ri has not ended, the process advances to step S406.

In step S406, the dicing control calculator 4111 extends imaging by the high-resolution camera 14a to image the crack Wc on the surface of the wafer W1. In step S407, the dicing control calculator 4111 determines whether or not the imaging execution section Ri has ended. When the imaging execution section Ri has ended, the process advances to step S408, a movement to the next street Ws is made, and then the crack inspection process is terminated. When the imaging execution section Ri has not ended, the process returns to step S406.

### Advantageous Effects of Third Embodiment

According to the third embodiment, the following advantageous effects are achieved.

According to the third embodiment, similarly to the first embodiment, the dicing device 401 includes the shared mounting member 13b to which both the laser irradiator 13a and the high-resolution camera 14a are mounted. Accordingly, an increase in the number of components and the complexity of the mounting structure for the laser irradiator 13a and the high-resolution camera 14a in the dicing device 401 can be reduced or prevented.

According to the third embodiment, as described above, the dicing device 401 includes the dicing control calculator 4111 configured or programmed to perform a control to continue to expose the high-resolution camera 14a to light with respect to a preset portion of the predetermined street Ws1 of the plurality of streets Ws while forming the modified layer Wm in the wafer W1 by the laser L along the Df direction at the predetermined street Ws1 to image the crack Wc on the surface closer to the high-resolution camera 14a caused by the modified layer Wm to capture the panning image Gf using the high-resolution camera 14a. Accordingly, when the panning image Gf is obtained by imaging the crack Wc on the surface closer to the high-resolution camera 14a, it can be reliably confirmed that the crack Wc has reached the surface of the wafer W1, and thus it is possible to confirm a location at which the wafer W1 is not properly divided because the crack Wc has not reached the surface of the wafer W1. Consequently, it is possible to change the emission conditions of the laser L and re-emit the laser L to the predetermined street Ws1, and it is also possible to identify the location at which the wafer W1 is not properly divided and perform subsequent detailed inspections to reduce or prevent an increase in the number of detailed inspections.

According to the third embodiment, as described above, the dicing control calculator 4111 is configured or programmed to, when imaging the crack Wc on the surface of the wafer W1 closer to the high-resolution camera 14a caused by the modified layer Wm using the high-resolution camera 14a while forming the modified layer Wm in the wafer W1, perform a control to continue to expose the high-resolution camera 14a to light to capture the panning image Gf using the high-resolution camera 14a based on the illumination intensity Lx and exposure time Tx of the high-resolution camera 14a, both of which are set to correspond to the value obtained by multiplying together the predetermined illumination intensity L₀ and the predetermined exposure time T₀, both of which enable the crack Wc to be recognized. Accordingly, the crack Wc clearly appears in the panning image Gf captured by continuing to expose the high-resolution camera 14a to light, and thus the dicing control calculator 4111 can reliably recognize the crack Wc.

According to the third embodiment, as described above, the dicing device 401 includes the chuck table unit 12 to move the wafer W1 in the Df direction while holding the wafer W1. The mounting member 13b is fixed in position in the horizontal direction and the upward-downward direction. The dicing control calculator 4111 is configured or programmed to perform a control to continue to expose the high-resolution camera 14a to light with respect to the predetermined street Ws1 while forming the modified layer Wm in the wafer W1 by the laser L at the predetermined street Ws1 by moving the wafer W1 held by the chuck table unit 12 in the Df direction with respect to the high-resolution camera 14a fixed in position by the mounting member 13b to capture the panning image Gf using the high-resolution camera 14a. Accordingly, the crack Wc is imaged using the high-resolution camera 14a fixed in position such that the focal position Fp of the high-resolution camera 14a can be maintained constant, and thus the panning image Gf can be acquired in which the crack Wc clearly appears.

According to the third embodiment, as described above, the high-resolution camera 14a is mounted to the mounting member 13b together with the laser irradiator 13a with the focal position Fp of the laser L from the laser irradiator 13a and the optical center Po of the high-resolution camera 14a aligned along the Df direction as viewed from the Z1 direction side (in a plan view). The dicing control calculator 4111 is configured or programmed to perform a control to move the wafer W1 in the Df direction relative to the laser irradiator 13a and the high-resolution camera 14a until the focal position Fp of the laser L reaches the ending point En of the predetermined street Ws1 in the Df direction, and then continue relative movement of the wafer W1 and extend imaging of the crack Wc by the high-resolution camera 14a to capture the panning image Gf. Since the focal position Fp of the laser L from the laser irradiator 13a and the optical center Po of the high-resolution camera 14a are aligned along the Df direction, the crack Wc in the portion between the focal position Fp of the laser L from the laser irradiator 13a and the optical center Po of the high-resolution camera 14a has not been imaged by the high-resolution camera 14a when the focal position Fp of the laser L reaches the ending point En of the predetermined street Ws1 in the Df direction. Therefore, imaging of the crack Wc by the high-resolution camera 14a is extended such that the crack Wc in question can be imaged by the high-resolution camera 14a, and thus the crack Wc formed on the predetermined street Ws1 can be reliably imaged by the high-resolution camera 14a to the extent necessary.

According to the third embodiment, as described above, the dicing control calculator 4111 is configured or programmed to perform a control to extend imaging of the crack Wc by the high-resolution camera 14a to capture the panning image Gf based on the imaging conditions including the information about the imaging execution section Ri based on the larger of the first distance based on the minimum value of the exposure time of the high-resolution camera 14a and the second distance based on the maximum value of the illumination intensity of the high-resolution camera 14a. Accordingly, the imaging execution section Ri is set so as not to exceed settable numerical limits for the minimum exposure time and maximum illumination intensity of the high-resolution camera 14a, and thus the panning image Gf in which the crack Wc is recognizable can be acquired.

According to the third embodiment, as described above, the dicing control calculator 4111 is configured or programmed to, when the imaging execution section Ri at the predetermined street Ws1 for imaging the crack Wc by extending imaging by the high-resolution camera 14a has a distance that does not enable the exposure time and illumination intensity, both of which enable the crack Wc to be recognized in the panning image Gf, to be set, perform the image process to amplify the luminance value (average luminance value Ba) contained in the panning image Gf captured by extending imaging by the high-resolution camera with respect to the predetermined street Ws1. Accordingly, even when the exposure time and illumination intensity of the high-resolution camera 14a exceed the limits of settable numerical values, the crack Wc is imaged by the high-resolution camera 14a within a range of each of the settable numerical values of the exposure time and illumination intensity of the high-resolution camera 14a, and then the luminance value (average luminance value Ba) included in the acquired panning image Gf is amplified such that the panning image Gf in which the crack Wc is recognizable can be acquired.

According to the third embodiment, as described above, the dicing control calculator 4111 is configured or programmed to, when the length of the predetermined street Ws1 in the Df direction is longer than the distance between the focal position Fp of the laser L and the optical center Po of the high-resolution camera 14a, perform a control to stop the high-resolution camera 14a from imaging the crack Wc and make a movement to the next street Ws at which the modified layer Wm is to be formed when the focal position Fp of the laser L reaches the ending point En of the predetermined street Ws1 in the Df direction in the preset imaging execution section Ri in which the crack Wc is imaged by the high-resolution camera 14a, and the extension of imaging of the crack We by the high-resolution camera 14a is not set. Accordingly, the time required to move from the predetermined street Ws1 to the next street Ws can be shortened as much as possible while information about the crack Wc required for inspection based on the crack Wc is acquired. Thus, the accuracy of the inspection can be ensured, and an increase in the processing time required to form the modified layer Wm in the wafer W1 can be reduced or prevented.

According to the third embodiment, as described above, the dicing control calculator 4111 is configured or programmed to, when the length of the predetermined street Ws1 in the Df direction is shorter than the distance between the focal position Fp of the laser L and the optical center Po of the high-resolution camera 14a, perform a control to continue relative movement of the wafer W1 and extend imaging of the crack Wc by the high-resolution camera 14a to capture the panning image Gf after the focal position Fp of the laser L reaches the ending point En of the predetermined street Ws1 in the Df direction in the preset imaging execution section Ri in which the crack Wc is imaged by the high-resolution camera 14a, and the extension of imaging of the crack Wc by the high-resolution camera 14a is set. In the case of the short section as described above, when the focal position Fp of the laser L reaches the ending point En of the predetermined street Ws1 in the Df direction and then a movement to the street Ws next to the predetermined street Ws1 is made, the crack Wc at the predetermined street Ws1 cannot be imaged. Therefore, imaging of the crack Wc by the high-resolution camera 14a is extended such that even when the length of the predetermined street Ws1 in the Df direction is short, the crack Wc can be imaged by the high-resolution camera 14a.

According to the third embodiment, as described above, the dicing control calculator 4111 is configured or programmed to control the high-resolution camera 14a to image the crack Wc based on the imaging execution section Ri for the high-resolution camera 14a set to further satisfy the imaging condition that the high-resolution camera 14a is exposed to light with respect to the portion of the predetermined street Ws1 in which the modified layer Wm is formed by the laser L, and the high-resolution camera 14a is not exposed to light with respect to the portion of the predetermined street Ws1 in which the modified layer Wm is not formed by the laser L, the predetermined exposure time T₀, and the predetermined illumination intensity L₀. Accordingly, the high-resolution camera 14a does not image the portion of the predetermined street Ws1 in which the modified layer Wm is not formed by the laser L, but images only the portion of the predetermined street Ws1 in which the modified layer Wm is formed by the laser L and the crack Wc is formed, and thus an image (panning image Gf) in which the crack Wc more clearly appears can be acquired. The remaining advantageous effects of the third embodiment are similar to those of the first embodiment, and thus description thereof is omitted.

### Setting of Illumination Intensity in Imaging Execution Section in First to Third Embodiments

An example of the setting of the illumination intensity Lx in the imaging execution section Ri in the first to third embodiments is now described with reference to FIGS. 56 and 58 to 62. In the first and second embodiments, the preset portion of the predetermined street Ws1 corresponds to the imaging execution section Ri in the third embodiment, and thus the setting of the illumination intensity Lx in the imaging execution section Ri is equal to the setting of the illumination intensity Lx in the preset portion. For convenience of description, the imaging execution section Ri is used below.

As shown in FIG. 56, as an example, the imaging execution section Ri is set from the starting point St1 to the point Ph before the ending point En of the predetermined street Ws1 in the Df direction based on the processing section Rm (laser emission section) in which the modified layer Wm is formed at the predetermined street Ws1 by the laser L. The imaging execution section Ri may be set by the user or set automatically by the external control apparatus 4100.

The exposure time Tx is set by dividing the imaging execution section Ri by the moving speed of the wafer W1 in the Df direction. As shown in FIGS. 58 to 62, the illumination intensity Lx of the panning image Gf is calculated by dividing, by the exposure time Tx, the value obtained by multiplying the predetermined illumination intensity L₀ by the predetermined exposure time T₀ (illumination intensity Lx=“predetermined illumination intensity L₀”×“predetermined exposure time T₀”/“exposure time Tx”). The predetermined illumination intensity L₀ and the predetermined exposure time T₀ are an illumination intensity and an illumination intensity set for a still image in which the luminance value is within the luminance value detectable range Rbr and the range that is equal to or less than the extraction threshold Tre is within the non-defective item determination reference width range Wcg, respectively. The predetermined illumination intensity L₀, the predetermined exposure time T₀, the exposure time Tx, and the illumination intensity Lx are automatically set by the external control apparatus 4100.

In the dicing devices 1 according to the first and second embodiments and the dicing device 401 according to the third embodiment, the illumination intensity Lx in the imaging execution section Ri is set by the process described above.

### Modified Examples

The embodiments disclosed this time must be considered as illustrative in all points and not restrictive. The scope of the present disclosure is not shown by the above description of the embodiments but by the scope of claims for patent, and all modifications (modified examples) within the meaning and scope equivalent to the scope of claims for patent are further included.

For example, while the example in which when the amount of positional deviation in the first inspection at the next street Ws is within the warning range R31 or R32, the dicing control calculator 111 (3112) performs a control to adjust the amount of movement of the chuck table unit 12 in the Y direction by an amount by which the amount of positional deviation is corrected when a movement from the next street Ws to the next predetermined street Ws2 via the route R is made has been shown in each of the aforementioned first to third embodiments, the present disclosure is not restricted to this. In the present disclosure, depending on the processing speed of the dicing control calculator or the length of a route from the current street to the next street, for example, the amount of movement of the chuck table unit in the Y direction may be adjusted before processing of the next street. Alternatively, the amount of movement of the chuck table unit in the Y direction may be adjusted at and after the next-next street from the current street.

While the example in which the dicing control calculator 111 (3112) performs a control to make a setting to perform the second inspection on the street Ws for which it is identified that the inspection result of the first inspection is bad among the plurality of streets Ws has been shown in each of the aforementioned first to third embodiments, the present disclosure is not restricted to this. In the present disclosure, the controller may perform a control to make a setting to perform the second inspection on an inspection point for which it is identified that the inspection result of the first inspection is bad among a plurality of inspection points set on the plurality of streets Ws.

While the example in which the second inspection is performed on the street Ws for which it is identified that the result of the first inspection is bad among the plurality of intersections Cr between the cracks Wc of the wafer W1 has been shown in each of the aforementioned first to third embodiments, the present disclosure is not restricted to this. In the present disclosure, the second inspection may be performed at every intersection.

While the example in which the imager 14 includes the high-resolution camera 14a and the wide-angle camera 14b, both of which are infrared cameras, has been shown in each of the aforementioned first to third embodiments, the present disclosure is not restricted to this. In the present disclosure, the imager may include a visible light camera in addition to the high-resolution camera 14a and the wide-angle camera 14b, both of which are infrared cameras.

While the example in which the imager 14 captures the panning image Gf in the preset portion of the street Ws has been shown in each of the aforementioned first to third embodiments, the present disclosure is not restricted to this. In the present disclosure, the imager may capture a plurality of time-lapse images by shuttering a plurality of times in the preset portion of the street.

While the example in which the second inspection is performed after the modified layer Wm is formed in the wafer W1 has been shown in each of the aforementioned first to third embodiments, the present disclosure is not restricted to this. In the present disclosure, the second inspection may be performed during formation of the modified layer Wm in the wafer W1.

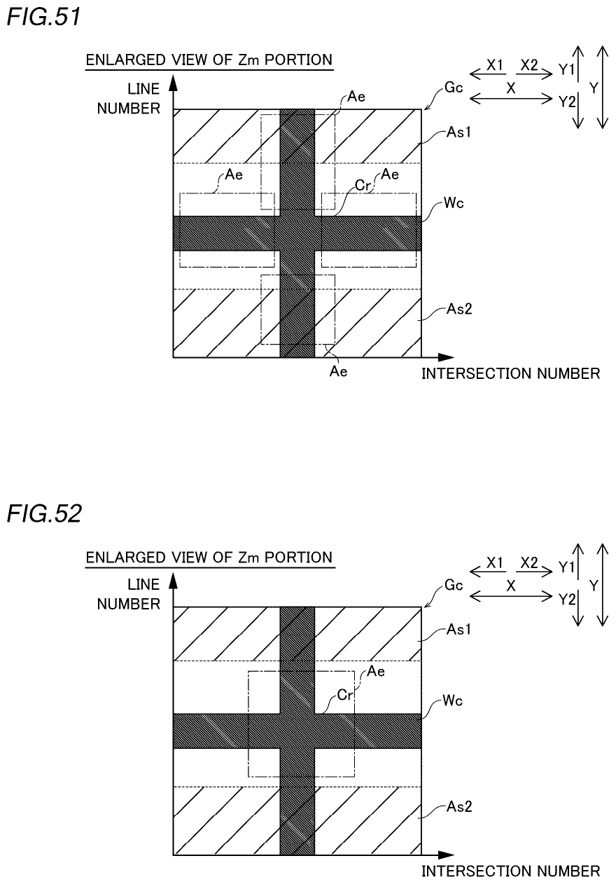

While the example in which the identification frame Ae is superimposed on a portion of the crack Wc on the left side of the intersection image Gc has been shown in each of the aforementioned first to third embodiments, the present disclosure is not restricted to this. In the present disclosure, as shown in FIG. 51, a plurality of identification frames may be placed in four portions of the cracks on the left side, right side, upper side, and lower side of the intersection image. Alternatively, as shown in FIG. 52, one identification frame may be placed at the center of the cracks in the intersection image. Alternatively, a plurality of identification frames may be placed so as to overlap each other.

While the example in which when the imaging execution section Ri at the predetermined street Ws1 for imaging the crack Wc by extending imaging by the high-resolution camera 14a (first imager) has a distance that does not enable the exposure time and illumination intensity, both of which enable the crack Wc to be recognized in the panning image Gf, to be set, the dicing control calculator 4111 (controller) performs the image process to amplify the average luminance value Ba (luminance value) contained in the panning image Gf captured by extending imaging by the high-resolution camera 14a (first imager) with respect to the predetermined street Ws1 based on the acquired imaging conditions has been shown in the aforementioned third embodiment, the present disclosure is not restricted to this. In the present disclosure, when the imaging execution section at the predetermined street for imaging the crack by extending imaging by the first imager has a distance that does not enable the exposure time and illumination intensity, both of which enable the crack to be recognized in the panning image, to be set, the controller may not image the crack using the first imager.

While the example in which the dicing control calculator 111 (3112) (controller) performs a control to acquire the illumination intensity for performing the first inspection based on the exposure time for performing the first inspection and the exposure time and illumination intensity for performing the second inspection has been shown in each of the aforementioned first and second embodiments, the present disclosure is not restricted to this. In the present disclosure, when imaging the crack caused by the modified layer using the first imager after the modified layer is formed in the wafer, the controller may perform a control to continue to expose the first imager to light at the illumination intensity and for the exposure time both set to correspond to a value obtained by multiplying together the predetermined illumination intensity and the predetermined exposure time, both of which enable the crack to be recognized, while moving the wafer held by the table unit in the processing direction with respect to the first imager fixed in position by the mounting member. Accordingly, an image in which the crack is recognizable can be reliably acquired even when the first imager is continuously exposed to light and captures the image.

While the example in which the dicing control calculator 111 (3112) (controller) performs a control to acquire the illumination intensity for performing the first inspection based on the exposure time for performing the first inspection and the exposure time and illumination intensity for performing the second inspection has been shown in each of the aforementioned first and second embodiments, the present disclosure is not restricted to this. In the present disclosure, the controller may perform a control to continue to expose the first imager to light to acquire the panning image based on the illumination intensity and exposure time of the first imager both set to correspond to the value obtained by multiplying together the predetermined illumination intensity and the predetermined exposure time, both of which enable the crack to be recognized, when imaging, using the first imager, the crack on the surface of the wafer closer to the first imager caused by the modified layer while forming the modified layer in the wafer. Accordingly, the crack clearly appears in the panning image captured by continuing to expose the first imager to light, and thus the controller can reliably recognize the crack.

While the example in which when the length L1 of the predetermined street Ws1 in the Df direction (processing direction) is longer than the distance between the focal position Fp of the laser L and the optical center Po of the high-resolution camera 14a (first imager), the dicing control calculator 4111 (controller) performs a control to stop the high-resolution camera 14a (first imager) from imaging the crack Wc and make a movement to the next street Ws at which the modified layer Wm is to be formed when the focal position Fp of the laser L reaches the ending point En of the predetermined street Ws1 in the Df direction (processing direction) in the preset imaging execution section Ri in which the crack Wc is imaged by the high-resolution camera 14a (first imager), and the extension of imaging of the crack Wc by the high-resolution camera 14a (first imager) is not set has been shown in the aforementioned third embodiment, the present disclosure is not restricted to this. In the present disclosure, even when the length of the predetermined street in the processing direction is longer than the distance between the focal position of the laser and the optical center of the first imager, the extension of imaging of the crack by the first imager may be set in order to increase a range of imaging of the crack by the first imager.

While the control process of the dicing control calculator 111 (3112, 4111) is described, using the flowchart described in a manner driven by a flow in which processes are performed in order along a process flow for the convenience of illustration in each of the aforementioned first to third embodiments, the present disclosure is not restricted to this. In the present disclosure, the control process of the controller may be performed in an event-driven manner in which processes are performed on an event basis. In this case, the control process may be performed in a complete event-driven manner or in a combination of an event-driven manner and a manner driven by a flow.

What is claimed is:

1. A dicing device comprising:
a laser irradiator configured to emit a laser in a processing direction extending along each of a plurality of streets of a wafer to form a modified layer in the wafer;
a first imager configured to image the wafer in which the modified layer has been formed; and
a shared mounting member to which both the laser irradiator and the first imager are mounted.

2. The dicing device according to claim 1, wherein
the mounting member is fixed in position in a horizontal direction and an upward-downward direction of the dicing device; and
the laser irradiator and the first imager are fixed in position in the horizontal direction and mounted to the mounting member.

3. The dicing device according to claim 2, further comprising:
a table configured to move the wafer in the processing direction while holding the wafer; wherein
the first imager is fixed in position in the horizontal direction and is configured to image the wafer in which the modified layer has been formed by the laser emitted to the wafer from the laser irradiator while the wafer is moved in the processing direction by the table.

4. The dicing device according to claim 3, further comprising:
a controller configured or programmed to, when imaging a crack caused by the modified layer using the first imager after the modified layer is formed in the wafer, perform a control to continue to expose the first imager to light at an illumination intensity and for an exposure time, the illumination intensity and the exposure time both being set to correspond to a value obtained by multiplying together a predetermined illumination intensity and a predetermined exposure time, both of which enable the crack to be recognized, while moving the wafer held by the table in the processing direction with respect to the first imager fixed in position by the mounting member.

5. The dicing device according to claim 4, wherein
the controller is configured or programmed to control the first imager to image the crack based on an imaging execution section for the first imager set to further satisfy an imaging condition that the first imager is exposed to light with respect to a portion of a predetermined street of the plurality of streets in which the modified layer is formed by the laser, and the first imager is not exposed to light with respect to a portion of the predetermined street in which the modified layer is not formed by the laser, the predetermined exposure time, and the predetermined illumination intensity.

6. The dicing device according to claim 1, wherein
the first imager is mounted to the mounting member together with the laser irradiator with a focal position of the laser from the laser irradiator and an optical center of the first imager aligned along the processing direction in a plan view.

7. The dicing device according to claim 1, further comprising:
a second imager mounted to the mounting member together with the first imager and the laser irradiator to image an alignment mark on the wafer; wherein
the first imager has a higher resolution than the second imager.

8. The dicing device according to claim 1, further comprising:
a controller configured or programmed to perform a control to continue to expose the first imager to light with respect to a preset portion of a predetermined street of the plurality of streets while forming the modified layer in the wafer by the laser along the processing direction at the predetermined street to create a panning image.

9. The dicing device according to claim 8, wherein
the controller is configured or programmed to, when imaging a crack on a surface of the wafer closer to the first imager caused by the modified layer using the first imager while forming the modified layer in the wafer, perform a control to continue to expose the first imager to light to capture the panning image based on an illumination intensity and an exposure time of the first imager, both of which are set to correspond to a value obtained by multiplying together a predetermined illumination intensity and a predetermined exposure time, both of which enable the crack to be recognized.

10. The dicing device according to claim 9, wherein
the controller is configured or programmed to control the first imager to image the crack based on an imaging execution section for the first imager set to further satisfy an imaging condition that the first imager is exposed to light with respect to a portion of the predetermined street in which the modified layer is formed by the laser, and the first imager is not exposed to light with respect to a portion of the predetermined street in which the modified layer is not formed by the laser, the predetermined exposure time, and the predetermined illumination intensity.

11. The dicing device according to claim 9, wherein
the controller is configured or programmed to perform a control to acquire an illumination intensity to image the preset portion of the predetermined street using the first imager while forming the modified layer in the wafer by the laser along the processing direction based on an exposure time preset for the first imager to image the preset portion of the predetermined street using the first imager while forming the modified layer in the wafer by emitting the laser along the processing direction, and an exposure time and an illumination intensity preset for the first imager to inspect the crack formed due to the modified layer after the modified layer is formed at all of the plurality of streets.

12. The dicing device according to claim 11, wherein
the controller is configured or programmed to perform a control to perform a first inspection to inspect whether processing of the modified layer by the laser is bad or not based on a plurality of average luminance values acquired for a plurality of respective pixel groups by averaging luminance values of a plurality of pixels included in the plurality of pixel groups of the panning image in which the plurality of pixel groups including the plurality of pixels aligned in the processing direction are aligned in a direction perpendicular to the processing direction.

13. The dicing device according to claim 12, wherein
the controller is configured or programmed to perform a control to acquire a plurality of crack luminance values that are equal to or greater than a preset threshold, and a position range in the direction perpendicular to the processing direction of the plurality of pixel groups having the plurality of crack luminance values based on average luminance values within a position range of the predetermined street among the plurality of average luminance values and the preset threshold.

14. The dicing device according to claim 12, wherein
the controller is configured or programmed to perform a control to acquire an amount of positional deviation of the crack formed due to the modified layer based on a difference between a position within a position range of a plurality of crack luminance values and a preset reference position, and perform the first inspection.

15. The dicing device according to claim 14, wherein
the controller is configured or programmed to perform a control to correct a positional deviation of a focal position of the laser in the direction perpendicular to the processing direction based on the amount of positional deviation before processing of the modified layer by the laser at a street after a street next to the predetermined street on which the plurality of average luminance values have been acquired.

16. The dicing device according to claim 13, wherein
the controller is configured or programmed to perform a control to perform the first inspection to inspect whether the crack formed due to the modified layer is appropriate or not based on at least one of a comparison between an average value of the plurality of crack luminance values and a preset reference average luminance value range or a comparison between a width as the position range of the plurality of crack luminance values and a preset reference width range.

17. The dicing device according to claim 13, wherein
the controller is configured or programmed to perform a control to notify an operator when an inspection result of the first inspection based on the plurality of crack luminance values is bad.

18. The dicing device according to claim 12, wherein
the dicing device is configured to make a setting to perform a second inspection to re-inspect whether the crack formed due to the modified layer is bad or not after the modified layer is formed at all of the plurality of streets of the wafer, based on an inspection result indicating that the processing of the modified layer is bad among inspection results of the first inspection for the plurality of streets.

19. A semiconductor chip manufacturing method comprising:
forming a modified layer in a wafer including a plurality of semiconductor chips by emitting a laser from a laser irradiator in a processing direction extending along each of a plurality of streets of the wafer;
imaging the wafer in which the modified layer has been formed using a first imager mounted to a mounting member shared with the laser irradiator; and
expanding an elastic sheet member to divide the wafer into the plurality of semiconductor chips along a dividing line by an expander.

20. A semiconductor chip manufactured by a dicing device, the dicing device comprising:
a laser irradiator configured to emit a laser in a processing direction extending along each of a plurality of streets of a wafer including a plurality of semiconductor chips to form a modified layer in the wafer;
a first imager configured to image the wafer in which the modified layer has been formed; and
a shared mounting member to which both the laser irradiator and the first imager are mounted.

21. The dicing device according to claim 1, further comprising:
a controller configured or programmed to perform a control to continue to expose the first imager to light with respect to a preset portion of a predetermined street of the plurality of streets while forming the modified layer in the wafer by the laser along the processing direction at the predetermined street to image a crack on a surface of the wafer closer to the first imager caused by the modified layer to capture a panning image using the first imager.

22. The dicing device according to claim 21, wherein
the controller is configured or programmed to, when imaging the crack on the surface of the wafer closer to the first imager caused by the modified layer using the first imager while forming the modified layer in the wafer, perform a control to continue to expose the first imager to light to capture the panning image using the first imager based on an illumination intensity and an exposure time of the first imager, both of which are set to correspond to a value obtained by multiplying together a predetermined illumination intensity and a predetermined exposure time, both of which enable the crack to be recognized.

23. The dicing device according to claim 8, further comprising:
a table configured to move the wafer in the processing direction while holding the wafer; wherein
the mounting member is fixed in position in a horizontal direction and an upward-downward direction of the dicing device; and
the controller is configured or programmed to perform a control to continue to expose the first imager to light with respect to the predetermined street while forming the modified layer in the wafer by the laser at the predetermined street by moving the wafer held by the table in the processing direction with respect to the first imager fixed in position by the mounting member to capture the panning image using the first imager.

24. The dicing device according to claim 21, wherein
the first imager is mounted to the mounting member together with the laser irradiator with a focal position of the laser from the laser irradiator and an optical center of the first imager aligned along the processing direction in a plan view, and
the controller is configured or programmed to perform a control to move the wafer in the processing direction relative to the laser irradiator and the first imager until the focal position of the laser reaches an ending point of the predetermined street in the processing direction, and then continue relative movement of the wafer and extend imaging of the crack by the first imager to capture the panning image.

25. The dicing device according to claim 24, wherein
the controller is configured or programmed to perform a control to extend imaging of the crack by the first imager to capture the panning image based on an imaging condition including information about an imaging execution section based on a larger of a first distance based on a minimum value of an exposure time of the first imager and a second distance based on a maximum value of an illumination intensity of the first imager.

26. The dicing device according to claim 24, wherein
the controller is configured or programmed to, when an imaging execution section at the predetermined street for imaging the crack by extending imaging by the first imager has a distance that does not enable an exposure time and an illumination intensity, both of which enable the crack to be recognized in the panning image, to be set, perform an image process to amplify a luminance value contained in the panning image captured by extending imaging by the first imager with respect to the predetermined street.

27. The dicing device according to claim 24, wherein
the controller is configured or programmed to, when a length of the predetermined street in the processing direction is longer than a distance between the focal position of the laser and the optical center of the first imager, perform a control to stop the first imager from imaging the crack and make a movement to a next street at which the modified layer is to be formed when the focal position of the laser reaches the ending point of the predetermined street in the processing direction in a preset imaging execution section in which the crack is imaged by the first imager, and extension of imaging of the crack by the first imager is not set.

28. The dicing device according to claim 24, wherein
the controller is configured or programmed to, when a length of the predetermined street in the processing direction is shorter than a distance between the focal position of the laser and the optical center of the first imager, perform a control to continue relative movement of the wafer and extend imaging of the crack by the first imager to capture the panning image after the focal position of the laser reaches the ending point of the predetermined street in the processing direction in a preset imaging execution section in which the crack is imaged by the first imager, and extension of imaging of the crack by the first imager is set.
